(19) United States
(12) Patent Application Publication
(10) Pub. No.: US 2026/0253645 A1
(43) Pub. Date: Aug. 27, 2026

(54) MEMORY DEVICES AND MEMORY SYSTEMS

(71) Applicant: FTMOS, LLC, Fremont, CA (US)

(72) Inventor: Suresh Rajan, Fremont, CA (US)

(21) Appl. No.: 19/420,433

(22) Filed: Dec. 15, 2025

Related U.S. Application Data
(60) Provisional application No. 63/761,777, filed on Feb. 21, 2025.
(60) Provisional application No. 63/798,166, filed on May 1, 2025.
(60) Provisional application No. 63/798,153, filed on May 1, 2025.
(60) Provisional application No. 63/929,604, filed on Dec. 2, 2025.

(51) Int. Cl. G11C 16/24; G11C 11/406; G11C 11/4091; G11C 16/04; G11C 16/08; G11C 16/10; G11C 16/26; G11C 29/44

(52) U.S. Cl. CPC G11C 16/24; G11C 11/406; G11C 11/4091; G11C 16/0483; G11C 16/08; G11C 16/10; G11C 16/26; G11C 29/4401

(57) ABSTRACT

A memory system including a controller communicatively coupled to one or more memory devices is operable to provide improved one or more attributes, such as power, performance, latency, bandwidth, reliability, manufacturability, yield, cost, capacity, etc.

### RELATED APPLICATIONS

The present application claims priority to: Application Serial No.: 63/761,777, filed Feb. 21, 2025 under Docket Number SUR1P001+; Application Serial No.: 63/798,153, filed May 1, 2025 under Docket Number SUR1P002+; Application Serial No.: 63/798,166, filed May 1, 2025 under Docket Number SUR1P003+; and Application Serial No.: 63/929,604, filed Dec. 2, 2025 under Docket Number SUR1P004+; which are all incorporated herein by reference in their entirety for all purposes.

### BACKGROUND & FIELD OF THE INVENTION

Embodiments generally relate to memory devices and memory systems, where the memory devices include bit cells that are organized in rows and columns.

### SUMMARY

Systems, methods, and computer program products are provided for improving one or more attributes of memory devices and memory systems, wherein the attributes may include power, performance, latency, bandwidth, reliability, manufacturability, yield, cost, capacity, etc.

### BRIEF DESCRIPTION OF THE DRAWINGS

So that the features of the various embodiments can be understood, a more detailed description, briefly summarized above, may be had by reference to various embodiments, some of which are illustrated in the accompanying drawings. It is to be noted, however, that the accompanying drawings illustrate only embodiments and are therefore not to be considered limiting of the scope of the invention, for the invention may admit to other equally effective embodiments. The following detailed description makes reference to the accompanying drawings that are now briefly described.

FIG. 1 shows the schematics of a NAND Flash string.

FIG. 2 illustrates a program or write operation to a NAND Flash bit cell.

FIG. 3 shows the histogram of threshold voltages (V_{T}) of erased and programmed floating gate transistors or Flash bit cells.

FIG. 4 shows the read operation of a bit cell in NAND Flash string.

FIG. 5 shows the flow chart of a read operation of the least significant bit of a TLC bit cell.

FIG. 6 shows the flow chart of a read operation of the middle bit of a TLC bit cell.

FIG. 7 shows the flow chart of a read operation of the most significant bit of a TLC bit cell.

FIG. 8 illustrates a NAND Flash device with sixteen strings operating in parallel.

FIG. 9 illustrates a portion of a current art 3D NAND Flash device.

FIG. 10 shows a simplified view of a plane of a current art 3D NAND Flash device.

FIG. 11 illustrates a NAND Flash string in one embodiment.

FIG. 12 shows a simplified diagram of a plane of a 3D NAND Flash device of the embodiment of FIG. 11.

FIG. 13 illustrates a simplified diagram of a plane of a 3D NAND device of another embodiment.

FIG. 14 shows the simplified diagram of a plane of a 3D NAND Flash device in yet another embodiment.

FIG. 15 illustrates a memory system including a controller and a memory device.

FIG. 16 illustrates a memory system including a controller and a plurality of memory devices.

FIG. 17 shows a simplified block diagram of a DRAM device.

FIG. 18 illustrates a more detailed diagram of a DRAM bank containing a memory bit cell array of 16 rows and 16 columns.

FIG. 19 shows a simplified view of a read of a DRAM bit cell.

FIG. 20 illustrates a small segment of a current art DRAM array, where the segment includes 8 rows and 8 columns of bit cells.

FIG. 21 shows a segment of a DRAM array with 10 rows and 8 columns of bit cells in one embodiment.

FIG. 22 shows the mapping between row addresses and rows in a memory bank.

FIG. 23 shows the mapping between row addresses and rows in a memory bank in one embodiment.

FIG. 24 illustrates the row remap logic in one embodiment.

FIG. 25 shows the flow chart of the row remap process of the embodiment in

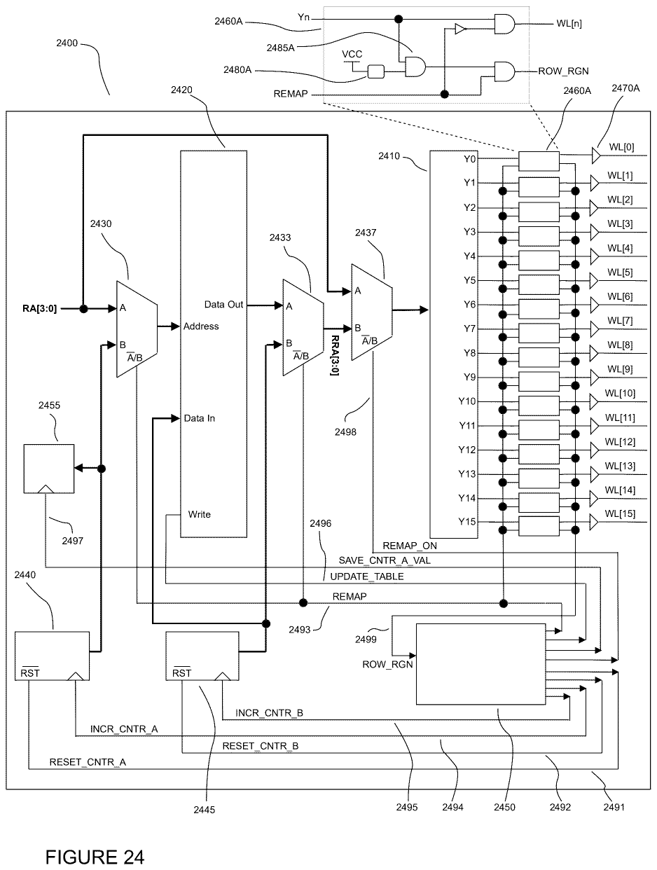

FIG. 24.

FIG. 26 illustrates the row remap logic in another embodiment.

FIG. 27 shows the flow chart of the row remap process of the embodiment in FIG. 26.

FIG. 28 illustrates the row remap logic in yet another embodiment.

FIG. 29 shows the flow chart of the row remap process of the embodiment in FIG. 28.

FIG. 30 shows the mapping between row addresses and rows in a memory bank of the embodiment in FIG. 28.

FIG. 31 illustrates the row remap logic in another embodiment.

FIG. 32 shows the flow chart of the row remap process of the embodiment in FIG. 31.

FIG. 33 illustrates the row remap logic of yet another embodiment.

FIG. 34 illustrates the row remap logic of another embodiment.

FIG. 35 shows the flow chart of the row remap process of the embodiment of FIG. 34.

FIG. 36 shows the mapping between row addresses and rows in a memory bank in yet another embodiment.

FIG. 37 illustrates a memory system including a controller and a memory device.

FIG. 38 shows a flow chart of the computer program product for configuring the memory device of FIG. 37 into multiple regions, equalizing the sizes of the regions, and operating the memory system with the multiple regions.

FIG. 39 shows the multiple regions of the memory device of FIG. 37 at three steps in the process shown in FIG. 38.

FIG. 40 illustrates a memory system including a controller and a plurality of memory devices.

FIG. 41 shows a flow chart of the computer program product for configuring each of the plurality of memory devices of FIG. 40 into multiple regions, equalizing the sizes of the regions, and operating the memory system with the multiple regions.

FIG. 42 shows the row remap logic in another embodiment.

FIG. 43 shows a simplified diagram of a DRAM bank that includes a plurality of memory array tiles (MATs).

FIG. 44 shows a simplified diagram of a DRAM bank that includes MATs with one row of bit cells and four columns (i.e. with one nibble of data).

FIG. 45 illustrates the column control circuit of the DRAM bank shown in FIG. 44.

FIG. 46 shows the mapping between the external column address and the 32 nibbles in some of the rows of the DRAM bank shown in FIG. 44.

FIG. 47 illustrates one embodiment of a DRAM bank wherein the repair is done at a granularity of a prefetch block.

FIG. 48 shows a more detailed diagram of the column control circuit of the DRAM bank shown in FIG. 47.

FIG. 49 illustrates the post-repair mapping between the external column address and the 32 nibbles in some DRAM rows of the embodiment of FIG. 47 and FIG. 48.

FIG. 50 shows another embodiment of a DRAM bank wherein the repair is done at a sub-prefetch block granularity.

FIG. 51 shows a more detailed diagram of the column control circuit of the DRAM bank shown in FIG. 50.

FIG. 52 illustrates the post-repair mapping between the external column address and the 32 nibbles in some DRAM rows of the embodiment of FIG. 50 and FIG. 51.

FIG. 53 shows yet another embodiment of a DRAM bank wherein the repair is done at a sub-prefetch block granularity.

FIG. 54 shows a more detailed diagram of the column control circuit of the DRAM bank shown in FIG. 53.

FIG. 55 illustrates the post-repair mapping between the external column address. and the 32 nibbles in some DRAM rows of the embodiment of FIG. 53 and FIG. 54.

FIG. 56 shows yet another embodiment of a DRAM bank wherein the repair is done at a sub-prefetch block granularity.

FIG. 57 shows a more detailed diagram of the column control circuit of the DRAM bank shown in FIG. 56.

FIG. 58 illustrates the post-repair mapping between the external column address. and the 32 nibbles in some DRAM rows of the embodiment of FIG. 56 and FIG. 57.

FIG. 59 shows a flow chart of the computer program product for a memory device to read or retrieve repair information, and store it in the memory device.

FIG. 60 shows another flow chart of the computer program product for a memory device in communication with an external device to read or retrieve repair information, and store it in the memory device.

FIG. 61 illustrates a flow chart of the computer program product for a memory device to perform scrubbing operations to generate and store repair information.

FIG. 62 shows a memory system including a controller and a memory device.

FIG. 63 illustrates a memory system including a controller and a plurality of memory devices.

FIG. 64 shows a flow chart of the computer program product for generating and storing the repair information for the memory device of FIG. 62 and/or the memory devices of FIG. 63 and the memory system operating with repaired memory devices.

FIG. 65 shows a portion of a DRAM array with 6 rows and 6 columns of bit cells.

FIG. 66 shows a simplified view of a DRAM bank with two regions in one embodiment.

FIG. 67 illustrates a simplified view of a DRAM bank with two regions in another embodiment.

FIG. 68 shows a simplified view of a DRAM bank with two regions in yet another embodiment.

FIG. 69 illustrates simplified view of a DRAM bank with two regions in a further embodiment.

FIG. 70 shows an embodiment of a row remapping logic block.

FIG. 71 illustrates the flow chart of one embodiment of a row remap process.

FIG. 72 shows the flow chart of one embodiment of a row map restore process.

FIG. 73 shows the flow chart of another embodiment of a row remap process.

FIG. 74 illustrates a simplified view of a DRAM bank with guard bands.

FIG. 75 shows a simplified view of a DRAM bank with group word lines and with guard bands.

FIG. 76 shows a simplified view of a DRAM bank that includes clamping transistors.

FIG. 77 illustrates an example layout of the embodiment of FIG. 76.

FIG. 78 shows a simplified view of a DRAM bank with remapping capability in another embodiment.

FIG. 79 illustrates a memory system including a controller and a plurality of memory devices, wherein the memory system has advanced ECC capability like Chipkill™.

FIG. 80 shows the row remap logic in yet another embodiment.

While the invention is susceptible to various modifications, combinations, and alternative forms, various embodiments thereof are shown by way of example in the drawings and will herein be described in detail. It should be understood, however, that the accompanying drawings and detailed description are not intended to limit the invention to the particular form disclosed, but on the contrary, the intention is to cover all modifications, equivalents and alternatives falling within the spirit and scope of the present invention as defined by the accompanying claims.

### DETAILED DESCRIPTION

Terms that are special to the field of various embodiments or specific to this description may, in some circumstances, be defined in this description. Further, the first use of such terms (which may include the definition of that term) may be highlighted in italics just for the convenience of the reader. Similarly, some terms may be capitalized, again for the convenience of the reader. It should be noted that the use of italics and/or capitalization, by itself, should not be construed as somehow limiting such terms: beyond any given definition, and/or to any specific embodiments disclosed herein, etc.

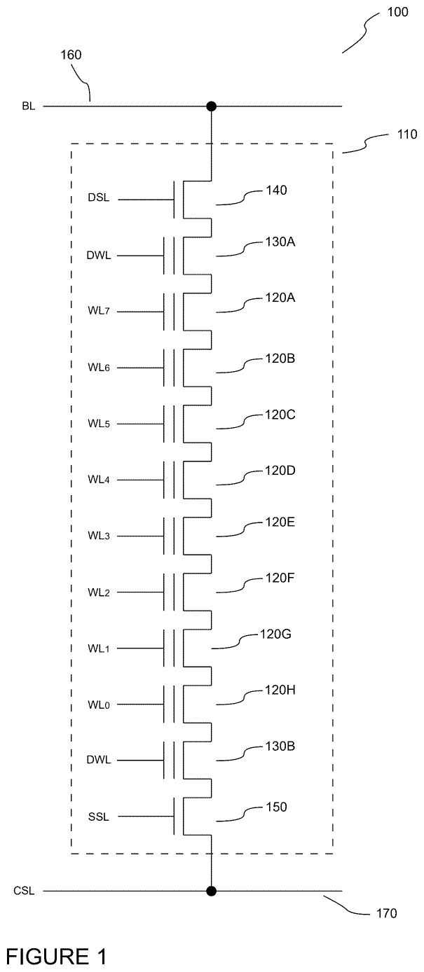

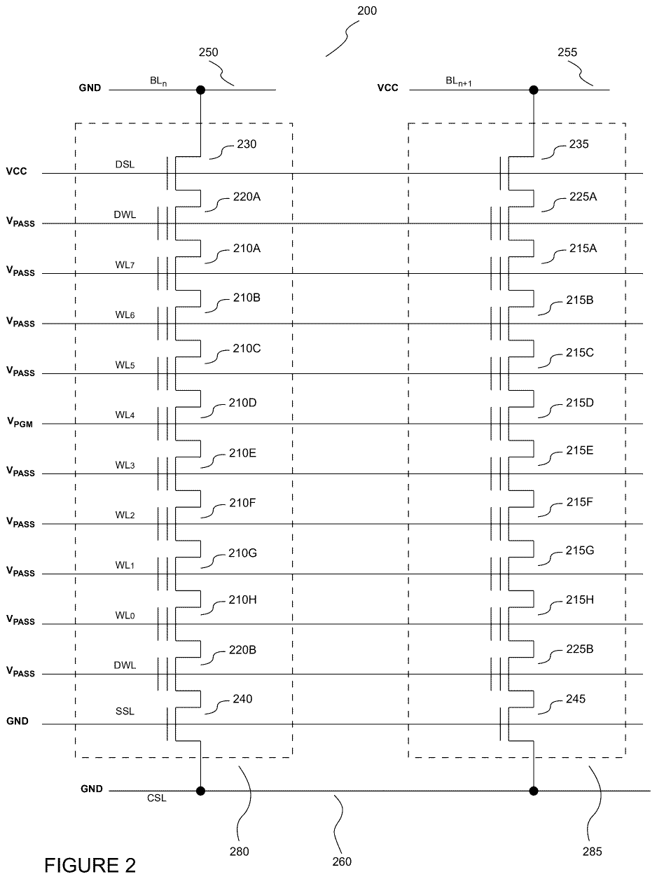

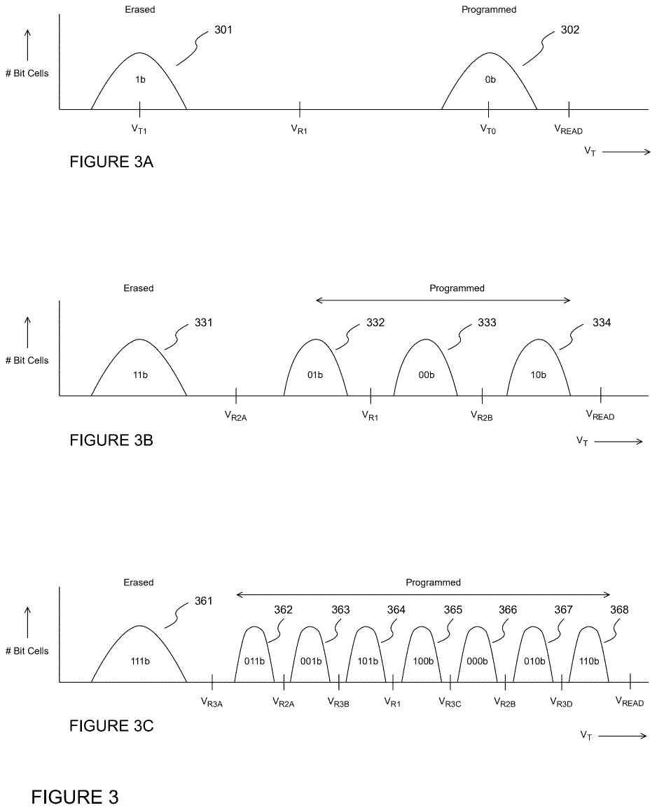

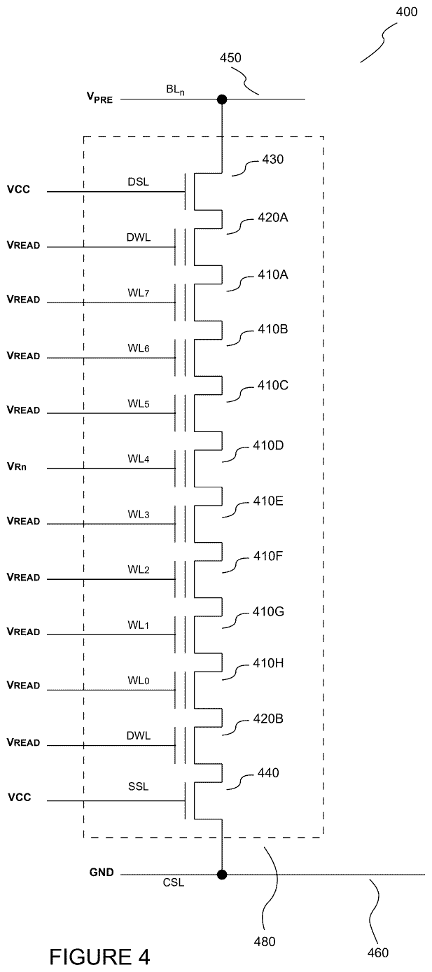

In this description, there may be multiple figures that depict similar structures with similar parts or components. Thus, as an example, to avoid confusion, an Object in FIG. 1 may be labeled “Object (1)” and a similar, but not identical, Object in FIG. 2 is labeled Object (2), etc. Furthermore, a figure may depict multiple instances of structures with similar parts or components. For example, multiple instances of an Object in FIG. 1 may be labeled “Object (1A)”, “Object (1B)”, “Object (1C)”, etc. Additionally, FIG. 2 may depict multiple instances of an Object, but only one instance may be labeled “Object (2)”. Furthermore, FIG. 3 may depict multiple instances of an Object, and only one instance may be labeled “Object (3A)”. It should be understood that the other instances may correspond to labels “Object (3B)”, “Object (3C)”, and so on. Also, FIG. 4 may depict multiple instances of an Object, but only few of the instances may be labeled as “Object (4A)”, and Object (4E)”. It should be understood that the other instances may correspond to labels “Object (4B)”, “Object (4C)”, and “Object (4D)” Again, it should be noted that the use of such protocol, by itself, should not be construed as somehow limiting such terms: beyond any given definition, and/or to any specific embodiments disclosed herein, etc. It should also be noted that not all parts or components in a figure may be labeled, to reduce clutter.

In this description, binary values are denoted by a b at the end of a numerical value. For example, 11b may denote a 2-bit binary number where both the bits are logic 1 (i.e. each bit is 1b).

In the following detailed description and in the accompanying drawings, specific terminology and images are used in order to provide a thorough understanding. In some instances, the terminology and images may imply specific details that are not required to practice all embodiments. Similarly, the embodiments described and illustrated are representative and should not be construed as precise representations, as there are prospective variations on what is disclosed that may be obvious to someone with skill in the art. Thus, this disclosure is not limited to the specific embodiments described and shown but embraces all prospective variations that fall within its scope. For brevity, not all steps may be detailed, where such details will be known to someone with skill in the art having benefit of this disclosure.

One embodiment focuses on improvements to memory systems and memory devices. While specific embodiments are described in the context of memory systems that may include DRAM devices and/or NAND Flash devices, it should be understood that various aspects may be applied to memory systems that include any type of memory device such as SRAM (Static Random Access Memory), FeRAM (Ferro-electric Random Access Memory), MRAM (Magnetic Random Access Memory), Field Write MRAM, Spin Torque Transfer (STT) MRAM, Memristor RAM, Resistor RAM (RRAM), Conductive-Bridging RAM (CBRAM), Silicon-Oxide-Nitride-Oxide-Silicon (SONOS) RAM, Twin-Transistor RAM (TTRAM), Thyristor-RAM (TRAM), synchronous graphics RAM (SCRAM), ZRAM (e.g. SOI RAM, Capacitor-less RAM, etc.), Phase Change RAM (PRAM or PCRAM, chalcogenide RAM, etc.), NOR Flash, etc., or any combination of such devices. In fact, aspects may be applied to any memory device, or combination of devices, whose bit cells are organized in rows and columns with associated word lines and bit lines respectively, and memory systems that include such memory devices.

Memory scaling introduces several challenges to memory device makers and memory system designers. Memory scaling enables memory device makers to increase the capacity (i.e. the number of bit cells) of the memory device. As memory capacity increases, the size of the memory array (of bit cells) increases. Larger memory arrays may typically operate at slower speeds. Although the minimum feature size may decrease with memory scaling, this may still not be able to compensate for the increase in the number of bit cells in the array. Hence, the performance of memory devices may not keep pace with the increase in memory capacity. Memory device designers and memory system designers may have to increase the prefetch size or operate more devices in parallel to ensure sufficient memory device and system performance.

Prefetching is a technique wherein the number of bits accessed in a read or write operation is more than the width of the external data I/O bus of the memory device. For example, for a memory device with 8 data I/O pins, a prefetch-of-4 implementation may result in 32 data bits in the memory array being accessed for each read or write operation. This may enable the data I/O pins to operate at 4 times the speed of the memory array.

Operating multiple memory devices in parallel may also increase the performance of the memory system. For example, if the system design requires 400 MB/s sequential read speed from a non-volatile memory system and a NAND Flash device is capable of 100 MB/s sequential read speed, system designers may operate 4 NAND Flash devices in parallel to achieve the desired sequential read performance. In systems that may not need large non-volatile memory capacity, the need for high performance may force an increase in the total non-volatile memory capacity, which increases the cost of the system.

As device geometries get smaller with scaling, more complex device fabrication processes may be required. For example, as DRAM device geometries become smaller with scaling, it may be increasingly difficult to reliably build the capacitor of the 1T-1C (one transistor-one capacitor) DRAM bit cell. In order to ensure sufficient data retention time and reliable read operation, DRAM manufacturers may typically target ~5 fF-10 fF as the capacitance of the bit cell's capacitor. As geometries become smaller, the aspect ratio of the bit cell capacitor may have to increase to ensure this desired capacitance. As mentioned, this may require complex fabrication process steps, and this may also impact the yield. For example, it may be difficult to guarantee that all the ~8.6×10⁹ bit cell capacitors in an 8Gb DRAM are structurally sound and have ~5 fF-10 fF of capacitance. A bit cell that is incapable of storing a bit, for example, due to a structurally defective capacitor, may typically be referred to as a bad bit cell.

Furthermore, memory fabrication process steps (and indeed, all semiconductor fabrication process steps) may be susceptible to variations (e.g. doping densities may vary). As device geometries get smaller with scaling, the variations may become larger. Thus, for example, the behavior or characteristics of memory device (e.g. DRAM) bit cells may fall within a distribution (e.g. Gaussian distribution). This may result in a situation where not all the bit cells in a memory device meet the desired specifications such as data access time (e.g. write latency, read latency), data retention, etc. In order to maximize yield (i.e. the percentage of memory devices that meet the published specification), manufacturers may now have to publish relaxed memory device specifications so as to ensure that all bit cells meet the published specifications even if many bit cells may be able to meet a higher performance specification. Hence, yield maximization may result in lower memory system performance. A bit cell that may not meet one or more of the published specifications (e.g. read latency, write completion time, retention time) may typically be referred to as a weak bit cell.

Some volatile memory bit cells (e.g. DRAM bit cells) may suffer from Variable Retention Time (VRT) phenomenon. Such cells may exhibit a plurality of retention times (i.e. a first retention time, a second retention time, etc.), and the retention time may change at arbitrary times. For example, a DRAM bit cell may normally have a retention time of 15 ms but at an arbitrary time, may exhibit a retention time of 2 ms, and later at another arbitrary time, may revert back to a retention time of 15 ms. It may be hard to predict which bit cell or bit cells may be susceptible to VRT during manufacturing testing at the factory, and it may be difficult to understand what operating conditions trigger such change in the retention time. Bit cells that exhibit VRT may also be considered as weak bit cells. As device geometries scale, more bit cells may exhibit this phenomenon.

To ensure that all bit cells in the device meet the published specifications, memory device manufacturers typically design memory devices (e.g. DRAM devices) with spare rows and spare columns of bit cells which may be used to replace rows of bit cells and/or columns of bit cells that either include defective bit cells or bit cells that do not meet the published specifications. This is commonly referred to as a repair process and is typically done in the factory.

As memory processes scale, there may be a higher probability of weak or bad bit cells being randomly distributed across the memory die. Furthermore, as device geometries shrink and bit cells become more closely spaced, a manufacturing defect may cause a cluster of bit cells to become weak or bad. For example, a manufacturing defect may cause five neighboring bit cells in each of three neighboring rows to be weak or bad. That is, a 5×3 matrix of bit cells may be weak or bad due to a manufacturing defect. Replacing an entire row or column of bit cells (that may include 8k or 16k bit cells) because the row or column may include a few, or even one or two, weak or bad bit cells may be wasteful. Such a repair mechanism may require manufacturers to include a large number of spare rows and spare columns in the memory device and thus, may increase the cost of a memory device.

Additionally, the pitch of the word lines and the bit lines in a memory device may decrease with scaling. For example, the minimum feature size of a DRAM device (typically referred to as F) in a 2x nm process may be between 20 nm and 29 nm, while F may be between 10 nm and 19 nm in a 1x nm process. In the case of a DRAM bit cell that is 6F² in size, the physical spacing between neighboring rows of bit cells may become smaller as F decreases. This may cause a disturbance in the charge stored in the bit cells of a row of cells when a neighboring row of bit cells is accessed (i.e. read or written). For example, when word line n is accessed (for a read, write, or refresh), the charge in the bit cells controlled by word lines n−1 and n+1, and possibly n−2 and n+2, may be disturbed. Repeated accesses of the same word line may cause sufficient disturbance that the (bit) values stored in one or more bit cells of the neighboring word lines may flip, or change, or become undifferentiable. For example, the value in a bit cell in a neighboring row may change from logic 1 to logic 0 or vice versa, or may be in an indeterminate logic state. Repeated accesses to the same row of bit cells may typically occur due to a malicious software program, and such an access pattern is commonly referred to as RowHammer or GPUHammer. There have been several reports of corruption of the data stored in DRAM-based memory systems when a malicious software program repeatedly accesses the same row of bit cells. For example, see https://thehackernews.com/2025/07/gpuhammer-new-rowhammer-attack-variant.html.

Various embodiments described herein may enable memory device designers to improve the manufacturability of volatile memory devices. This may provide one or more optional benefits to memory system designers in that DRAM scaling may continue to conform more or less with Moore's Law. The optional benefits may include lower cost, lower power, higher performance, higher manufacturing yield, simpler fabrication process, etc. While these embodiments described improvements to DRAM devices, this should not be construed as limiting this description to DRAM devices.

Other embodiments described herein may enable memory device designers to increase the performance of non-volatile memory devices. This may provide one or more optional benefits to memory system designers in that they may be able to achieve the desired memory system performance with fewer non-volatile memory devices. The optional benefits may include lower cost, lower power, higher manufacturing yield, simpler manufacturing or assembly process, smaller system form factor, etc. While various embodiments in this application describe improvements to NAND Flash devices, this should not be construed as limiting this description to NAND Flash devices.

Further embodiments described herein may enable system designers to maximize memory system performance while allowing DRAM manufacturers to achieve high yield. This may be done by configuring the DRAM device into multiple regions based on one or more aspects of the device. The configuration may be done after the device has been manufactured. Aspects include timing, latency, retention time, logic, power, performance, protocol, functionality, cost, etc. For example, the configuration may be done based on read latency. In this case, some bit cells may meet a read latency specification of p ns whereas other bit cells may meet a read latency specification of q ns, where p≠q. Thus, bit cells that meet a first (e.g. smaller) read latency specification may be grouped and assigned to a first region whereas bit cells that meet a second (e.g. longer) read latency specification may be grouped and assigned to a second region. In another example, the configuration may be done based on retention time, where bit cells that meet a first retention time specification are assigned to a first region and bit cells that meet a second retention time specification are assigned to a second region. In this case, the memory controller may refresh the first region of the memory device at a first refresh rate and refresh the second region of the memory device at a second refresh rate, thus reducing the power consumption of the memory device and memory system. In yet another example, the configuration may be done based on functionality. Fully functional bit cells may be assigned to a first region and partially functional or non-functional bit cells may be assigned to a second region. In a further example, bit cells that meet a first (e.g. low) bit error rate specification may be assigned to a first region while bit cells that meet a second (e.g. higher) bit error rate specification may be assigned to a second region. The configuration of the memory device into multiple regions may be done based on one or more aspects of each bit cell or may be done based on one or more aspects of a plurality of bit cells. Examples of a plurality of bit cells include a row of bit cells, a partial row of bit cells, a column of bit cells, a partial column of bit cells, a m×n array of bit cells where m and n are integers, a plurality of rows of bit cells (e.g. a set of b rows, where b is an integer, and b>1), a plurality of columns of bit cells (e.g. a set of d columns, where d is an integer, and d>1), etc. While various embodiments in this application describe configuring the memory device into multiple regions based on one or more aspects of a row of bit cells or a set of rows of bit cells, this should not be construed as limiting this description to assigning rows or sets of rows to the multiple regions.

In embodiments where the memory device is configured into multiple regions by assigning rows or sets of rows of bit cells to the regions, it may be advantageous to do the configuration in such a manner that the rows in a first region have consecutive row addresses, the rows in a second region have consecutive row addresses, the rows in a third region have consecutive row addresses, and so on, wherein the first row in the second region has a row address consecutive to that of the last row in the first region, the first row in the third region has a row address consecutive to that of the last row in the second region, and so on. For example, a first region may have consecutive row addresses 0 through q−1, a second region may have consecutive row addresses q through r−1, and a third region may have consecutive row addresses r through s−1, where q<r<s. Of course, in other embodiments, the regions may be interspersed. For example, a section of a first region may have consecutive row addresses p through q, a section of a second region may have consecutive row addresses q+1 through r, another section of a first region may have consecutive row addresses r+1 through s, another section of a second region may have consecutive row addresses s+1 through t, and a third region may have consecutive row addresses t+1 through u, where p<q<r<s<t<u.

Yet further embodiments described herein may enable memory device designers and manufacturers to repair, replace, or map out one or more bad or weak bit cells in each row. This may be done by providing extra bit cells in each row. The extra bit cells may be used for repair purposes, and optionally, may also be used to identify the location(s) of the weak or bad bit cells in that row. In other words, some of the extra bit cells in a row may be used to replace the weak or bad bit cells in that row, while some or all of the other extra bit cells may optionally be used to store the location of the weak or bad bit cells in that row. While various embodiments in this application describe repairing memory device at the level of rows, this should not be construed as limiting this description to performing the repair only at the level of rows. Additionally, while the repair schemes describe repairing DRAM devices, this should not be construed as limiting this description to DRAM devices.

Other embodiments described herein may enable memory device designers and manufacturers to map out rows with one or more bad or weak bit cells. This may be done by providing extra rows of bit cells in a memory array. The address of the rows to be mapped out may be stored by non-volatile means either in the memory device itself or external to the memory device. The memory device may then use this information to replace the rows with bad or weak cells with spare rows of bit cells. In some embodiments, rows with one or more bad or weak bit cells may be identified before or during run time, wherein the identification may be done by one or more DRAM devices, by one or more DRAM devices acting with one or more external logic devices, or by one or more external logic devices. Examples of external logic device may include a memory controller, a microprocessor, a central processing unit (CPU), an application processor, a graphics processor unit (GPU), an artificial intelligence processor (AI processor), a machine learning processor (ML processor), a tensor processing unit (TPU), an accelerated processing unit (APU), a network processing unit (NPU), an application specific integrated circuit (ASIC), a System-on-Chip (SoC), a field programmable gate array (FPGA), a CXL endpoint, a buffer, a register, a HBM logic die, a HMC logic die, an e.MMC controller, a UFS controller, a SATA SSD controller, a PCIe SSD controller, or any device that is capable of being in communication with a memory device. While such repair schemes are explained in the context of repairing DRAM devices, this should not be construed as limiting this description to DRAM devices.

Still further embodiments described herein may enable DRAM device designers and manufacturers to reduce or eliminate disturbance of stored data due to repeated accesses to one or more rows, thus improving the reliability of the DRAM device and also allowing memory system designers to maximize memory system performance. For example, these embodiments may enable memory device designers to harden the devices against malicious access patterns like RowHammer. This may provide one or more optional benefits to memory system designers in that, system level protections against malicious accesses may not be required at all or may require simpler schemes. The optional benefits may include lower cost, lower power, higher performance, less complex system design, etc. While these embodiments are described in the context of reducing or eliminating disturbance of stored data in DRAM devices due to repeated accesses to one or more rows of bit cells, this should not be construed as limiting this description to DRAM devices.

It should also be noted that while many of the embodiments described herein are described in the context of improvements to DRAM devices and NAND Flash devices, this should not be construed as limiting this description to DRAM devices and NAND Flash devices respectively. Furthermore, several of the embodiments described herein are described as being implemented only within a DRAM device or NAND Flash device, it should be noted that some of the functional elements may optionally be implemented in one or more external logic devices (e.g. logic die or layer, register, buffer, controller, processor, etc.) such that the one or more logic devices may act with one or more DRAM devices and/or NAND Flash devices to implement such embodiments.

FIG. 1 shows the schematics 100 of a NAND Flash string 110 of length 8, which includes a plurality of transistors connected in series between a Bit Line (BL) 160 and a Common Source Line (CSL) 170. As an option, any of the features of the present figure (and/or the description thereof) may be implemented in the context of the architecture and environment of any of the subsequent Figure(s). Of course, however, the system may be implemented in any desired environment.

The NAND Flash string includes transistor 140, whose gate may be connected to the Drain Select Line (DSL), floating gate transistors 120A-120H, whose gates may be connected to WL7 through WL0 respectively, two floating gate transistors 130A and 130B, whose gates may be connected to Dummy Word Line (DWL) signals, and transistor 150, whose gate may be connected to a Source Select Line (SSL) signal. Note that in some NAND devices, the floating gate transistors 120A-120H, 130A-130B, 140, and 150 may be replaced with transistors that include charge trap material(s). While the term “floating gate transistor” will be used throughout this description, it should be understood that this refers to transistors that either have a floating gate and a control gate or transistors that have charge trap material (in lieu of a floating gate) and a control gate. Each of the floating gate transistors 120A-120H may correspond to a bit cell in the NAND Flash device. Accordingly, floating gate transistor and bit cell may be used interchangeably in this description.

FIG. 2 shows the program (or write) operation 200 of a bit cell in a NAND Flash string. As an option, any of the features of the present figure (and/or the description thereof) may be implemented in the context of the architecture and environment of any of the previous Figure(s) and/or any of the subsequent Figure(s).

Two strings 280 and 285 are shown in this figure, which may be connected between BLₙ 250 and CSL 260, and BLₙ₊₁ 255 and CSL 260 respectively. Floating gate transistors 210D and 215D are to be programmed, to logic 0 and logic 1 respectively. To do this, DSL may be driven to VCC, DWL driven to V_{PASS}, WL[7:5] and WL[3:0] driven to V_{PASS}, SSL may be driven to GND, CSL may be driven to GND, and WL4 may be driven to VPGM. Since floating gate transistors 210D and 215D may be in the Erase state (i.e. programmed to logic 1), only the threshold voltage VTH of floating gate transistor 210D may need to be changed. Accordingly, BLₙ 250 may be driven to GND (to enable programming of transistor 210D) while BLₙ₊₁ 255 may be driven to VCC to inhibit programming of transistor 215D. Depending on the programming algorithm, one or more pulses of VPGM may be applied to WL4.

FIG. 3 shows the histogram of threshold voltages (V_{T}) of erased and programmed floating gate transistors. As an option, any of the features of the present figure (and/or the description thereof) may be implemented in the context of the architecture and environment of any of the previous Figure(s) and/or any of the subsequent Figure(s).

FIG. 3A shows the threshold voltages for SLC (i.e. single level cell or one bit per bit cell) bit cells. Erased bit cells may have lower threshold voltages 301 than programmed bit cells 302. By convention, erased bit cells may be represented as 1b (i.e. binary 1) and programmed bit cells may be represented as 0b (i.e. binary 0). V_{T1} and V_{T0} may represent the ideal threshold voltages of erased and programmed bit cells respectively. However, due to variations in the fabrication process (e.g. dopant concentration, size of polysilicon grain(s), presence of charge traps, variations in the dimensions of the floating gate transistors, oxide thickness variations, non-uniform etching, etc.), erased and programmed bit cells may have threshold voltages that are different from the ideal threshold voltages. Such variations may result in a distribution of threshold voltages around the ideal threshold voltages, as illustrated in FIG. 3A. For the sake of clarity, the ideal threshold voltages of the erased and programmed bit cells are not shown in FIG. 3B and FIG. 3C. FIG. 3B shows the threshold voltages for MLC (i.e. two bits per bit cell) bit cells. Erased bit cells may represent 11b (labeled as 331) and programmed bit cells may represent 01b, 00b, or 10b (labeled as 332, 333, and 334 respectively). FIG. 3C shows the threshold voltages for TLC (i.e. three bits per bit cell) bit cells. Erased bit cells may represent 111b (labeled as 361) and programmed bit cells may represent 011b, 001b, 101b, 100b, 000b, 010b, or 110b (labeled as 362 through 368 respectively). The logic values for the erased and programmed bit cells are shown strictly as an example. Many other mappings between the programmed bit cells and the logic values may be used. V_{R1}, V_{R2A}, V_{R2B}, V_{R3A}, V_{R3B}, V_{R3C}, and V_{R3D} are gate voltages that may be used to read the value of the bits stored in the bit cells.

FIG. 4 shows the read operation of a bit cell in NAND Flash string 480. As an option, any of the features of the present figure (and/or the description thereof) may be implemented in the context of the architecture and environment of any of the previous Figure(s) and/or any of the subsequent Figure(s).

As an example, assume that floating gate transistor (or bit cell) 410D was programmed with 2 bits per bit cell (i.e. MLC operation). So, one of the following values may be stored in the bit cell corresponding to floating gate transistor 410D: 11b, 01b, 00b, or 10b. By convention, the least significant bit (LSB) may be considered to be part of a lower page while the most significant bit (MSB) may be considered to be part of an upper page. First, bit line BLₙ may be pre-charged to a voltage V_{PRE} and CSL may be driven to GND. Then, the DSL and SSL signals may be driven to VCC, while DWL and WL[7:5] and WL[3:0] signals may be driven to V_{READ}. Now, to read the LSB of the value stored in floating gate transistor 410D, WL4 may be driven to V_{R1}. V_{READ} and V_{R1} are shown in FIG. 3B. If the LSB is 0b, then floating gate transistor 410D may be in the OFF state, and BLₙ may stay at V_{PRE}. If, on the other hand, the LSB is 1b, then floating gate transistor 410D may be in the ON state, and BLₙ may be pulled to GND. Reading the voltage of BLₙ after WL4 is driven to V_{R1} may determine the value of the LSB stored in floating gate transistor 410D. If the MSB is to be read, then the same steps described above may be done except that WL4 may be first driven to V_{R2A} and the voltage of BLₙ read. If the voltage of BLₙ may be GND or being pulled down to GND, then we may determine that the MSB is 1b. However, if voltage of BLₙ may stay at V_{PRE}, then the read operation may be repeated with WL4 driven to V_{R2B} (which is shown in FIG. 3B). If the BLₙ voltage may still be V_{PRE}, then the MSB may be determined to be 1b. But if the BLₙ voltage may be GND or being pulled down to GND, then the MSB may be determined to be 0b. Thus, for MLC bit cells, one of the two bits stored in a cell may be determined in a one-step read operation while the other bit may require two steps in the read operation.

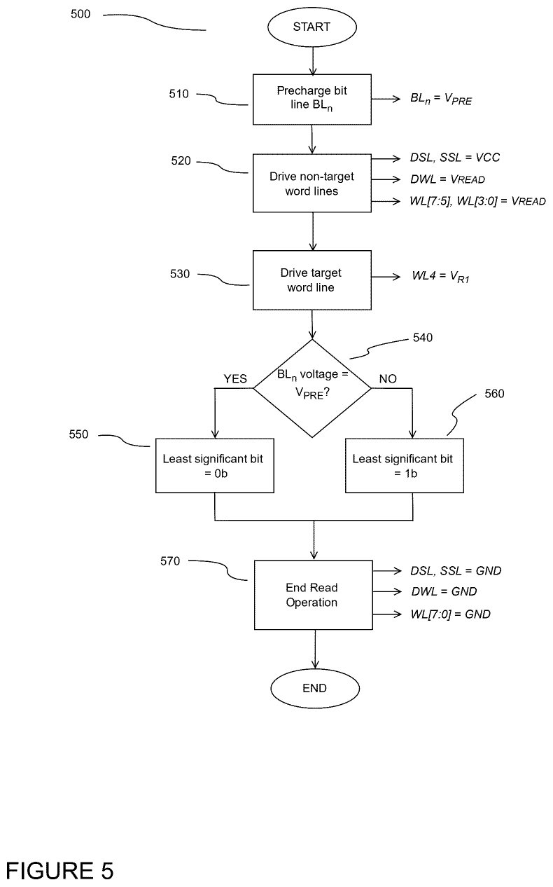

FIG. 5 shows the flow chart 500 of a read operation of the least significant (also referred to as the lower) bit of a TLC bit cell. As an option, any of the features of the present figure (and/or the description thereof) may be implemented in the context of the architecture and environment of any of the previous Figure(s) and/or any of the subsequent Figure(s).

As an example, assume that NAND Flash string 480 (see FIG. 4) is programmed with 3 bits per bit cell (i.e. TLC operation), and that bit cell 410D is the target of the read operation. In step 510, the bit line BLₙ 450 may be pre-charged to V_{PRE}. Then, in step 520, the DSL and SSL signals may be driven to VCC, and DWL, WL[7:5], and WL[3:0] may be driven to V_{READ}. Next, WL4 may be driven to V_{R1} in step 530 and the voltage of the bit line BLₙ 450 may be measured in step 540. If the voltage of bit line BLₙ 450 may still be V_{PRE}, then the LSB may be read as 0b in step 550. However, if the voltage of bit line BL 450 may be GND (or being pulled down to GND), then the LSB may be read as 1b in step 560. Then, DSL, SSL, DWL, WL[7:5], and WL[3:0] signals may be driven to GND in step 570 to end the read operation. V_{READ} and V_{R1} are shown in FIG. 3C. Although not shown in flow chart 500, CSL may be driven to GND during the read operation.

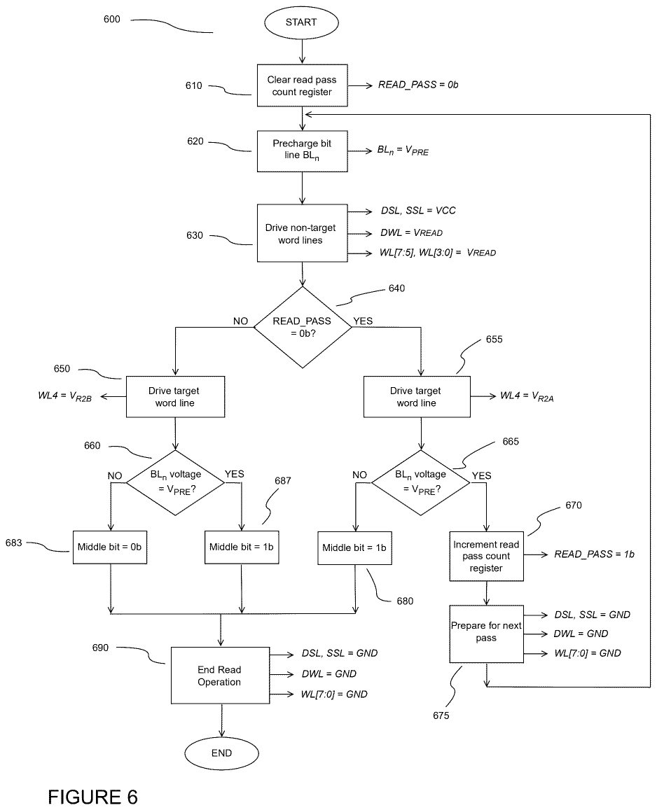

FIG. 6 shows the flow chart 600 of a read operation of the middle bit of a TLC bit cell. As an option, any of the features of the present figure (and/or the description thereof) may be implemented in the context of the architecture and environment of any of the previous Figure(s) and/or any of the subsequent Figure(s).

As before, and strictly as example, assume that NAND Flash string 480 (see FIG. 4) is programmed with 3 bits per bit cell (i.e. TLC operation), and that bit cell 410D is the target of the read operation. In step 610, an internal register READ_PASS may be set to 0b to indicate that this is the first pass through the read operation. Then, in step 620, the bit line BLₙ 450 may be pre-charged to V_{PRE}. Next, in step 630, the DSL and SSL signals may be driven to VCC, and DWL, WL[7:5], and WL[3:0] signals may be driven to V_{READ}. Then, in step 640, the value of READ_PASS register may be checked. If the value is 0b, WL4 may be driven to V_{R2A} in step 655, and the voltage of bit line BLₙ 450 may be measured in step 665. If the voltage of bit line BLₙ 450 may be GND (or being pulled down to GND), the middle bit may be read as 1b in step 680, and the operation flow may jump to step 690 to end the read operation. But, if the voltage of bit line BLₙ 450 may be V_{PRE}, the internal register READ_PASS may be incremented to 1b in step 670. Then, preparations for the next pass through the read operation may be done in step 675 by driving DSL, SSL, DWL, and WL[7:0] word lines to GND. Then, the operation flow may jump to step 620. Now, in this pass, the test in step 640 may return a mismatch (i.e. indicate that this is the second pass through the read operation), and WL4 may be driven to V_{R2B} in step 650. Then, the voltage on bit line BLₙ 450 may be measured in step 660. If the voltage may be GND (or being pulled down to GND), then the middle bit may be read as 0b in step 683. But, if the voltage may be V_{PRE}, then the middle bit may be read as 1b in step 687. After the middle bit has been read, the operation flow may move to step 690, where the read operation may be ended by driving DSL, SSL, DWL, and WL[7:0] signals to GND. V_{READ}, V_{R2A}, and V_{R2B} are shown in FIG. 3C. Other implementations are possible. For example, in the first pass through the read operation, WL4 may be driven to V_{R2B} in step 655 and the voltage of bit line BLₙ 450 may be compared with GND in step 665. Then, in the second pass through the read operation, WL4 may be driven to V_{R2A} in step 650. Although not shown in flow chart 600, CSL may be driven to GND during the read operation.

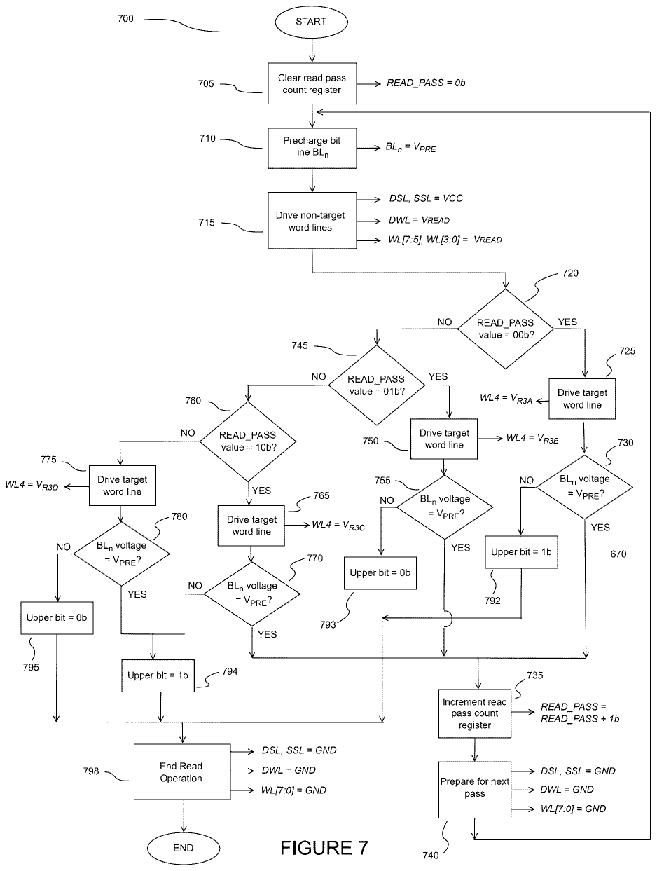

FIG. 7 shows the flow chart 700 of a read operation of the most significant (also referred to as the upper) bit of a TLC bit cell. As an option, any of the features of the present figure (and/or the description thereof) may be implemented in the context of the architecture and environment of any of the previous Figure(s) and/or any of the subsequent Figure(s).

As before, and again as example, assume that NAND Flash string 480 (see FIG. 4) is programmed with 3 bits per bit cell (i.e. TLC operation), and that bit cell 410D is the target of the read operation. An internal register READ_PASS may be set to 0b in step 705. Then, bit line BLₙ 450 may be pre-charged to V_{PRE} in step 710, and in step 715, DSL and SSL signals may be driven to VCC, and DWL, WL[7:5], and WL[3:0] may be driven to V_{READ}. Then, the value of READ_PASS may be checked in step 720. If the value may be 00b (i.e. this is the first pass through the read operation), WL4 may then be driven to V_{R3A} in step 725, and the voltage of the bit line BLₙ 450 may be compared with V_{PRE} in step 730. If the voltage may be GND (or being pulled down to GND), the upper bit may be read as 1b in step 792 and operation flow may move to step 798 to end the read operation. However, if the comparison in step 730 may result in a match, the READ_PASS register may be incremented (to 01b) in step 735, and preparations for the next pass through the read operation may be done in step 740 by driving DSL, SSL, DWL, and WL[7:0] signals to GND. Then, operation flow may jump to step 710, and the next pass through the read operation may be done. In this pass, the test in step 720 may return a mismatch, so READ_PASS may be compared to 01b in step 745. This may return a match in the second pass, so WL4 may be driven to V_{R3B} in step 750, and the voltage of bit line BLₙ 450 may be compared with V_{PRE} in step 755. If the comparison may return a mismatch (i.e. bit line voltage is GND or being pulled down to GND), the upper bit may be read as 0b in step 793 and operation flow may move to step 798 to end the read operation. But if the comparison may return a match (i.e. bit line voltage is still at V_{PRE}), the READ_PASS register may be incremented (to 10b) in step 735, preparations for the next pass may be done in step 740 by driving DSL, SSL, DWL, and WL[7:0] to GND, and operation flow may return to step 710. Now, in this pass, the comparison in both steps 720 and 745 may return a mismatch, so operation flow may go to step 760. The comparison in this step may return a match (this being the third pass), so WL4 may be driven to V_{R3C} in step 765 and the voltage of bit line BLₙ 450 may be compared with V_{PRE} in step 770. If the bit line voltage may be GND or being pulled down to GND, then the upper bit may be read as 1b in step 794 and operation flow may move to step 798. But if the bit line voltage may still be V_{PRE} in step 770, then READ_PASS may be incremented (to 11b) in step 735, preparations for the next pass may be done in step 740 by driving DSL, SSL, DWL, and WL[7:0] to GND, and operation flow may return to step 710 for the last pass through the read operation. In the fourth and last pass, the comparison in steps 720, 745, and 760 may all return a mismatch, so operation flow may move to step 775. In this step, WL4 may be driven to V_{R3D}, and the voltage of bit line BLₙ 450 may be compared to V_{PRE} in step 780. If the comparison returns a match, the upper bit may be read as 1b in step 794. But if the comparison returns a mismatch, the upper bit may be read as 0b in step 795. Finally, operation flow may move to step 798, where the read operation may be ended by driving DSL, SSL, DWL, and WL[7:0] to GND. V_{READ}, V_{R3A}, V_{R3B}, V_{R3C}, and V_{R3D} are all shown in FIG. 3C. Note that in flow chart 700, the upper bit value is determined by progressively moving the voltage of WL4 from V_{R3A} to V_{R3B} to V_{R3C} to V_{R3D} and testing the voltage of bit line BLₙ 450 at each pass. This sequence is an example. Other sequences may be used. For example, the voltage of WL4 may be set to V_{R3D}, V_{R3C}, V_{R3B}, and V_{R3A} in the first, second, third, and fourth passes respectively and the upper bit value may be determined based on the voltage of bit line BLₙ 450 in each of the passes. Although not shown in flow chart 700, CSL may be driven to GND during the read operation.

It can be seen from the flow chart 500 in FIG. 5 (and flow charts 600 and 700 in FIG. 6 and FIG. 7 respectively) that a read of a bit cell may involve finding the smallest gate voltage that may turn on the floating gate transistor corresponding to the bit cell being read. All the other transistors in the string may be on during the entire read operation. When the floating gate transistor corresponding to the bit cell being read is turned on, a conductive path may be established between the pre-charged bit line and CSL, which may cause the bit line voltage to be pulled down to GND.

Although many of the previous figures have illustrated one or two NAND Flash strings, typical NAND Flash devices may be organized to operate a plurality of strings in parallel.

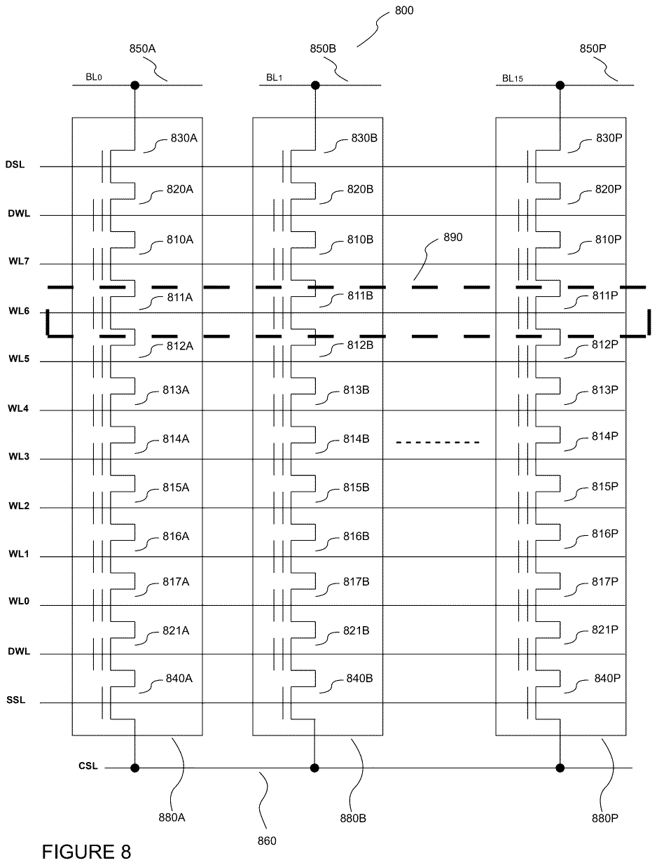

FIG. 8 illustrates a NAND Flash device 800 with sixteen strings 880A-880P operating in parallel. As an option, any of the features of the present figure (and/or the description thereof) may be implemented in the context of the architecture and environment of any of the previous Figure(s) and/or any of the subsequent Figure(s).

It should be noted that a typical NAND Flash device may have thousands of strings operating in parallel and device 800 is shown with sixteen strings in parallel strictly as an example. Each of the strings 880A-880P may be connected to one dedicated bit line of the 16 bit lines 850A-850P, and to CSL (common source line) signal. Furthermore, string 880A may include a transistor 830A that may be controlled by the DSL (drain select line) signal, two floating gate transistors 820A and 821A that may be controlled by the DWL (dummy word line) signal, eight floating gate transistors 810A-817A that may store bits and be controlled by the WL[7:0] signals respectively, and transistor 840A that may be controlled by the SSL (source select line) signal. Strings 880B-880P may include transistors similar to those described above for string 880A. Each of the word lines WL[7:0] may correspond to a page, an example of which is labelled 890 in the figure. Since NAND Flash device 800 is shown with sixteen strings in parallel, device 800 may be said to have a page (example, page 890) size of sixteen. That is, the number of strings operated in parallel is commonly referred to as the page size. With respect to device 800, in the case of SLC operation, a page of sixteen bits may be stored in the floating gate transistors controlled by a common word line (e.g. WL6). In the case of MLC operation, two pages (e.g., lower page and upper page) of sixteen bits each may be stored in the floating gate transistors controlled by a common word line, and in the case of TLC operation, three pages (e.g. lower page, middle page, and upper page) of sixteen bits each may be stored in the floating gate transistors controlled by a common word line. As mentioned previously, typical NAND Flash devices may have page sizes of 2 KB or higher.

In an example 3D NAND Flash manufacturing process, alternate layers of silicon oxide and silicon nitride may be deposited on a wafer. Then, multiple memory holes (MHs) may be etched, polysilicon may be deposited in the MH, and then completely filled with the filler material (e.g. silicon oxide). Next, vertical slits may be etched so as to create “islands” of alternating silicon oxide and silicon nitride layers, and MHs. Then, the silicon nitride layers may be removed by a chemical process (e.g., etching), resulting in the layers of silicon oxide separated from the neighboring layers by voids. Next, a layer of tunneling oxide may be deposited in the voided areas, followed successively by depositions of charge trap material, and blocking oxide (e.g. a high-K dielectric material). Then, the remaining gaps in the structure (i.e. the space between the silicon oxide layers) may be filled with a conducting material (e.g. Tungsten), which may then act as the gates of the floating gate transistors in the NAND Flash string. In the final steps of the fabrication process, bit lines may be connected to the polysilicon channels of the strings and associated sense amplifiers. This fabrication process flow is referred to as the Gate Last process, since the transistor gates are fabricated towards the end of the fabrication process. It should be noted that the fabrication process described above is a simplified example. Each Flash manufacturer may have a proprietary fabrication process that may differ from the example fabrication process described above, and may include many more steps.

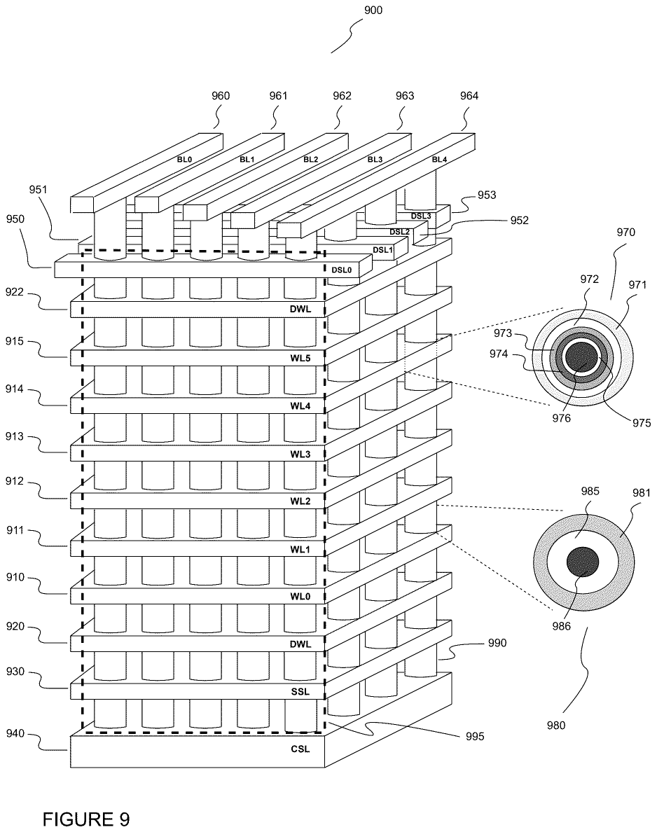

FIG. 9 illustrates a portion of a current art 3D NAND Flash device 900. As an option, any of the features of the present figure (and/or the description thereof) may be implemented in the context of the architecture and environment of any of the previous Figure(s) and/or any of the subsequent Figure(s).

Note that this figure is not to scale and certain dimensions may be exaggerated or reduced for clarity. The portion of the 3D NAND Flash Device shown in FIG. 9 may include a plurality of memory holes (MH), one of which is labelled 990 in the figure. It should be mentioned that each memory hole may correspond to a string. Each of the MHs or strings may be connected to one of the bit lines 960-964. Each string may include two dummy word lines (DWL) 920 and 922, six word lines WL[5:0] 910-915. The MHs may be surrounded by alternate layers of conducting material and insulating material, where the conducting material acts as the word lines (i.e. the gates of the floating gate transistors) and the insulating material provides isolation between the word lines. In other words, the insulating material isolates each floating gate transistor in the string from its neighbors. Note that only the conducting material is shown in this figure to better illustrate the structure of a 3D NAND Flash device. It should be understood that the insulating material may be present in the voids between the word lines.

The cross-section 970 of a memory hole in a layer of conducting material is shown on the right in FIG. 9. As mentioned previously, the MH surrounded by conducting material may act as a floating gate transistor capable of storing one or more bits of data. The MH (e.g. 990) may include concentric layers of conducting material (e.g. Tungsten) 971, blocking oxide 972, charge trap material 973, tunneling oxide 974, polysilicon 975, and filler material (e.g. silicon oxide) 976. The polysilicon layer 975 may act as the channel for the floating gate transistor. The tunneling oxide layer 974 may enable electrons to tunnel between the polysilicon layer 975 and the charge trap layer 973, which as the name implies, may trap the electrons that tunnel from the polysilicon layer. The blocking oxide layer 972 may act to electrically isolate the gate of the floating gate transistor from the MH. In this example, the gate of the floating gate transistor may correspond to the layer of conducting material 971.

The cross-section 980 of a memory hole in a layer of insulating material is also shown on the right in FIG. 9. As described previously, the MH, when surrounded by insulating material, may act to isolate a floating gate transistor from the neighboring floating gate transistors that may be connected in series. The MH (e.g. 990) may include concentric layers of insulating material (e.g. silicon oxide) 981, polysilicon 985, and filler material (e.g. silicon oxide) 986.

FIG. 9 illustrates a 3D NAND Flash device 900 with four DSL signals, DSL [3:0] 950-953. Each DSL may connect a plurality of MHs to the bit lines. The set of MHs that may be connected to the bit lines through a DSL is commonly referred to as a sub-block, one of which is labelled as 995 in this figure. Furthermore, all the sub-blocks controlled by common word lines are typically referred to as a block. Accordingly, FIG. 9 illustrates a block with four sub-blocks, with each sub-block connecting to the bit lines by one of four DSL signals DSL [3:0].

It should also be noted that the 3D NAND Flash illustrated in FIG. 9 is just one example. Several other implementations are possible. For example, the 3D NAND Flash device 900 is shown with a common SSL (source select signal) for all the MHs (or sub-blocks) in the figure. A different implementation may be possible, where a plurality of SSLs may be used such that each DSL has an associated SSL. In other words, each sub-block may have dedicated DSL and SSL signals.

A q-layer terminology is commonly associated with 3D NAND Flash devices, where q is a positive integer. This term (i.e. “q-layer” or “q layers”) is commonly understood to mean that the device includes q layers of conducting material (e.g. Tungsten), wherein a floating gate transistor (or bit cell) may be present at each intersection of an MH with a layer of conducting material. Alternately, “q-layer or q layers” may also mean that each string in the device has q floating gate transistors that may be capable of storing bits. The layers corresponding to dummy word lines or to other non-storage signals (e.g. DSL or drain select line) are typically not included in the layer count. Similarly, the layers of insulating material (e.g. silicon oxide) are not included in the layer count.

When the Flash industry transitioned from 2D fabrication to 3D fabrication, the number of vertical layers (i.e. transistors) in the string was 32, 48, or 64. In such cases, the MH was etched in a single step. However, as 3D fabrication matured, Flash manufacturers increased the layer count as a means of scaling the capacity of Flash devices. Newer generations of 3D NAND Flash devices may have 128, 192, or more layers. As layer count increases, it becomes increasingly challenging to etch the MH in a single step. As a result, NAND Flash manufacturers typically use a multi-step etch process, in which smaller sections of the string are fabricated on top of each other and connected. To illustrate, let us assume a 192-layer string, a 2-step etch process, and the example fabrication process described above. In a first step, 96 layers of silicon oxide and 96 layers of silicon nitride may be alternately deposited on the NAND Flash wafer. Then, a MH may be etched. Next, the silicon nitride layers may be removed by chemical process and successive depositions of tunneling oxide, charge trap material, and blocking oxide may be done. Finally, conducting material (e.g. Tungsten) may be deposited between the layers of silicon oxide and may act as the gate of the floating gate transistors in the string. At this stage, half of the 192-layer string may have been fabricated. Then, the whole process may be repeated in a second step to fabricate the remaining half of the 192-layer string, taking care to align and connect the MH etched in the second step with the MH etched in the first step. The MH etched in the first step may typically be called the lower memory hole (LMH or lower MH) and the MH etched in the second step may typically be called the upper memory hole (UMH or upper MH). It should also be noted that the LMH may be connected to the Common Source Line (CSL) and that the UMH may be connected to a Bit Line (BL), which may enable the LMH and the UMH to be operable as a single string, connecting to a BL and the CSL at the ends respectively. In other words, the string (i.e. LMH and UMH) in a current art NAND Flash device may be operable to perform a single read operation, or a single write (i.e. program) operation, or a single erase operation at a given time. And as described previously, a single read operation or a single write operation in a p-layer current art NAND Flash device may require various signals to pass through p floating gate transistors (and other transistors).

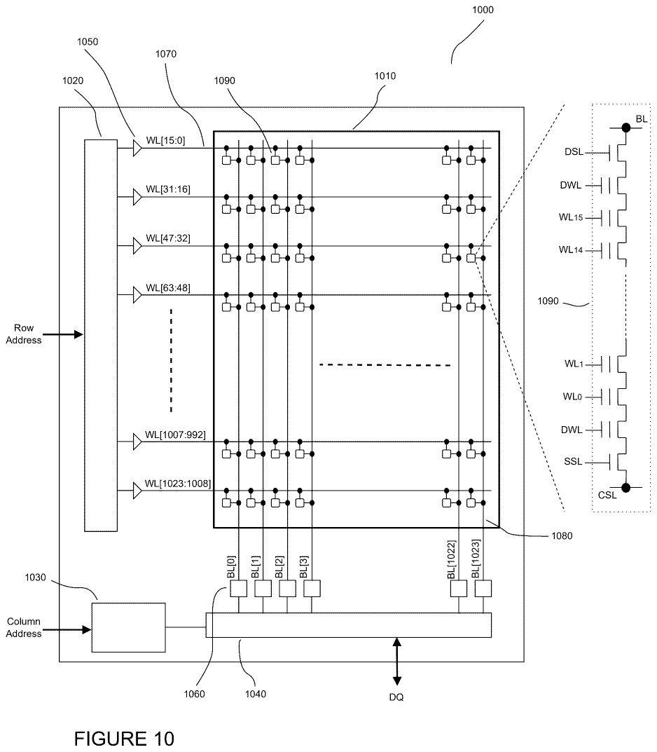

FIG. 10 shows a simplified view of a plane 1000 of a current art 3D NAND Flash device. As an option, any of the features of the present figure (and/or the description thereof) may be implemented in the context of the architecture and environment of any of the previous Figure(s) and/or any of the subsequent Figure(s).

A plane is the commonly used term to denote a portion of a NAND Flash device that may be addressed uniquely and be the target of read, write (i.e. program), and erase operations. It may be equivalent to the bank of a DRAM device. As shown, plane 1000 may include an array of NAND Flash strings 1010, a row address decoder 1020, a column address decoder 1030, column selection logic 1040, a plurality of word line drivers (one of which is labeled 1050), a plurality of sense amplifiers (one of which is labeled 1060), a plurality of word lines (one of which is labeled 1070), a plurality of bit lines (one of which is labeled 1080), and a plurality of NAND Flash strings (one of which is labeled 1090). A simplified schematics of a NAND Flash string 1090 is shown on the right side. Plane 1000 is shown with 1024 word lines and 1024 bit lines strictly as an example. A plane of a current art NAND Flash device may have 32K or more word lines and 16K or more bit lines. Plane 1000 may support only one read or write (i.e. program) operation at any given time as these operations may require the use of the bit lines and plane 1000 includes only one set of bit lines.

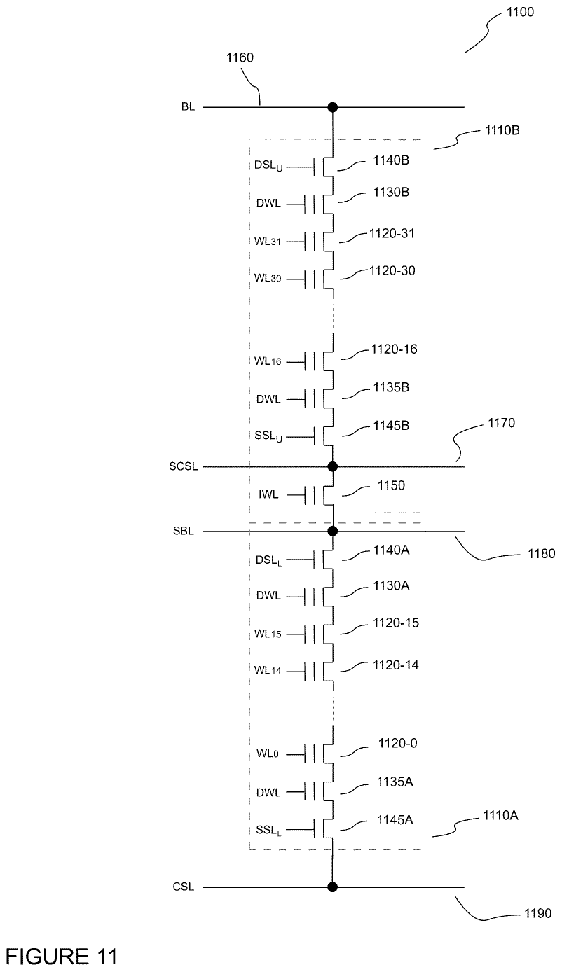

In one embodiment, a secondary common source line (SCSL) and a secondary bit line (SBL) may be used per string to optionally improve read or write performance of a NAND Flash device. Such an example string is shown in FIG. 11, wherein the string 1100 includes a lower memory hole (LMH) 1110A and an upper memory hole (UMH) 1110B, bit line BL 1160, and CSL (common source line) 1190. As shown, LMH 1110A may include SBL signal 1180, transistor 1140A (controlled by the lower drain select line signal DSL_{L}), floating gate transistors 1130A and 1135A (controlled by dummy word line signal DWL), floating gate transistors 1120-0 through 1120-15 (controlled by WL0 through WL15 signals respectively), and transistor 1145A (controlled by lower source select line signal SSL_{L}). Also, as shown, UMH 1110B may include transistor 1140B (controlled by upper drain select line signal DSL_{U}), floating gate transistors 1130B and 1135B (controlled by dummy word line signal DWL), floating gate transistors 1120-16 through 1120-31 (controlled by WL16 through WL31 signals), transistor 1145B (controlled by upper source select line signal SSL_{U}), SCSL signal 1170, and floating gate transistor 1150 (controlled by isolation word line signal IWL). Note that string 1100 is shown with 32 floating gate transistors (1120-0 through 1120-31) capable of storing bits strictly as an example. Current art NAND Flash devices may have strings with 128 or more floating gate transistors capable of storing bits.

While it may be advantageous to fabricate the SBL as part of the first etch in, say, a two-step etch process, and fabricate the IWL (isolation word line) floating gate transistor and the SCSL as part of the second etch in a two-step etch process, other processes, methodologies, or structures may be used to fabricate the secondary bit line (SBL), the secondary source select line (SCSL), and the isolating floating gate transistor 1150.

In operation, the isolation floating gate transistor 1150 may be used to separate string 1100 into two sub-strings 1110A and 1110B, and isolate the sub-strings from each other. Then, an external controller (e.g. memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, e.MMC controller, UFS controller, SATA SSD controller, PCIe SSD controller, or any device that is capable of being in communication with a NAND Flash device) may direct an operation (e.g. read) to the sub-string 1110A, while directing another operation (e.g. read) to the sub-string 1110B at the same time or at overlapping times. As described previously, a read of, say, floating gate transistors 1120-14 may include finding the lowest gate voltage (on WL14) that causes floating gate transistor 1120-14 to turn on and cause a discharge path between SBL and CSL. Similarly, a read of, say, floating gate transistor 1120-16 may include finding the lowest gate voltage (on WL16) that causes floating gate transistor 1120-16 to turn on and cause a discharge path between BL and SCSL. As can be seen from FIG. 11, if the isolation floating gate transistor 1150 be in the OFF state, then the read operations to floating gate transistors 1120-14 and 1120-16 may occur at the same time or may overlap in time without one operation affecting the other.

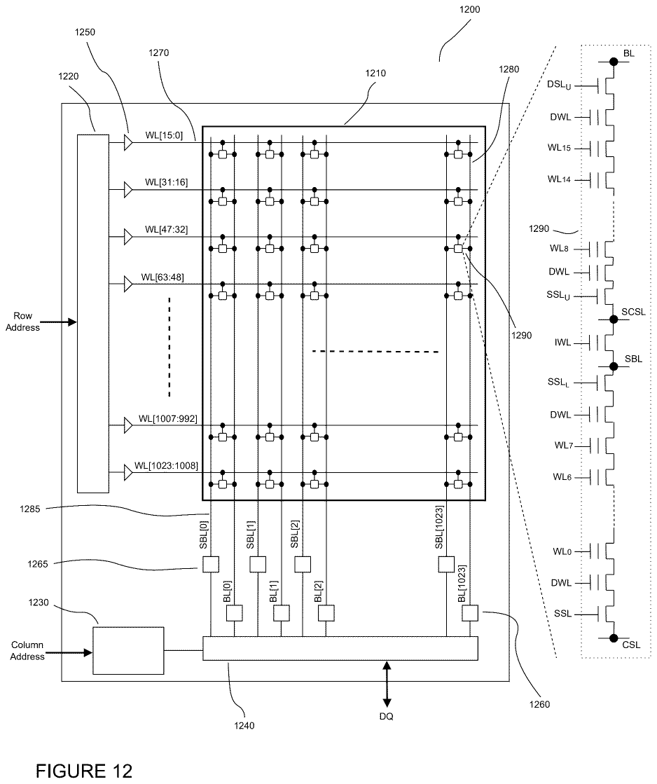

FIG. 12 shows a simplified diagram of a plane 1200 of a 3D NAND Flash device, wherein each string may include a secondary source select line signal (SCSL), an isolation floating gate transistor, and a secondary bit line (SBL) as illustrated in FIG. 11. As an option, any of the features of the present figure (and/or the description thereof) may be implemented in the context of the architecture and environment of any of the previous Figure(s) and/or any of the subsequent Figure(s).

In other embodiments, isolation floating gate transistor 1150 of FIG. 11 may not be fabricated, which may enable sub-strings 1110A and 1110B to function as independent strings. In such embodiments, there may not be a need to accurately align the memory holes or strings 1110A and 1110B.

Plane 1200 includes an array of strings 1210, row address decoder 1220, column address decoder 1230, column selection logic 1240, a plurality of word line drivers (one of which is labeled 1250), a first set of sense amplifiers 1260, a second set of sense amplifiers 1265, a plurality of word lines (one of which is labeled 1270), a first set of bit lines BL[1023:0] (one of which is labeled 1280), and a second set of bit lines SBL[1023:0] (one of which is labeled 1285). Array 1210 may include a plurality of strings, one of which is labeled 1290 and is shown expanded on the right side of FIG. 12.

As can be seen in FIG. 12, plane 1200 includes two sets of bit lines, BL[1023:0] and SBL[1023:0], and two sets of sense amplifiers. Thus, plane 1200 may be capable of performing two operations (e.g. read, write or program, etc.) in parallel or overlapping in time.

In current art NAND Flash devices and in the NAND Flash device embodiment shown in FIG. 11 and FIG. 12, each of the bit lines (and optionally, each of the secondary bit lines) may connect to all the corresponding strings in the array. For example, in an array of m rows of strings and n strings per row, bit line 0 (and optionally, secondary bit line 0) may connect to the first string in each of the m rows (i.e. to string 0 in each of the rows), bit line 1 (and optionally, secondary bit line 1) may connect to the second string in each of the m rows (i.e. to string 1 in each of the rows), and so on, and bit line n−1 (and optionally, secondary bit line n−1) may connect to the last string in each of the m rows (i.e. to string n−1 in each of the rows).

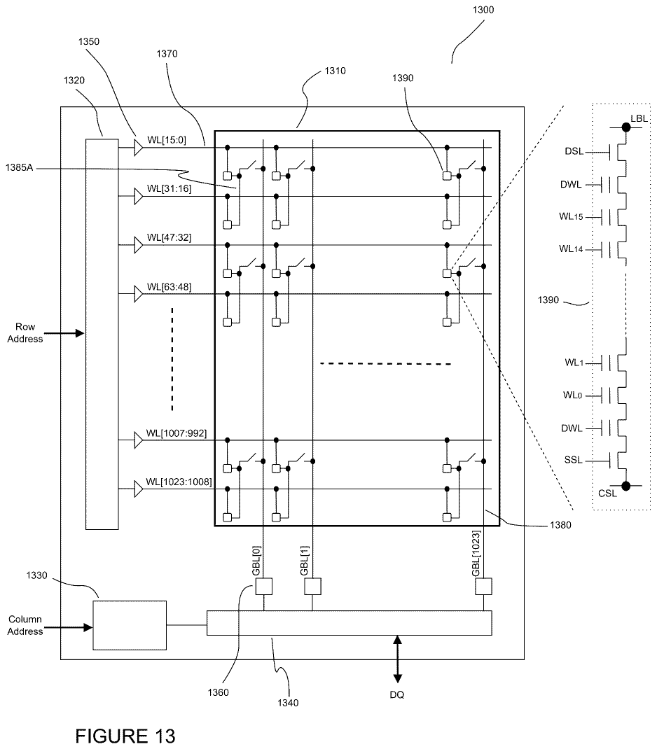

In another embodiment, a NAND Flash device may include a plurality of sets of local bit lines and a set of global bit lines. This is illustrated in FIG. 13, which shows a simplified diagram of a NAND plane 1300 of this embodiment. As an option, any of the features of the present figure (and/or the description thereof) may be implemented in the context of the architecture and environment of any of the previous Figure(s) and/or any of the subsequent Figure(s).

Plane 1300 may include an array 1310 of NAND Flash strings, row address decoder 1320, column address decoder 1330, column selection logic 1340, plurality of word line drivers (one of which is labeled 1350), a plurality of sense amplifiers (one of which is labeled 1360), plurality of word lines (one of which is labeled 1370), plurality of global bit lines (one of which is labeled 1380), and a plurality of groups of local bit lines (one of which is labeled 1385A). Array 1310 may include a plurality of bit strings, one of which is labeled 1390 and is shown expanded on the right side of FIG. 13.

Each group of local bit lines may be connected to the group of global bit lines through switches (e.g. transistors). The switches may be controlled by the row address decoder such that a particular group of local bit lines may be connected to the global bit lines when a row connected to that particular local bit lines may be the target of an operation (e.g. read). Note that the control signals for such switches are not shown in FIG. 13. Also note that FIG. 13 shows two rows of strings sharing a local bit line. This is strictly as an example. The number of rows assigned to a set of local bit lines is a design choice and any number of rows may be connected to common local bit lines.

Strictly as an example, say that WL20 is the target of a read operation. As shown, WL20 is connected to the group of local bit lines 1385A. Then, the group of local bit lines 1385A may be connected to the global bit lines while all the other groups of local bit lines may be isolated from the global bit lines. Then, the global bit lines 1380 and the local bit lines 1385A may be precharged to the voltage V_{PRE}, WL[31:21] and WL[19:16] may be driven to voltage V_{READ}, DWL signals of the second row of strings in array 1310 may be driven to voltage VCC or V_{READ}, the DSL and SSL signals of the second row of strings in array 1310 may be driven to VCC, CSL may be driven to GND, and the minimum threshold voltage required to turn on floating gate transistors controlled by WL20 may be determined using the example read operation flow chart illustrated in FIG. 5, FIG. 6, or FIG. 7.

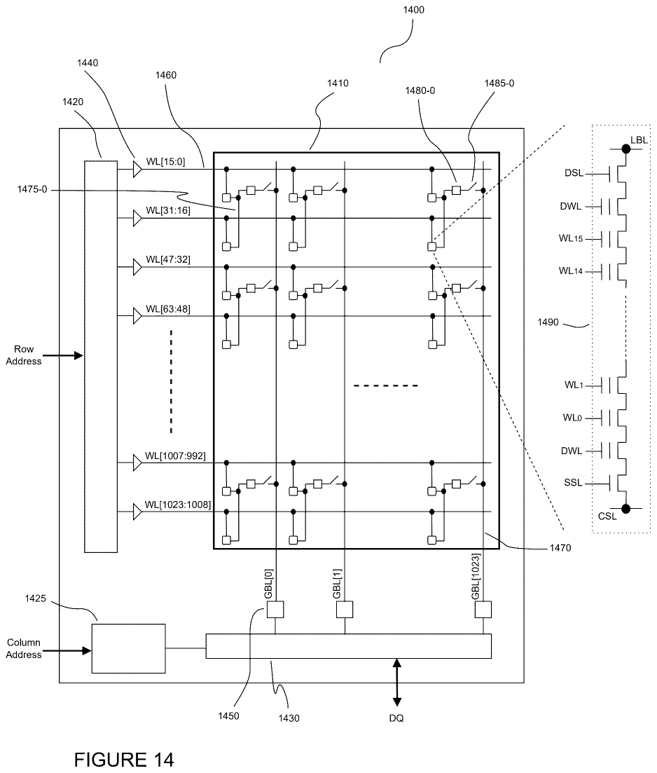

FIG. 14 shows the simplified diagram of a plane 1400 of a 3D NAND Flash device in yet another embodiment. As an option, any of the features of the present figure (and/or the description thereof) may be implemented in the context of the architecture and environment of any of the previous Figure(s) and/or any of the subsequent Figure(s).

Plane 1400 may include an array of strings 1410, row address decoder 1420, column address decoder 1425, column selection logic 1430, plurality of word line drivers (one of which is labeled 1440), global sense amplifiers 1450, plurality of word lines (one of which is labeled 1460), global bit lines (one of which is labeled 1470), plurality of groups of local bit lines (one such group is labeled 1475-0), plurality of groups of local sense amplifiers (one such group is labeled 1480-0), plurality of groups of switches (e.g. transistors), wherein each group of switches may connect a group of local sense amplifiers to the global bit lines (one such group of switches is labeled 1485-0), and a plurality of strings. One of the strings is labeled 1490 and is shown expanded on the right side of FIG. 14. Note that only one local bit line of group 1475-0 is labeled, only one local sense amplifier of group 1480-0 is labeled, and only one switch of group 1485-0 is labeled in the figure. The plurality of groups of local bit lines and local sense amplifiers may allow plane 1400 to support multiple operations (e.g. read) to overlap in time or occur at the same time. This may optionally provide higher performance.

As an example, say that WL13, WL60, and WL1010 are targets of read operations. First, local bit line group 1475-0 may be precharged to V_{PRE}, WL[15:14] and WL[12:0] may be driven to V_{READ}, DWL may be driven to VCC or V_{READ}, the corresponding DSL and SSL signals may be driven to VCC, CSL may be driven to GND, and WL13 may be driven to a first threshold voltage as shown in the example read operation flow chart illustrated in FIG. 5, FIG. 6, or FIG. 7. The associated group of local sense amplifiers 1480-0 may be used for the local sense operation.

At the same time or overlapping in time, local bit line group 1475-1 may be precharged to V_{PRE}, WL[63:61] and WL[59:48] may be driven to V_{READ}, DWL may be driven to VCC or V_{READ}, the corresponding DSL and SSL signals may be driven to VCC, CSL may be driven to GND, and WL60 may be driven to a first threshold voltage as shown in the example read operation flow chart illustrated in FIG. 5, FIG. 6, or FIG. 7. The associated group of local sense amplifiers 1480-1 may be used for the local sense operation.

Additionally, at the same time or overlapping in time, local bit line group 1475-31 may be precharged to V_{PRE}, WL[1023:1011] and WL[1009:1008] may be driven to V_{READ}, DWL may be driven to VCC or V_{READ}, the corresponding DSL and SSL signals may be driven to VCC, CSL may be driven to GND, and WL1010 may be driven to a first threshold voltage as shown in the example read operation flow chart illustrated in FIG. 5, FIG. 6, or FIG. 7. The associated group of local sense amplifiers 1480-31 may be used for the local sense operation.

Also overlapping with the above local sense operations, the global bit lines 1470 may be precharged to V_{PRE}, and each of the groups of switches 1485-0, 1485-1, and 1485-31 may be activated one at a time to connect the associated local sense amplifiers with the global bit lines. This may allow the local sense amplifiers to transfer the state of the local bit lines to the global sense amplifiers 1460. Based on the state of the global sense amplifiers after the transfer (i.e. after the global sense operation), the local sense operations may be repeated with a second voltage applied to WL13, WL60, or WL1010. That is, the read operation flow chart illustrated in FIG. 5, FIG. 6, or FIG. 7 may be modified such that the determination of the minimum threshold voltage required to turn on the floating gate transistors controlled by WL13, WL60, and WL1010 may require the involvement of the local and the global sense amplifiers.

With careful design, it may be possible to overlap the timing of the local sense operations and the global sense operations to maximize the performance of plane 1400. Of course, this example describes performing operations to three strings overlapped in time. The number of overlapping operations may depend on the 3D NAND density and organization, the latencies of the operations, the number of strings per local bit line, and other such design factors.

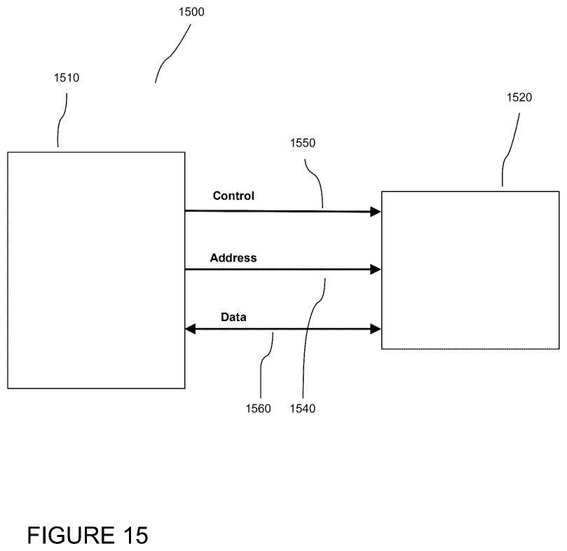

FIG. 15 shows a memory system 1500 including a controller 1510 and a NAND Flash device 1520. As an option, any of the features of the present figure (and/or the description thereof) may be implemented in the context of the architecture and environment of any of the previous Figure(s) and/or any of the subsequent Figure(s).

Controller 1510 may be a memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, e.MMC controller, UFS controller, SATA SSD controller, PCIe SSD controller, or any device that is capable of being in communication with a NAND Flash device. Controller 1510 may be packaged with the NAND Flash device 1520 in a System-in-Package (SiP) or controller 1510 and NAND Flash device 1520 may be in separate packages. Address signals 1540 and control signals 1550 may flow mostly from controller 1510 to NAND Flash device 1520 while data signals 1560 may flow bi-directionally between controller 1510 and NAND Flash device 1520. Controller 1510 may be operable to issue a plurality of commands (e.g. read) that may overlap in time to a plane of NAND Flash device 1520.

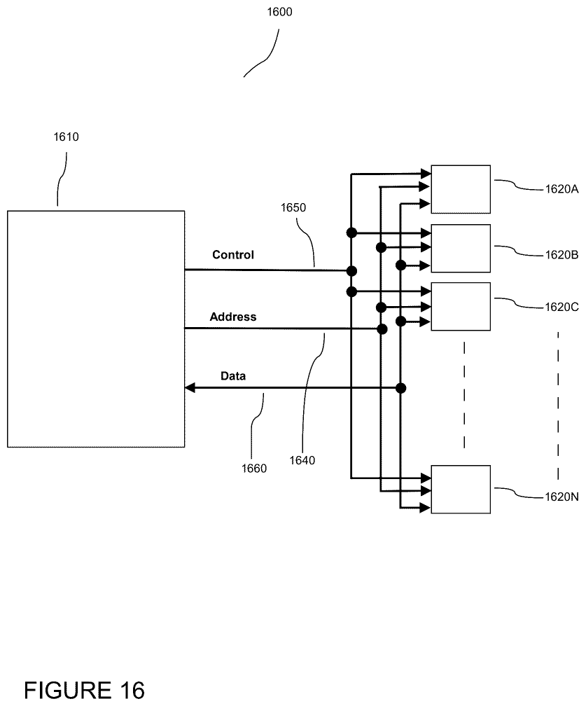

FIG. 16 shows a memory system 1600 including a controller 1610 and a plurality of NAND Flash devices 1620A-1620N. As an option, any of the features of the present figure (and/or the description thereof) may be implemented in the context of the architecture and environment of any of the previous Figure(s) and/or any of the subsequent Figure(s).

Controller 1610 may be a memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, e.MMC controller, UFS controller, SATA SSD controller, PCIe SSD controller, or any device that is capable of being in communication with a NAND Flash device. Controller 1610 may be packaged with the plurality of NAND Flash devices 1620A-1620N in a System-in-Package (SiP) or controller 1610 and NAND Flash devices 1620A-1620N may be in separate packages. Furthermore, all the NAND Flash devices 1620A-1620N may be packaged together in a single package or in a plurality of packages. Address signals 1640 and control signals 1650 may flow mostly from controller 1610 to NAND Flash devices 1620A-1620N while data signals 1660 may flow bi-directionally between controller 1610 and NAND Flash devices 1620A-1620N. Controller 1610 may be operable to issue a plurality of commands (e.g. read) that may overlap in time to a plane of at least one of the NAND Flash devices 1620A-1620N.

In various embodiments, the NAND Flash device may be implemented as a single monolithic integrated circuit or may be implemented in a three-dimensional integrated circuit. In the context of the present description, a three-dimensional integrated circuit refers to any integrated circuit comprised of stacked wafers and/or dies (e.g. silicon wafers and/or dies, etc.), which are interconnected vertically and are capable of behaving as a single device. For example, in one embodiment, memory system 1500 (and/or memory system 1600) may include a three-dimensional circuit that is a wafer-on-wafer device, where a first wafer may include a plurality of strings and a second wafer may include circuits such as address decoders, sense amplifiers, timing circuits, and/or I/O circuits. In the context of the present description, a wafer-on-wafer device refers to any device including two or more semiconductor wafers that are communicatively coupled in a wafer-on-wafer configuration. In one embodiment, the wafer-on-wafer device may include a device that is constructed utilizing two or more semiconductor wafers, which are aligned, bonded, and possibly cut in to at least one three-dimensional integrated circuit. In this case, vertical connections (e.g. TSVs, etc.) may be built into the wafers before bonding or created in the stack after bonding.

In another embodiment, memory system 1500 (and/or memory system 1600) may include a three-dimensional integrated circuit that is a die-on-wafer device. In the context of the present description, a die-on-wafer device refers to any device including one or more dies positioned on a wafer. In one embodiment, the die-on-wafer device may be formed by dicing a first wafer into singular dies, then aligning and bonding the dies onto die sites of a second wafer. For example, the first wafer may include circuits such as address decoders, sense amplifiers, timing circuits, and/or I/O circuits, and the second wafer may include a plurality of strings. Vertical connections (e.g. TSVs, etc.) may be built into the wafers before bonding or created in the stack after bonding.

In yet another embodiment, memory system 1500 (and/or memory system 1600) may include a three-dimensional integrated circuit that is a die-on-die device. In the context of the present description, a die-on-die device refers to a device including two or more aligned dies in a die-on-die configuration. In one embodiment, the die-on-die device may be formed by dicing a first wafer and a second wafer into singular dies, then aligning and bonding at least one die from the first wafer onto at least one die from the second wafer. For example, the first wafer may include circuits such as address decoders, sense amplifiers, timing circuits, and/or I/O circuits, and the second wafer may include a plurality of strings. Vertical connections (e.g. TSVs, etc.) may be built into the wafers before bonding or created in the stack after bonding.

It should be noted that each of the embodiments described previously may incorporate elements, architectural features, circuits, logic blocks, signals, or any implementation details from other embodiments. For example, the embodiments of FIG. 13 and FIG. 14, may be implemented such that the strings in the memory array may have 2 bit lines and 2 common source lines as shown in the embodiment of FIG. 11.

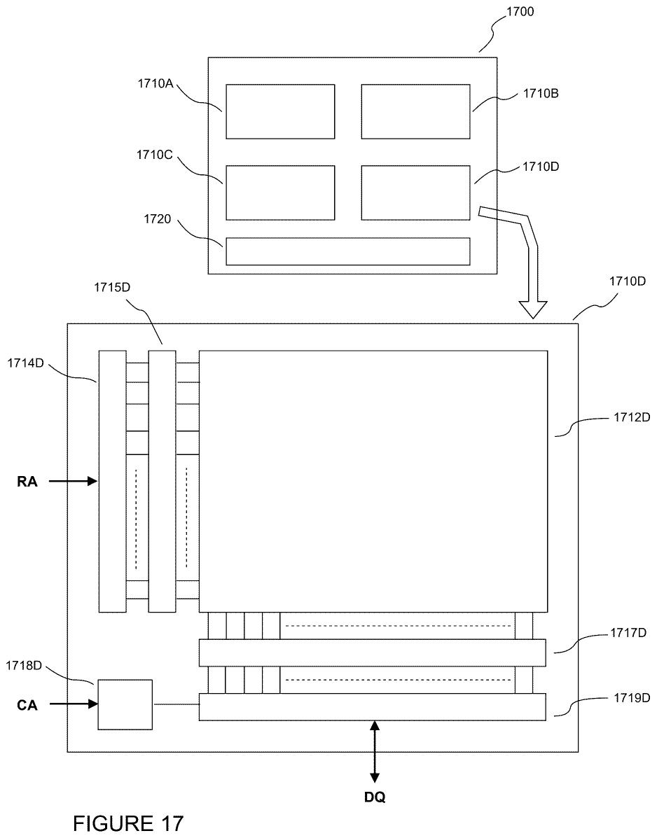

FIG. 17 shows the block diagram of a DRAM device 1700 with four banks 1710A-1710D and an I/O block 1720. As an option, any of the features of the present figure (and/or the description thereof) may be implemented in the context of the architecture and environment of any of the previous Figure(s) and/or any of the subsequent Figure(s).

Each bank may include a plurality of bit cells arranged in rows and columns, row address decoder, word line drivers, sense amplifiers, column address decoder, and column selection logic. An expanded view of bank 1710D is shown at the bottom of the figure. Bank 1710D may include an array of bit cells 1712D arranged in rows and columns, row address decoder 1714D, word line drivers 1715D, sense amplifiers 1717D, column address decoder 1718D, and column selection logic 1719D. Row address bits and column address bits are labeled RA and CA respectively, and data I/O lines are labeled DQ.

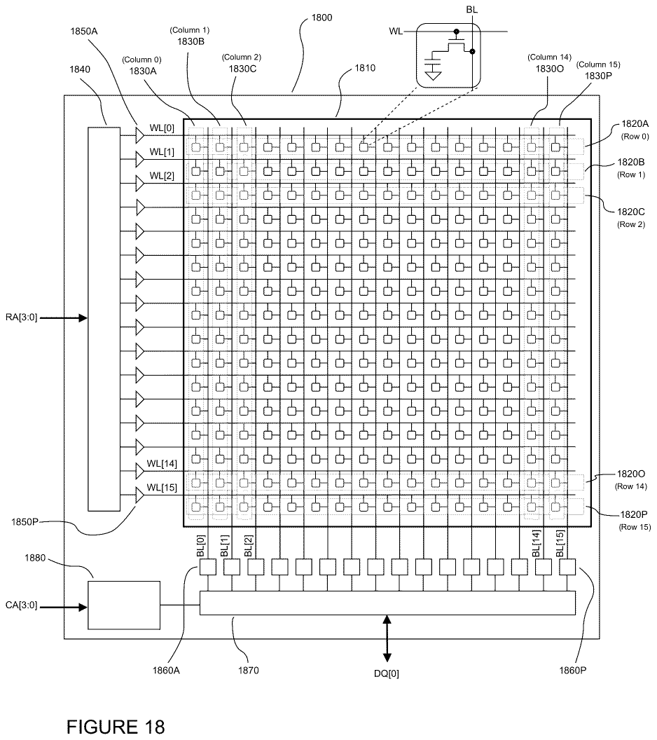

FIG. 18 shows a more detailed diagram of a bank 1800 of a DRAM device. As an option, any of the features of the present figure (and/or the description thereof) may be implemented in the context of the architecture and environment of any of the previous Figure(s) and/or any of the subsequent Figure(s).

Bank 1800 is shown to include a memory array 1810 with sixteen rows of bit cells 1820A-1820P and sixteen columns of bit cells 1830A-1830P. Word lines WL[15:0] are shown associated with the sixteen rows of bit cells 1820P-1820A respectively, and bit lines BL[15:0] are shown associated with the sixteen columns of bit cells 1830P-1830A respectively. It should be noted that the array size is deliberately chosen to be small to better illustrate various embodiments. Currently available DRAM devices typically have much larger array of bit cells (e.g. 2K rows, and 16K columns) per bank. A bit cell may be located at each intersection of a word line and a bit line in memory array 1810. Each bit cell may include a transistor and a capacitor (i.e. the bit cells is a 1T1C cell), wherein the transistor controls access to the cell, and the capacitor stores the data bit in the form of an electrical charge. Bank 1800 may also include a row decoder 1840, which decodes row address RA[3:0] into sixteen outputs, each of which is connected to one of sixteen word line drivers 1850A-1850P. The word line drivers may drive the corresponding word lines WL[15:0]. When a given word line is energized (e.g. driven high), the transistors in the associated row of bit cells may turn on and connect the capacitors in that row's bit cells to the associated bit lines. In other words, all the bit cells controlled by that word line may be connected to bit lines BL[15:0]. Sense amplifiers 1860P-1860A connected to the bit lines BL[15:0] respectively may then sense the charge stored in the bit cells of the active word line. The sense amplifiers 1860A-1860P may also connect to column selection logic 1870. Column decoder 1880 may decode column address CA[3:0] and operating in conjunction with column selection logic 1870, may connect the DQ[0] line to one of the sixteen sense amplifiers 1860A-1860P. Note that a x1 (i.e. a 1-bit wide) array is described and illustrated in FIG. 18 strictly as an example. Other array widths may also be used. For example, in a x2 array, column decoder 1880 may decode column address CA[3:1], and operating in conjunction with column selection logic 1870, connect two of the sixteen sense amplifiers 1860A-1860P to data I/O lines DQ[1:0]. Similarly, for a x4 array, column decoder 1880 and column selection logic 1870 may use column address CA[3:2] to connect four of the sense amplifiers 1860A-1860P to data I/O lines DQ[3:0].

DRAM designers typically use Memory Array Tiles (MATs) as the building blocks of a DRAM array when designing a DRAM device. A MAT may include one or more of the following: an array of bit cells (e.g. 256×256, 512×512, etc.) arranged in rows and columns, local sense amplifiers, and optionally, local word line drivers. Such tiles may be used to build larger arrays. For example, if a DRAM bank has 8K (i.e. 8,192) rows and 16K (i.e. 16,384) columns, and a MAT includes a 512×512 array of bit cells, a DRAM designer may place 16 MATs along the x-axis in each row and 32 MATs along the y-axis in each column (i.e. construct a 16×32 array of MATs) to obtain an 8K×16K array of bit cells. The array of bit cells in a MAT may be implemented similar to the memory array 1810 of FIG. 18. For example, in the case of a 512×512 MAT, each word line may control the transistors in 512 bit cells, and each bit line may connect to a non-gate terminal of the transistor (i.e. the source or drain terminal) in each of the 512 bit cells. In FIG. 18, it can be seen that each of the bit lines BL[15:0] connects to sixteen transistors.

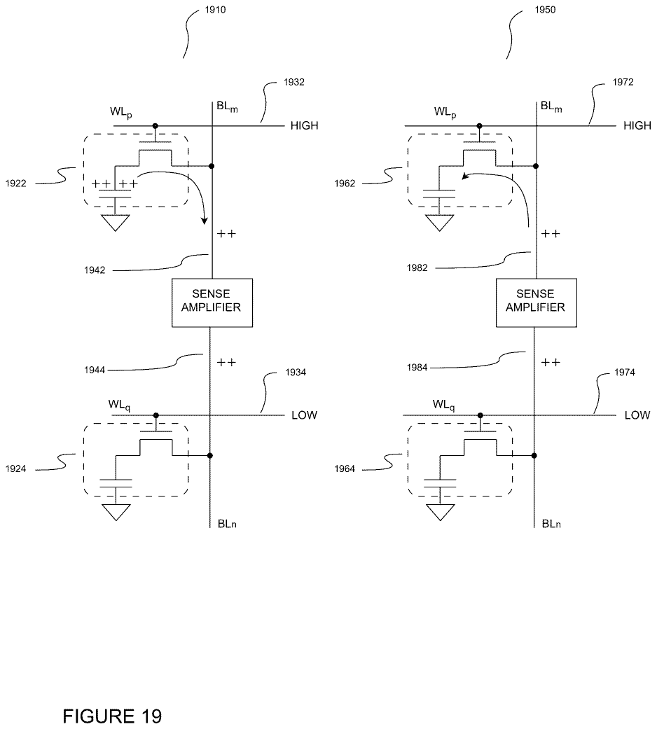

In operation, the capacitor of a bit cell may be charged to a first voltage (e.g. VDD) to store a logic 1 in the bit cell, and charged to a second voltage (e.g. GND) to store a logic 0 in the bit cell. Reading the logic bit stored in a bit cell may involve precharging the bit line to a third voltage (e.g. VDD/2), and energizing the associated word line, which may cause the transistor of the bit cell to turn on. If the bit cell capacitor voltage is higher than the voltage on the bit line, the bit cell capacitor may discharge some of its charge to the bit line, which may cause the bit line voltage to increase. This increase in the bit line voltage may be sensed by a sense amplifier (typically, by comparing the voltage on the bit line to the voltage on a precharged bit line that is not active; that is, used as a reference), resulting in a logic 1 being detected by the sense amplifier. This is illustrated in FIG. 19, wherein circuit 1910 includes two bit cells 1922 and 1924, two word lines 1932 and 1934, and two bit lines 1942 and 1944. Bit cell 1922, and associated word line 1932 and bit line 1942 may belong to a first MAT while bit cell 1924, and associated word line 1934 and bit line 1944 may belong to a second MAT. Bit cell 1922 is shown to store a charge corresponding to a logic 1. When word line 1932 is energized, bit cell 1922 may discharge some of its charge to bit line 1942, thus causing the bit line voltage to increase (e.g. to VDD/2+D). The sense amplifier may detect the difference between the voltage on bit line 1942 and the voltage on bit line 1944 (e.g. VDD/2), and amplify the difference, so as to detect that a logic 1 was stored in bit cell 1922 (i.e. capacitor of bit cell 1922 was previously charged to VDD), and to fully restore the charge of the capacitor of bit cell 1922.

In the case that the bit cell capacitor voltage is less than the voltage of the bit line, the bit line may discharge some of its charge to the bit cell capacitor, which may cause the bit line voltage to decrease. This decrease may be sensed by the sense amplifier, causing a logic 0 to being detected. This is illustrated in FIG. 19, wherein circuit 1950 includes two bit cells 1962 and 1964, two word lines 1972 and 1974, and two bit lines 1982 and 1984. Bit cell 1962, and associated word line 1972 and bit line 1982 may belong to a first MAT while bit cell 1964, and associated word line 1974 and bit line 1984 may belong to a second MAT. Bit cell 1962 is shown to store a charge corresponding to a logic 0. When word line 1972 is energized, bit line 1982 may discharge some of its charge to bit cell 1962, thus causing the bit line voltage to decrease (e.g. to VDD/2-D). The sense amplifier may detect the difference between the voltage on bit line 1982 and the voltage on bit line 1984 (e.g. VDD/2), and amplify the difference, so as to detect that a logic 0 was stored in bit cell 1962 (i.e. capacitor of bit cell 1962 was previously charged to GND), and to fully restore the charge of the capacitor of bit cell 1962.

As described above and illustrated in FIG. 19, the sensing of the charge stored in a bit cell may depend on the ratio of the capacitance of the bit cell capacitor to the capacitance of the bit line. The magnitude of the change in the voltage of the bit line may need to be sufficient to cause the sense amplifier to detect the difference in voltage between its two inputs, and amplify the difference, and thus also restore the charge in the bit cell capacitor to the full amount. Consequently, a minimum ratio of the capacitance of a bit cell capacitor to the capacitance of a bit line may need be required for reliable detection of the charge stored in a bit cell. However, as DRAM processes scale, it may become more challenging to achieve the desired minimum capacitance of a bit cell capacitor in all the bit cells of a DRAM device. Published reports indicate that the capacitor aspect ratio in DRAM devices currently available in the market are ³50, and that this is one of the main limiters of continuous DRAM scaling.

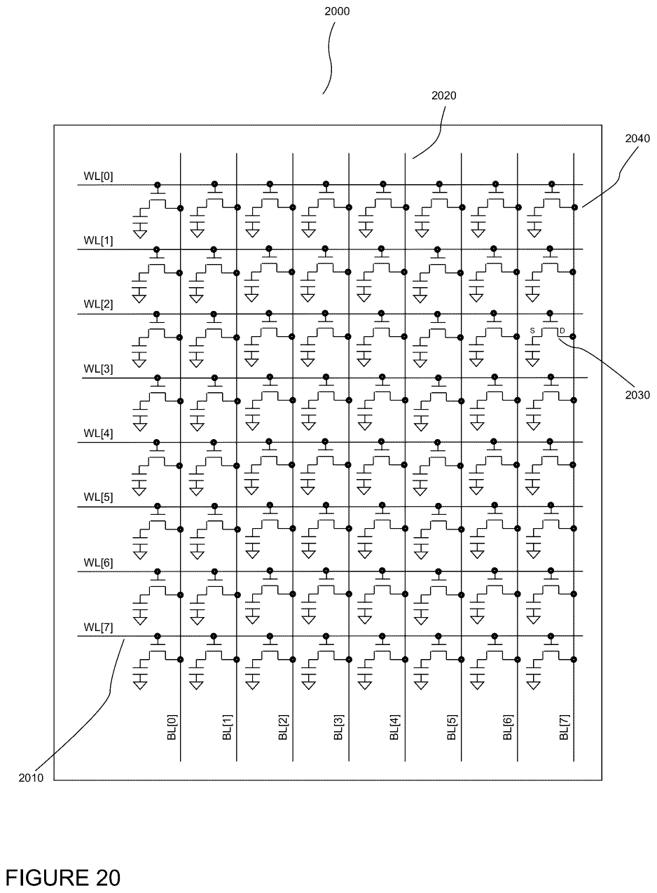

FIG. 20 shows a segment 2000 of an array of bit cells in a current art DRAM device. As an option, any of the features of the present figure (and/or the description thereof) may be implemented in the context of the architecture and environment of any of the previous Figure(s) and/or any of the subsequent Figure(s).

Segment 2000 includes 8 word lines WL[7:0], one of which is numbered as 2010, and 8 bit lines BL[7:0], one of which is numbered 2020. A DRAM bit cell may be at the intersection of each word line and each bit line. Accordingly, each word line may connect to the gate terminals of the transistors of the bit cells of the associated row of 8 bit cells, and each bit line may connect to the drain terminals of the transistors of the bit cells of the associated column of 8 bit cells. A drain terminal of the transistor of a bit cell is labeled as 2030 in the figure. Note that for a MOS transistor, the source and drain terminals may be interchangeable. Additionally, a contact between a bit line and a drain terminal of a transistor is labeled as 2040 in the figure. As can be seen from the figure, each bit line 2020 may connect to 8 drain terminals 2030 by means of 8 contacts 2040. Hence, the total capacitance of a bit line may include the capacitance of the bit line itself, the combined capacitances of the 8 contacts, and the combined capacitances of the 8 drain terminals.

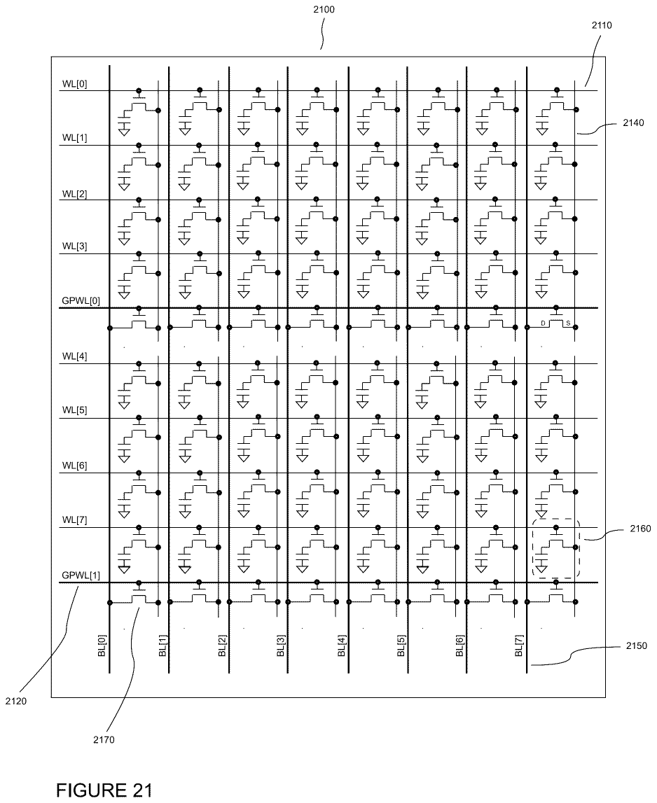

In the embodiment illustrated in FIG. 21, the capacitance of the bit line may be reduced, which may reduce the complexity of the fabrication of high aspect ratio capacitors, and may also increase the yield of DRAM devices. As an option, any of the features of the present figure (and/or the description thereof) may be implemented in the context of the architecture and environment of any of the previous Figure(s) and/or any of the subsequent Figure(s).

As mentioned above, the total capacitance of a bit line may include the capacitance of the bit line itself, the capacitance of the contacts to the transistors of the bit cells, and the capacitance of the drain regions of the bit cell transistors. In this embodiment, a bit line may connect to fewer transistors, thus reducing the capacitance of the contacts to the transistors, as well as reducing the capacitance of the drain regions of such transistors, which may result in a reduction of the total bit line capacitance.

Array segment 2100 includes 8 word lines WL[7:0], one of which is numbered 2110, and 8 bit lines BL[7:0], one of which is numbered 2150, and a plurality of bit cells, one of which is labeled 2160. Segment 2100 also includes 2 group word lines GPWL[1;0], one of which is labeled 2120, 16 local bit lines, one of which is labeled 2140, and 16 group access transistors, one of which is labeled 2170. As shown, each local bit line may connect to the drain terminals of the transistors of 4 bit cells, and to the source terminal of a group access transistor. The drain terminal of a group access transistor may connect to one of the bit lines BL[7:0], while the gate terminal of a group access transistor may connect to one of the group word lines GPWL[1:0]. As can be seen from FIG. 21, each bit line may now connect to drain terminals of only 2 group access transistors by means of 2 contacts. Hence, the total capacitance of the bit line may be reduced. Note that while FIG. 21 shows transistors 2170 as the group access control circuits, any switch may be used as the group access control circuit.

In array segment 2100, each set of 4 word lines may be a group with an associated group word line. For example, word lines WL[3:0] may be a first group, and have an associated group word line GPWL[0]. Similarly, word lines WL[7:4] may be a second group, and have an associated group word line GPWL[1]. In operation, when a row of bit cells is accessed, the corresponding word line and the associated group word line may be energized (e.g. driven high). For example, if row 2 is to be accessed, a row address decoder in this embodiment may drive both WL[2] and GPWL[0] high, and the bit cells in row 2 may connect to bit lines BL[7:0] through the local access transistors (i.e. the access transistor in each of the cells) and the associated group access transistors. It should be noted that a group with 4 rows is illustrated in FIG. 21 strictly as an example. A group may have any number of rows. For example, a group may have 16 rows or 64 rows of bit cells. The number of rows in a group may be implementation dependent.

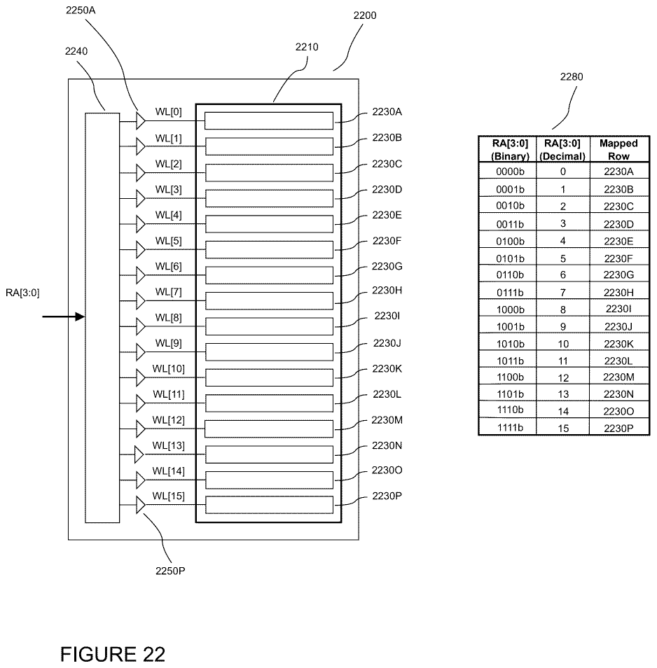

FIG. 22 shows the mapping between row addresses and rows in a memory array of DRAM bank 2200. As an option, any of the features of the present figure (and/or the description thereof) may be implemented in the context of the architecture and environment of any of the previous Figure(s) and/or any of the subsequent Figure(s).

Again, strictly as an example, the DRAM bank 2200 illustrated in this figure is shown to include memory array 2210, row address decoder 2240, and 16 word line drivers 2250A-2250P. Memory array 2210 includes 16 rows of memory bit cells 2230A-2230P. Note that this figure shows a very simplified view of a DRAM bank, and many functional blocks or circuits are not shown. Row address decoder 2240 may decode row address RA[3:0] to 16 outputs, and each output may be connected to one of the 16 word line drivers 2250A-2250P. As shown, word line WL[0] may activate the bit cells in the first row 2230A, word line WL[1] may activate the bit cells in the second row 2230B, word line WL[2] may activate the bit cells in the third row 2230C, and so on. The mapping between row address RA[3:0] and the 16 rows of bit cells 2230A-2230P is shown in table 2280 in FIG. 22.

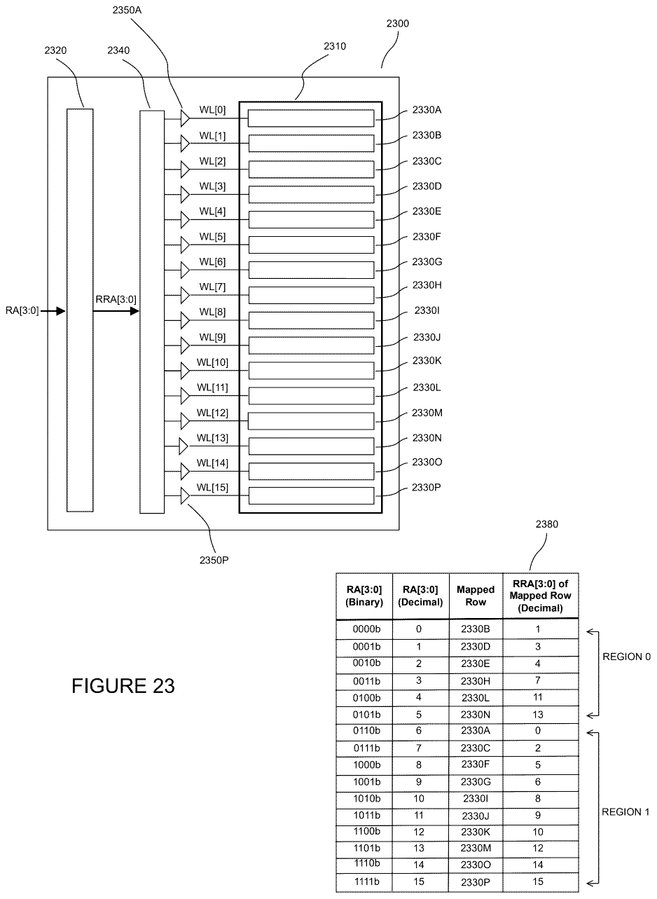

FIG. 23 shows an example mapping between row addresses and the rows in a memory array in one embodiment. As an option, any of the features of the present figure (and/or the description thereof) may be implemented in the context of the architecture and environment of any of the previous Figure(s) and/or any of the subsequent Figure(s).

DRAM bank 2300 includes memory array 2310, row address remap logic 2320, row address decoder 2340, and word line drivers 2350A-2350P. Memory array 2310 includes sixteen rows of bit cells 2330A-2330P. In operation, row address remap logic 2320 may map the input row address RA[3:0] to the output row address RRA[3:0], which may then be decoded by row address decoder 2340. In FIG. 23, RA[3:0] may be termed as the external address and RRA[3:0] may be termed as the internal address of the row, where the external address is the address used by a device external to the DRAM device (i.e. an external logic device, like a controller, a register, a buffer, a logic die, automatic test equipment, etc.) to access a row while the internal address is the input address to row decoder 2340. Alternately, RA[3:0] may be termed as the virtual address of a row and RRA[3:0] may be termed as the physical address of a row. Based on the value of RRA[3:0], row address decoder may activate one of its 16 outputs, and the corresponding word line may be driven high by the respective word line driver. If no remapping is done, the address bits on RRA[3:0] may be the same as the address bits on RA[3:0]. In such case of no remapping, row 2330A may map to RA[3:0]=RRA[3:0]=0000b (decimal 0), row 2330B may map to RA[3:0]=RRA[3:0]=0001b (decimal 1), row 2330C may map to RA[3:0]=RRA[3:0]=0010b (decimal 2), and so on. Row address remap logic 2320 may enable mapping of RA[3:0] to RRA[3:0] based on one or more aspects of the DRAM device. An example remapping of RA[3:0] to RRA[3:0] in accordance with one embodiment is shown in table 2380. Comparing the mapping table 2380 in FIG. 23 to that (i.e. table 2280) in FIG. 22, it is clear that row address RA[3:0]=0000b is mapped to row 2330B in FIG. 23 while it is mapped to row 2230A in FIG. 22. Similarly, row address RA[3:0]=0001b is mapped to row 2330D in FIG. 23 while it is mapped to row 2230B in FIG. 22. In table 2380, rows 2330B, 2330D, 2330E, 2330H, 2330L, and 2330N may be assigned to REGION 0 and mapped to RA[3:0]=0000b, 0001b, 0010b, 0011b, 0100b, and 0101b respectively. Furthermore, the remaining rows (2330A, 2330C, 2330F, 2330G, 2330I, 2330J, 2330K, 2330M, 2330O and 2330P) may be assigned to REGION 1 and mapped to RA[3:0]=0110b through RA[3:0]=1111b. As can be seen from the table, all the rows in REGION 0 may have sequential external addresses, all the rows in REGION 1 may have sequential external addresses, and the first row in REGION 1 (row 2330A) may have an external address that is sequential to the external address of the last row in REGION 0 (row 2330N).

Table 2380 in FIG. 23 also shows that the rows in each region may be remapped in an ordered (i.e. ascending) manner. That is, the internal (or physical) addresses of the rows in each region may ascend from the address of the first row in the region to the address of the last row in the region. For example, the internal addresses of the rows in the REGION 0 in the above table are (in decimal): 1, 3, 4, 7, 11, and 13, where the row with internal address 1 (decimal) is the first row in REGION 0 and the row with internal address 13 (decimal) is the last row in REGION 0. Similarly, the internal addresses of the rows in REGION 1 are (in decimal): 0, 2, 5, 6, 8, 9, 10, 12, 14, and 15, with the row with internal address 0 (decimal) being the first row in REGION 1 and row with internal address 15 (decimal) being the last row in REGION 1.

FIG. 24 illustrates remap logic 2400 in one embodiment. As an option, any of the features of the present figure (and/or the description thereof) may be implemented in the context of the architecture and environment of any of the previous Figure(s) and/or any of the subsequent Figure(s).

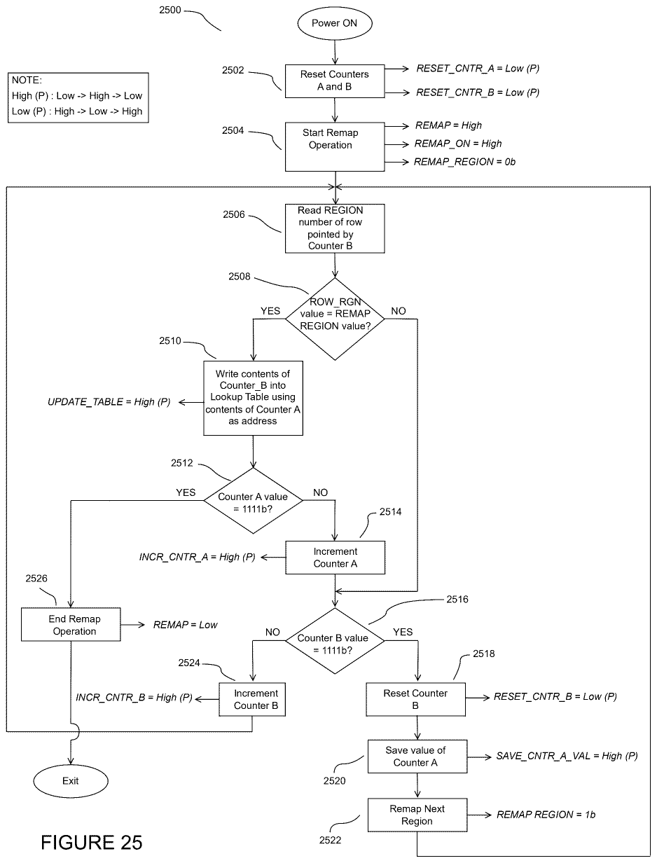

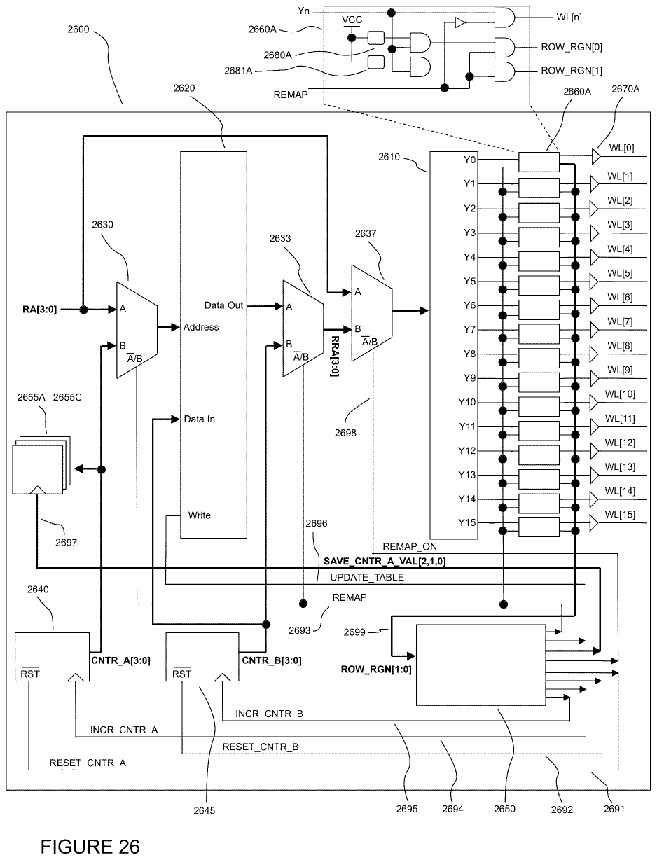

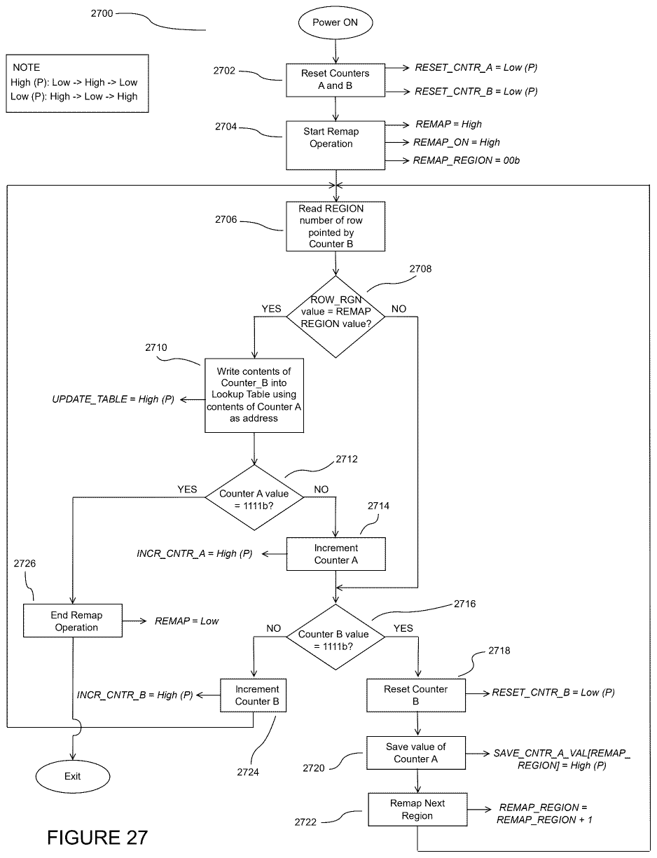

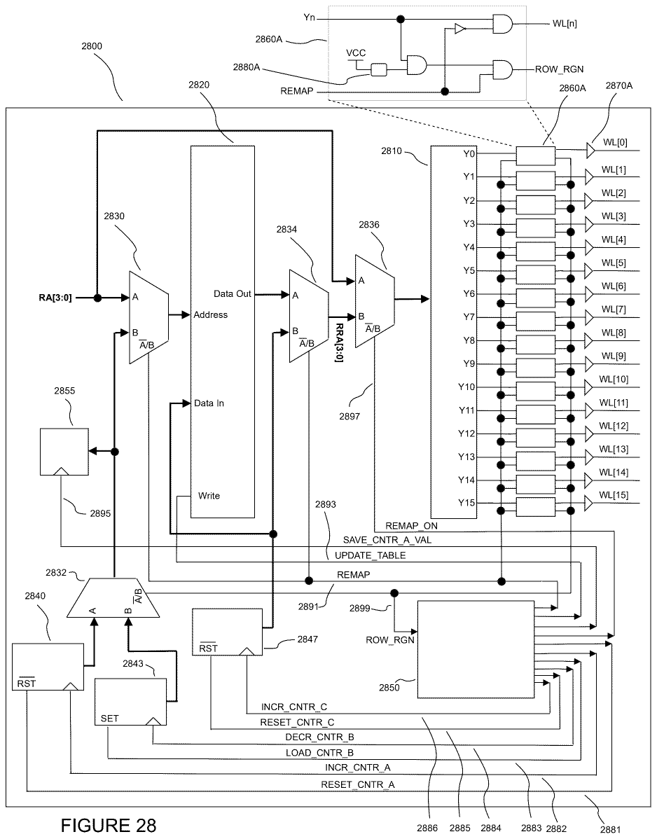

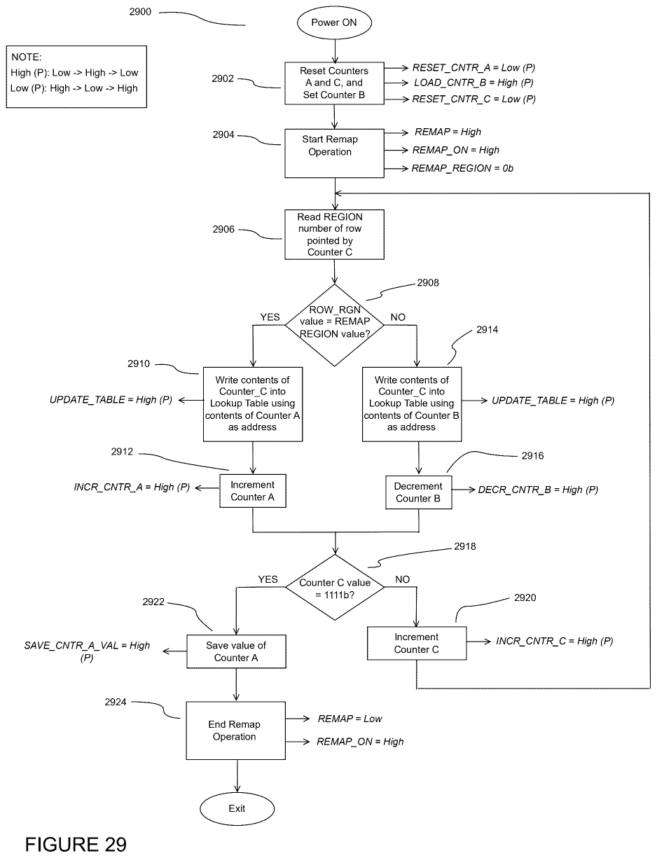

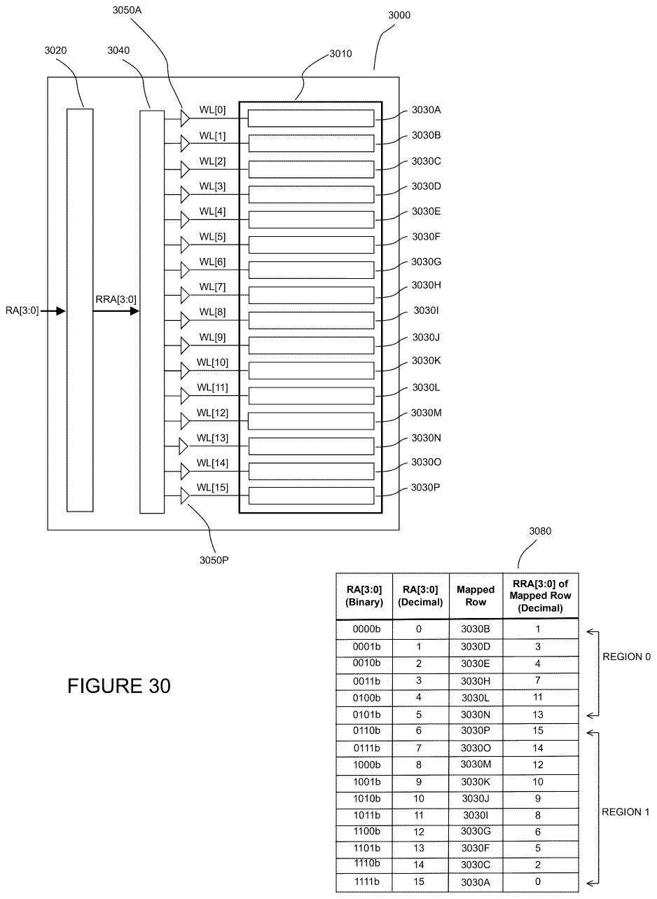

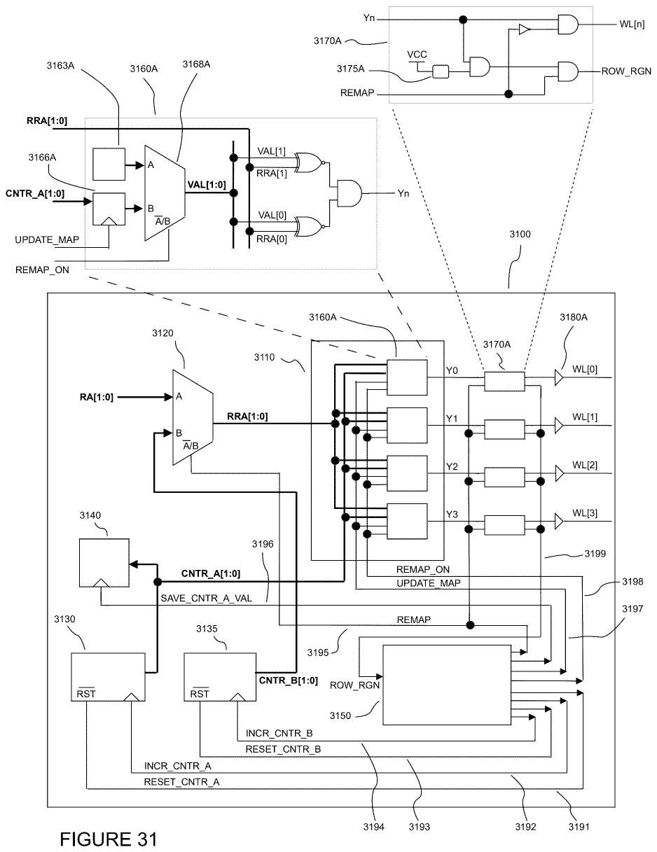

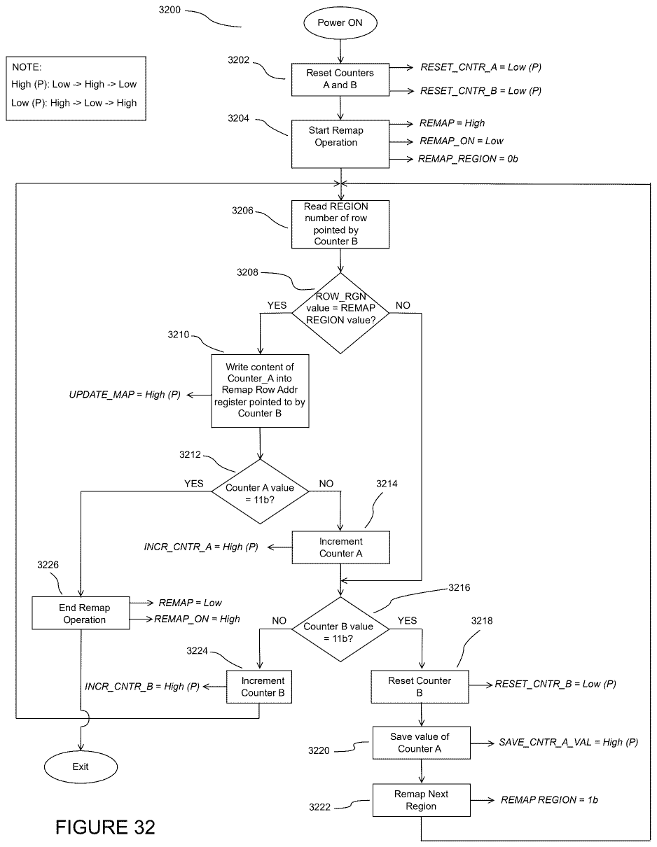

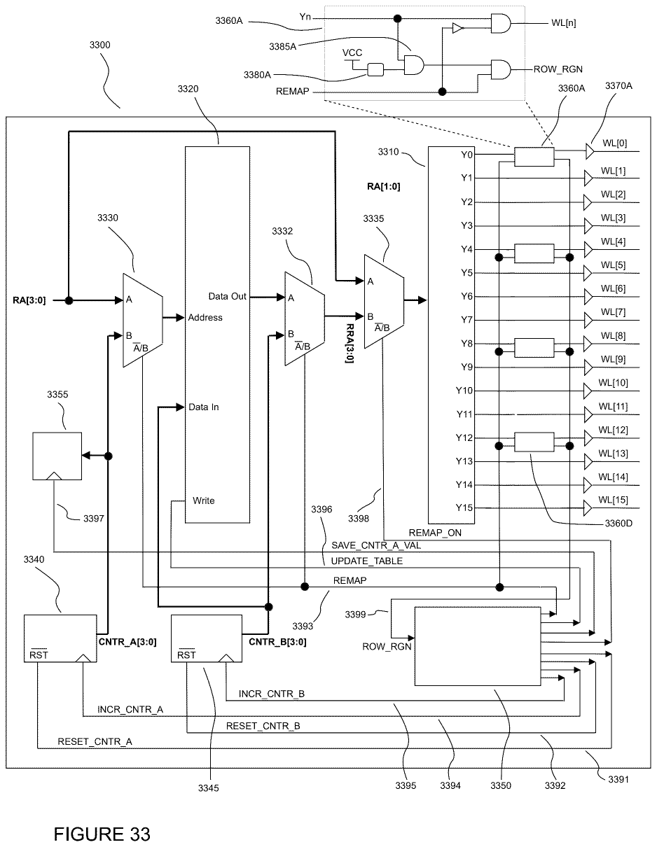

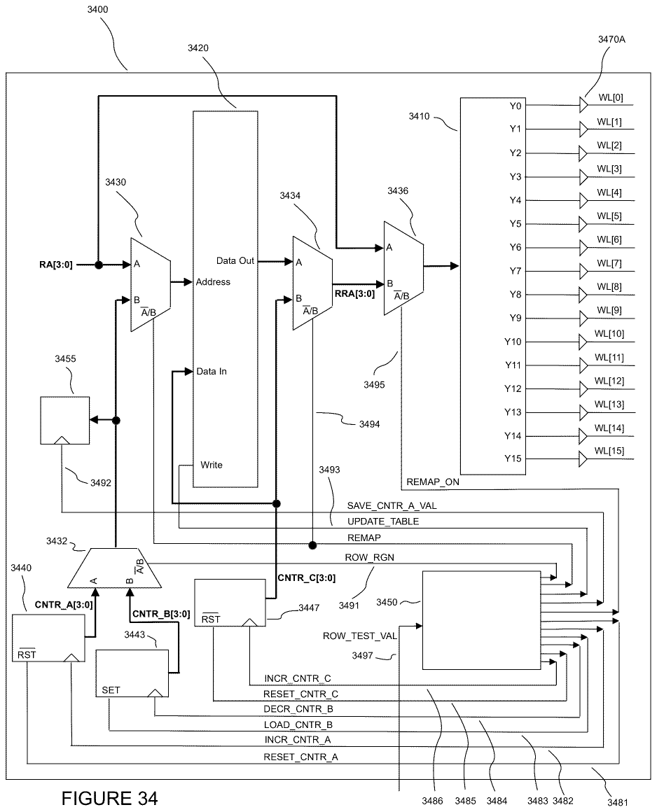

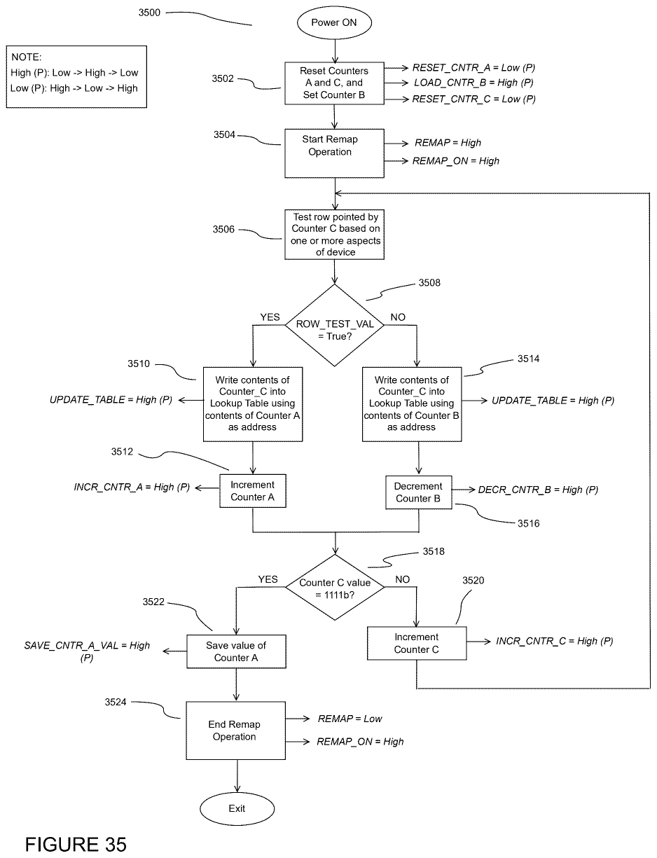

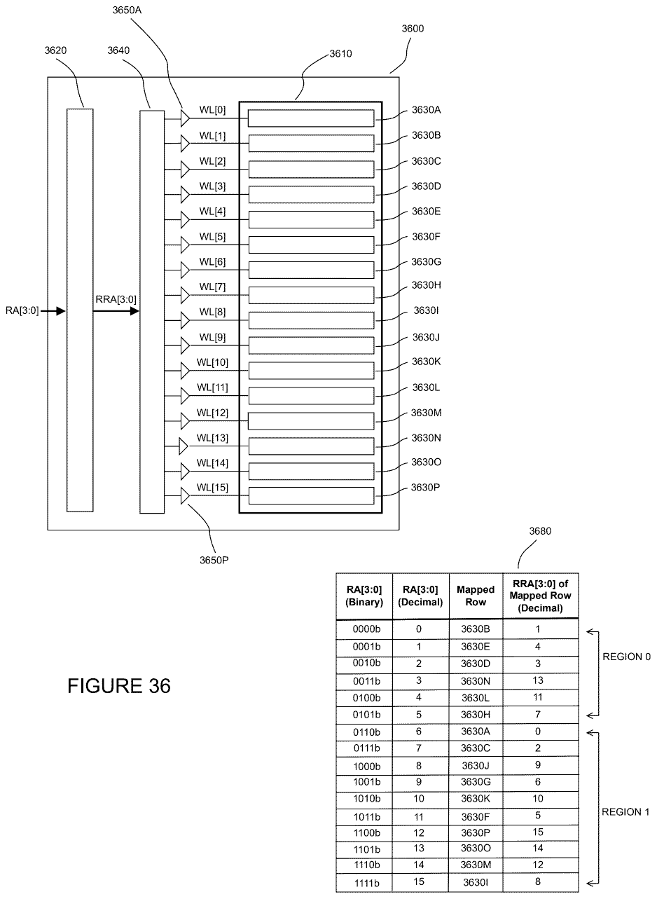

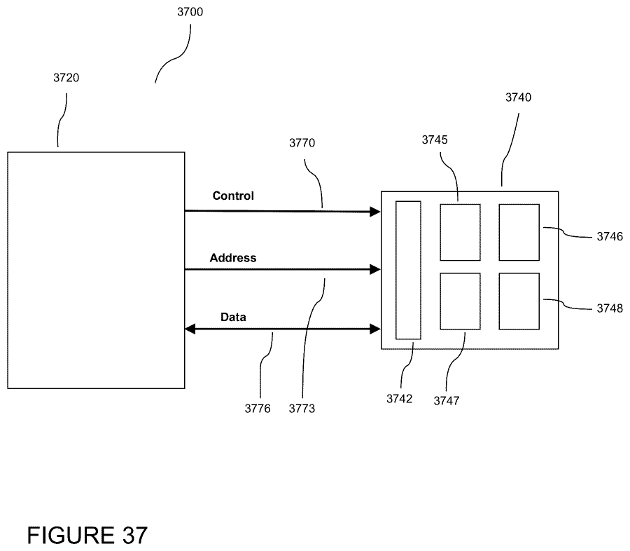

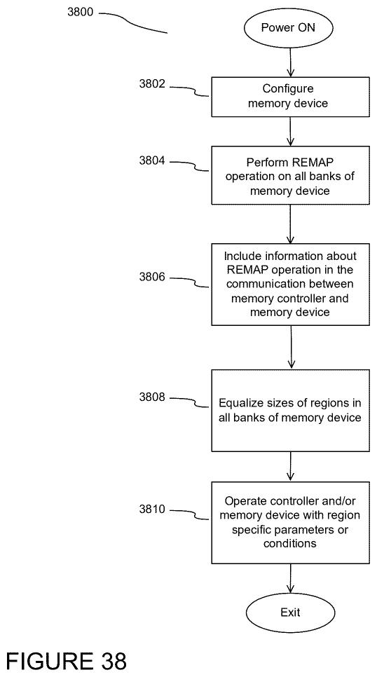

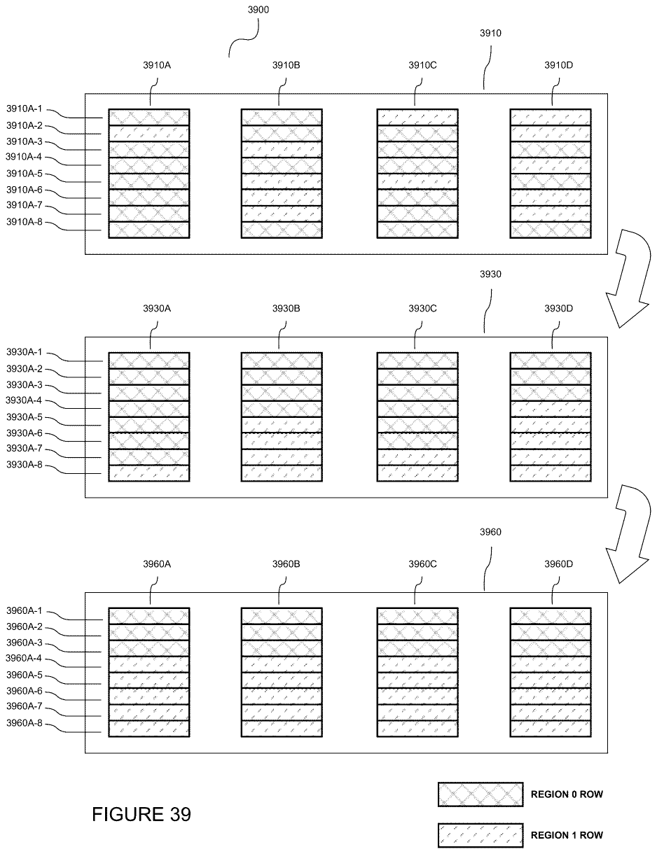

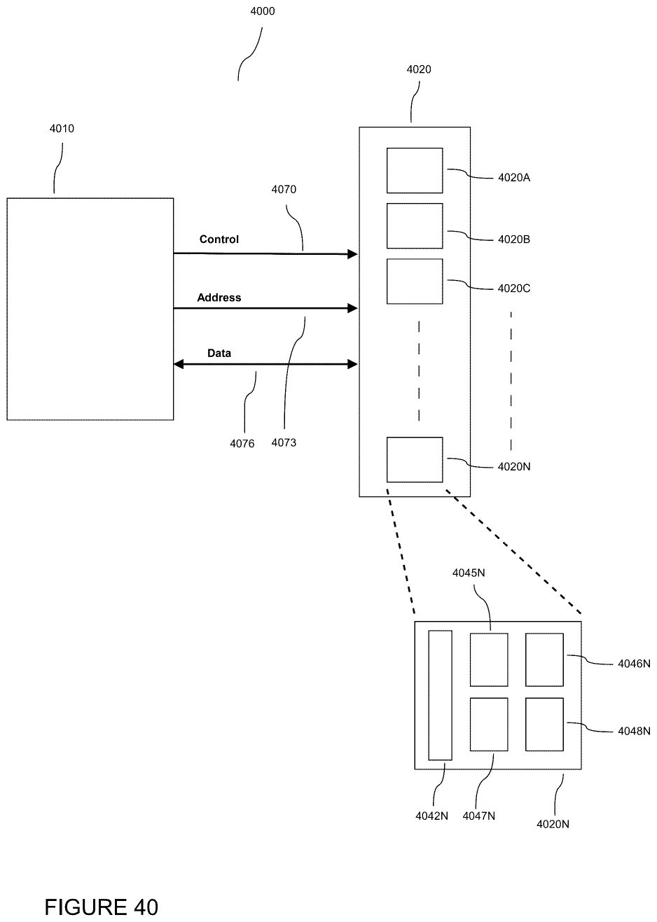

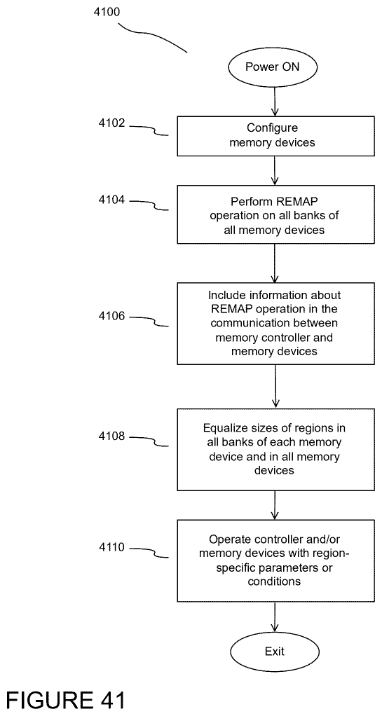

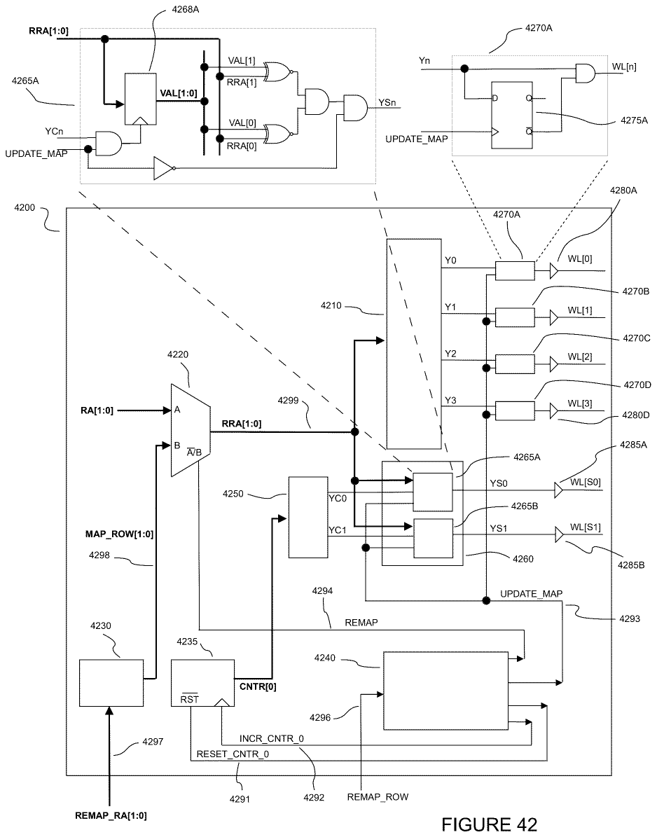

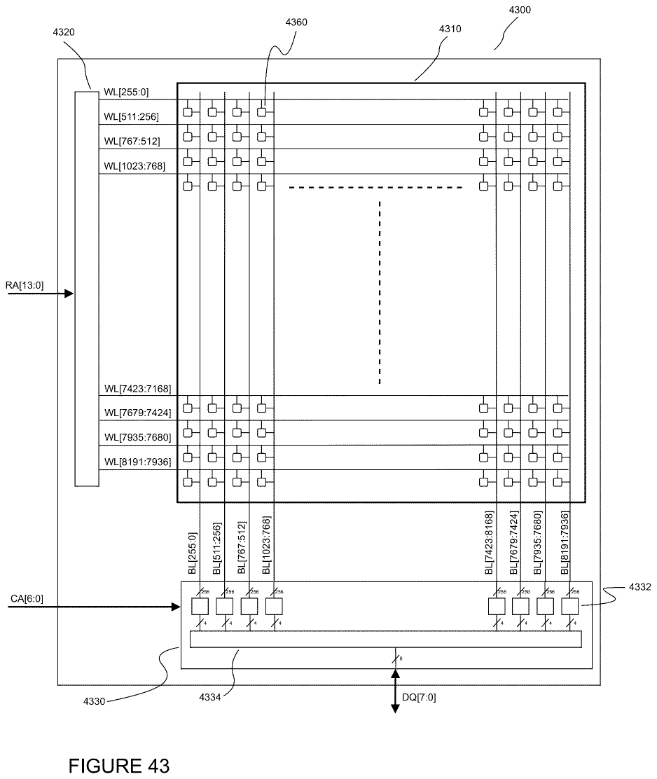

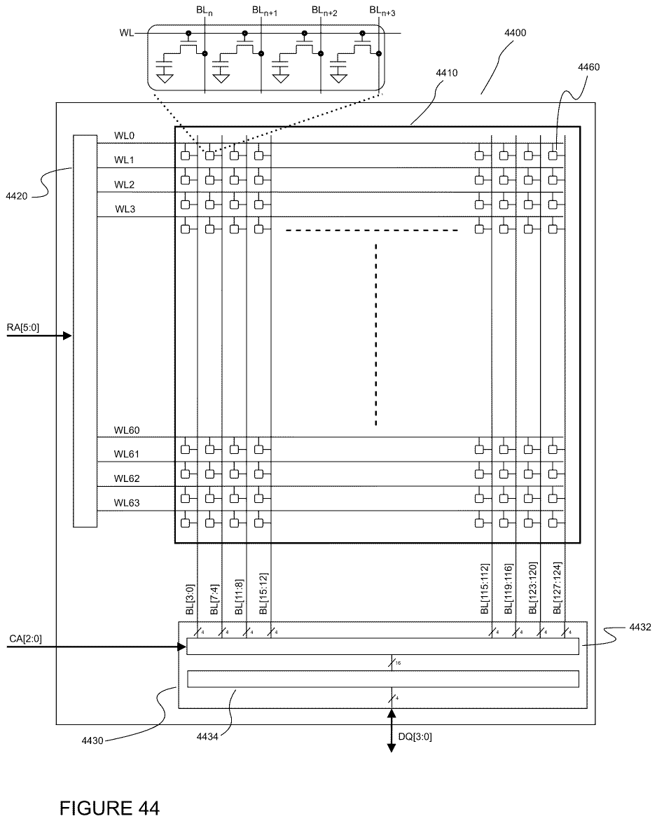

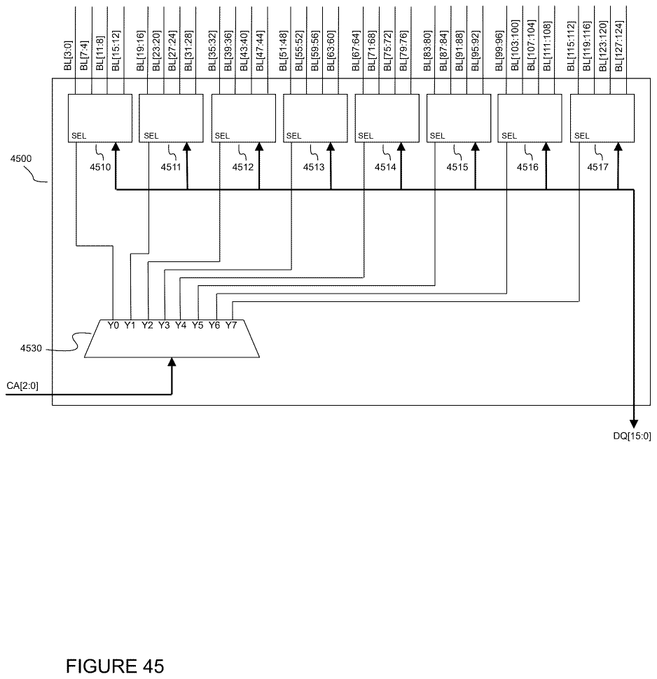

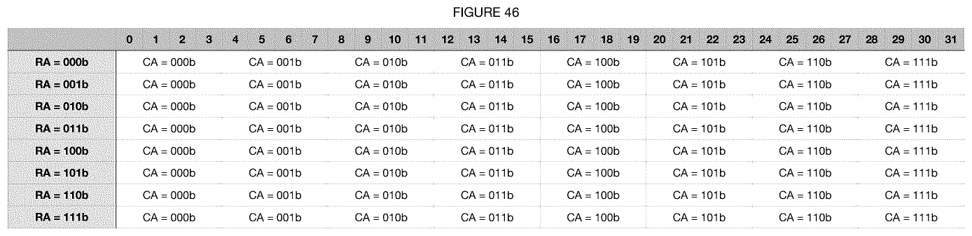

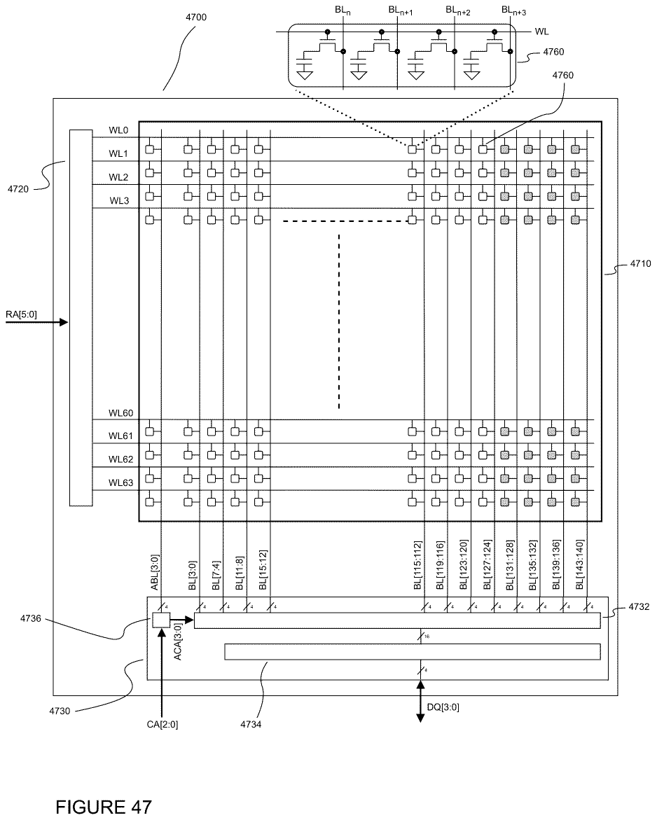

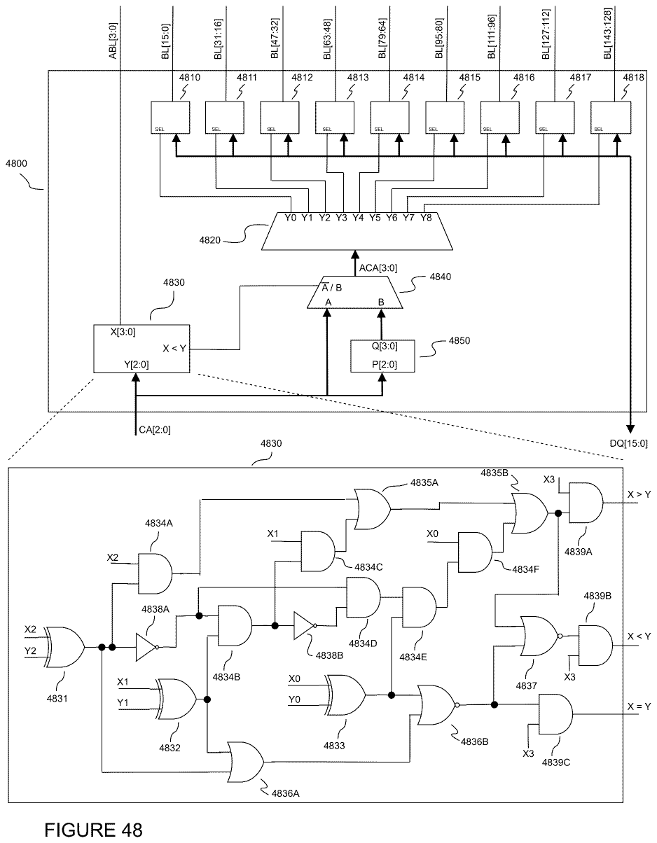

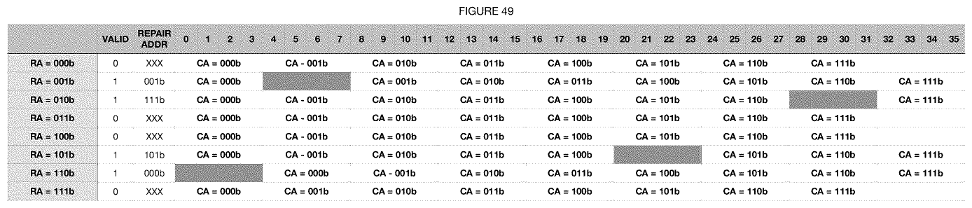

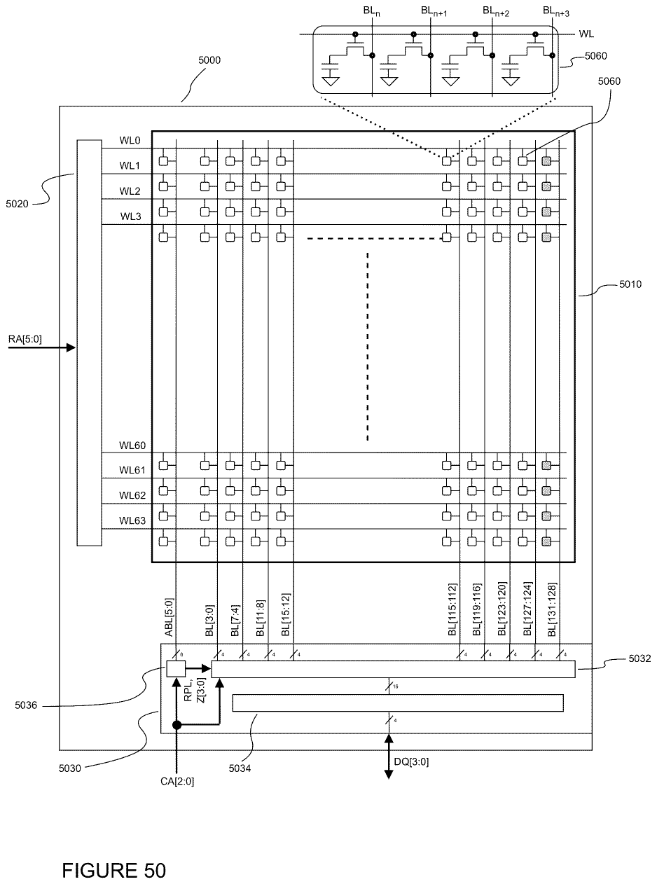

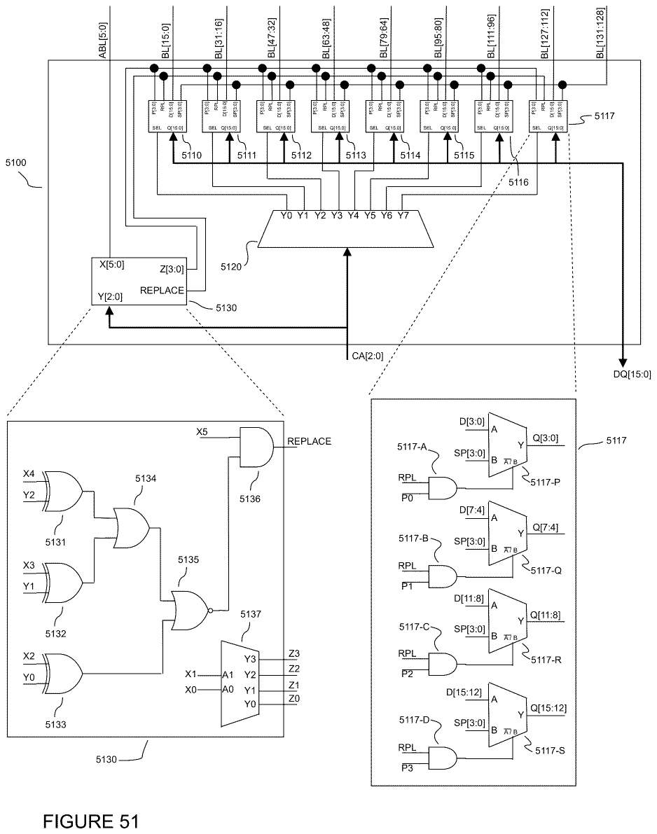

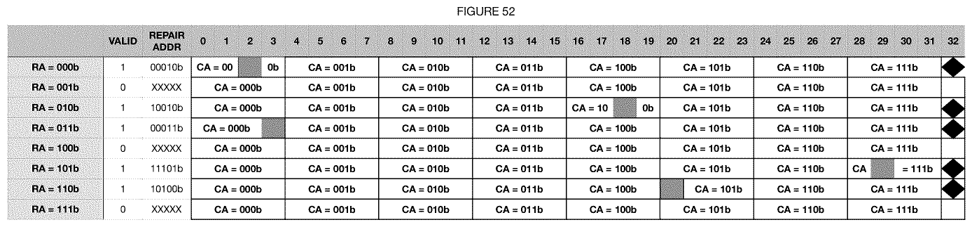

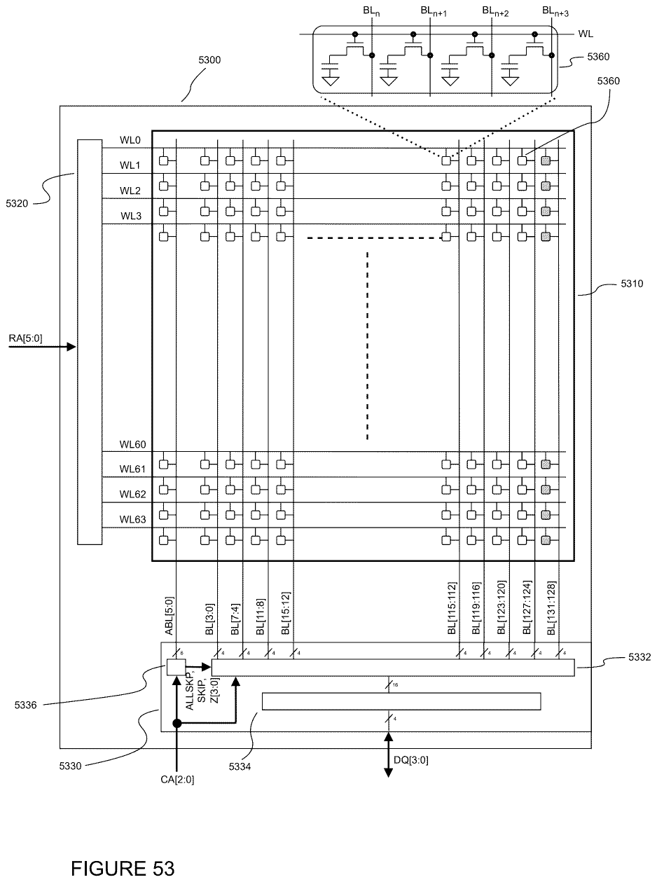

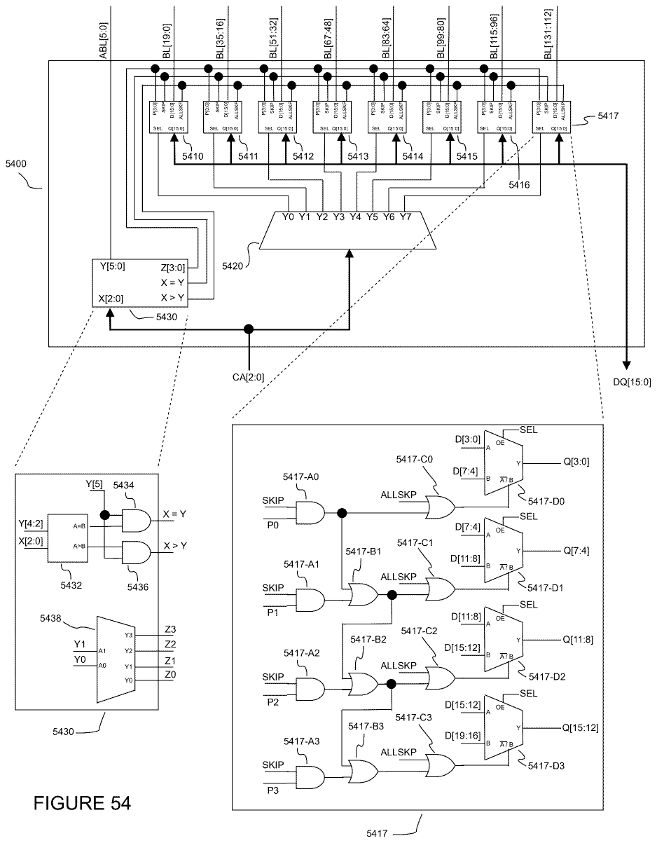

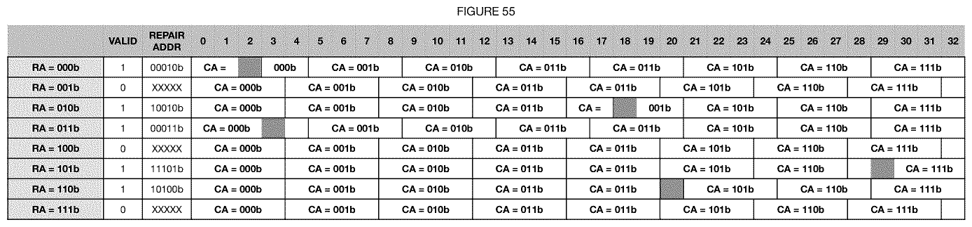

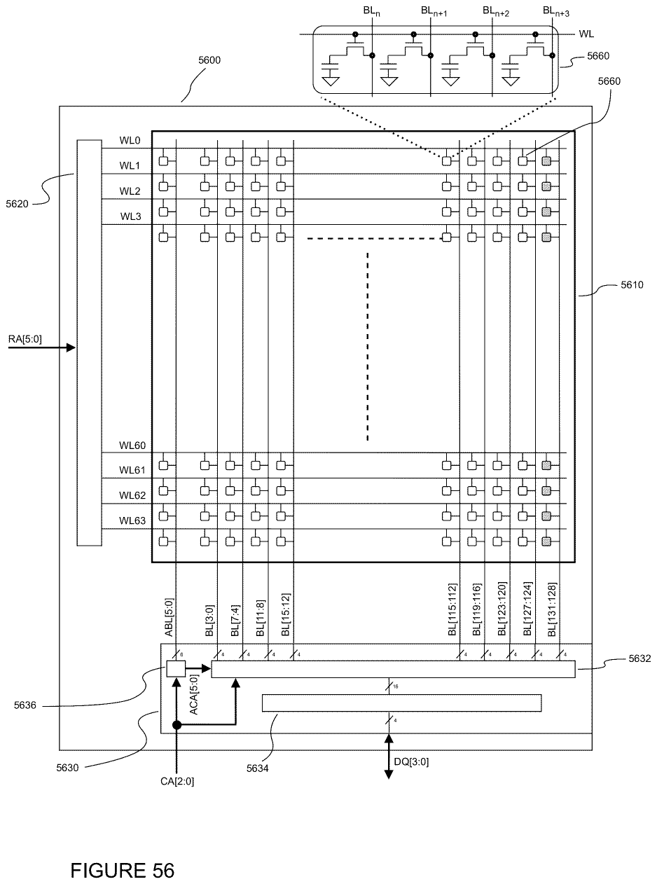

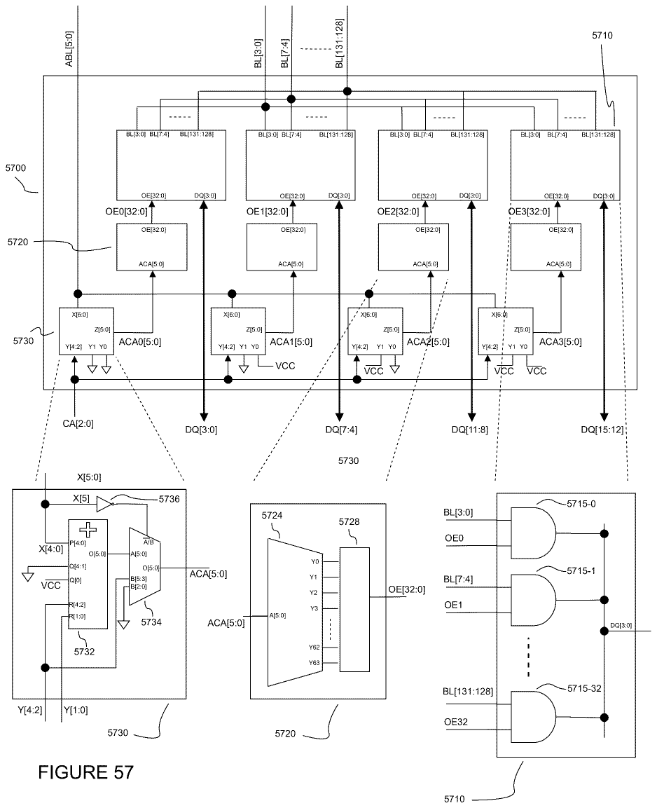

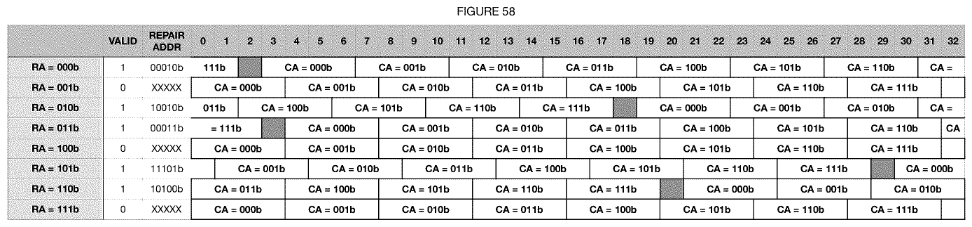

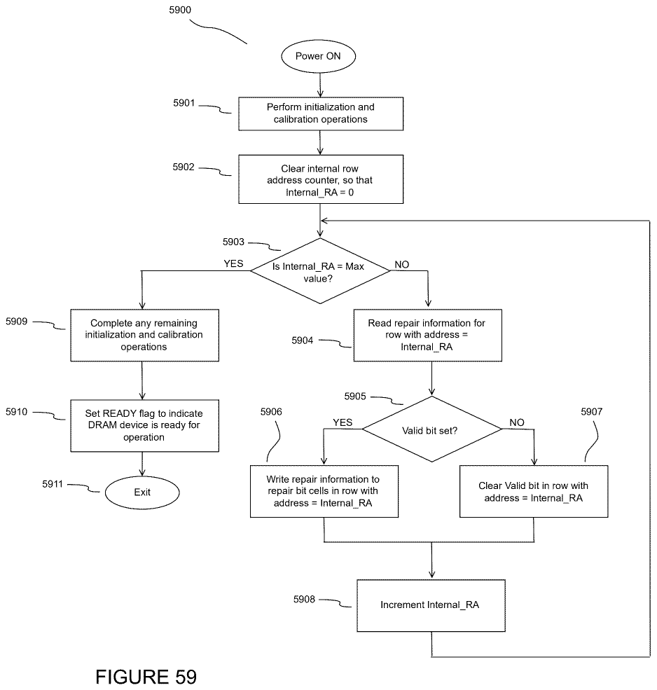

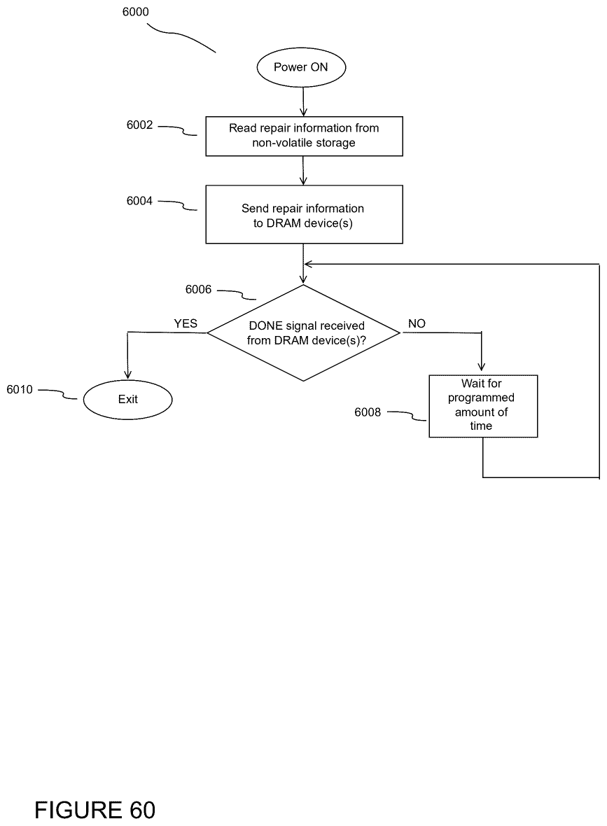

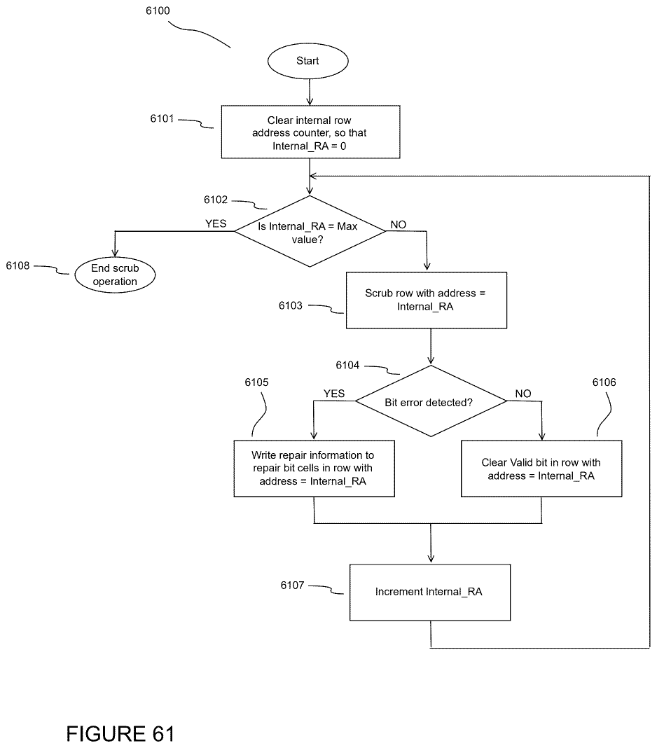

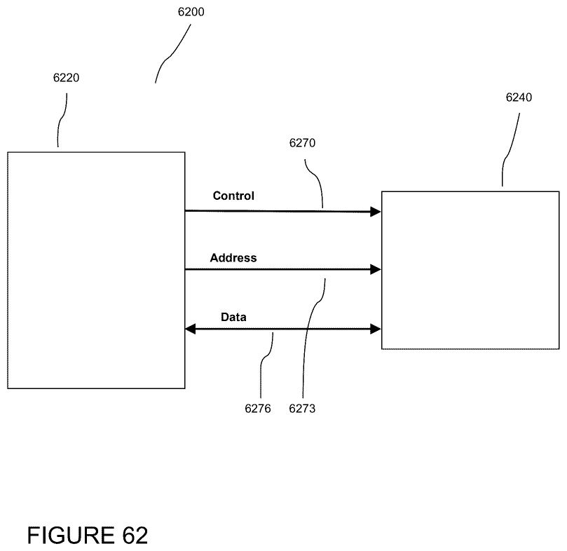

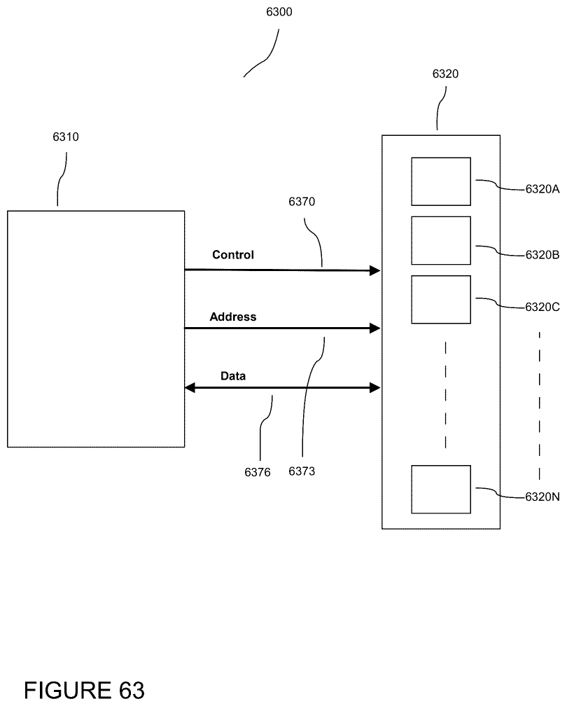

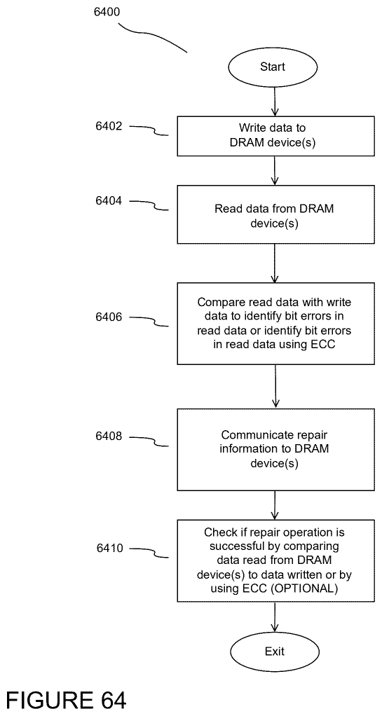

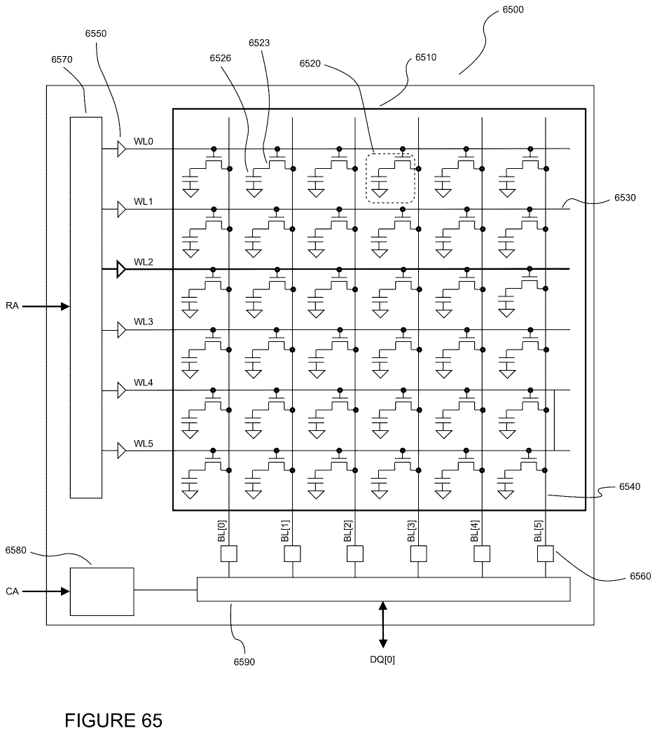

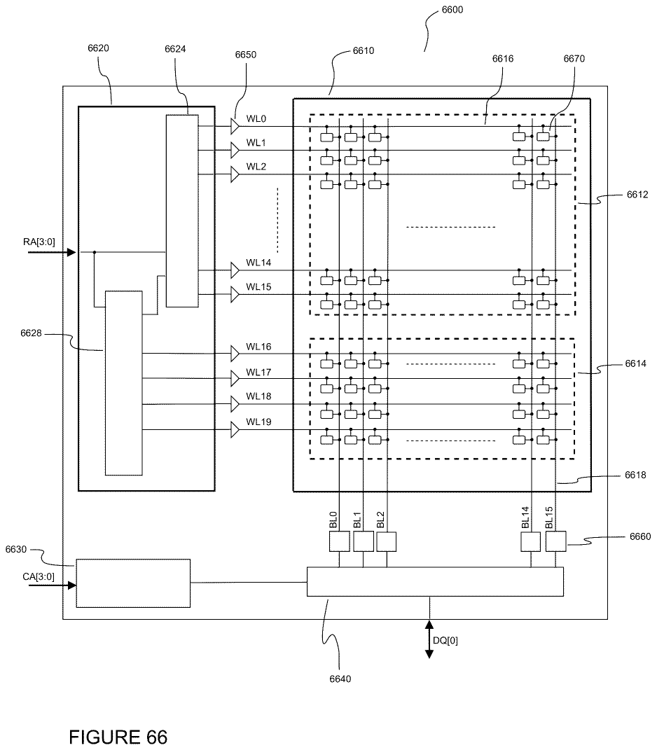

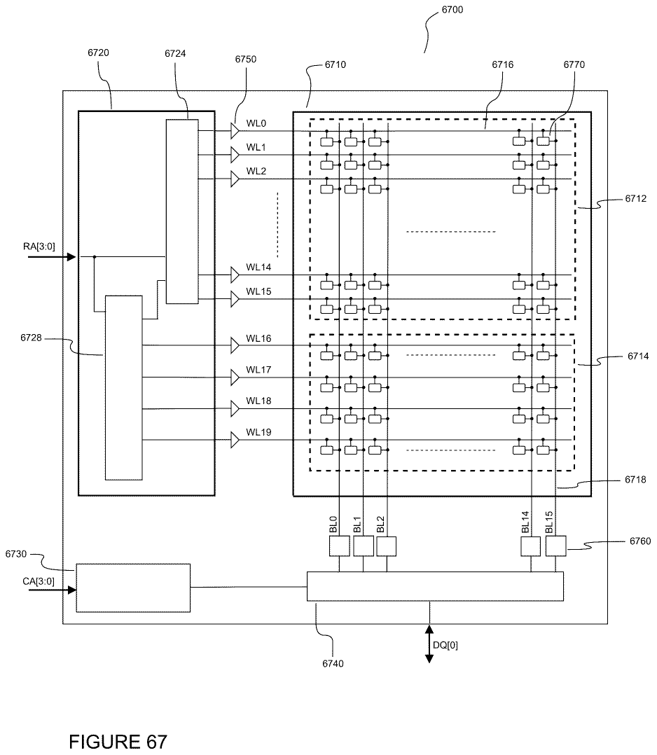

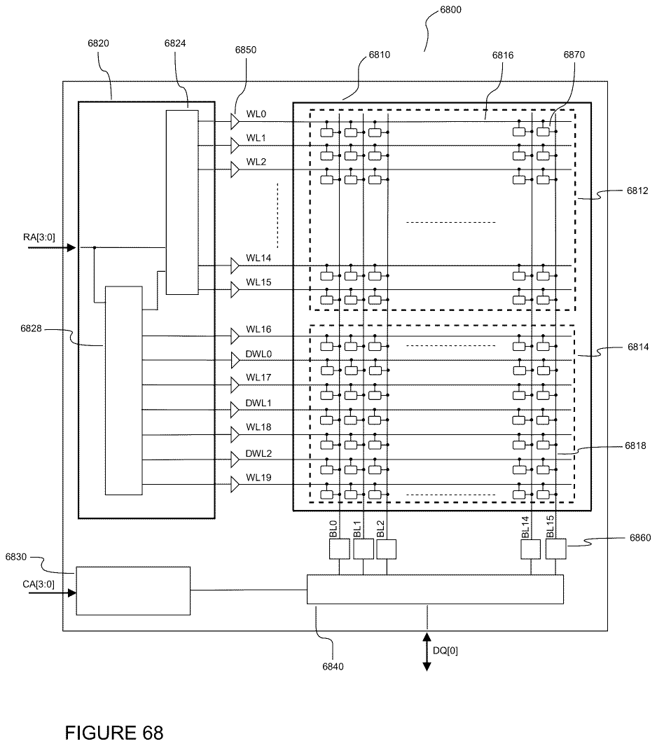

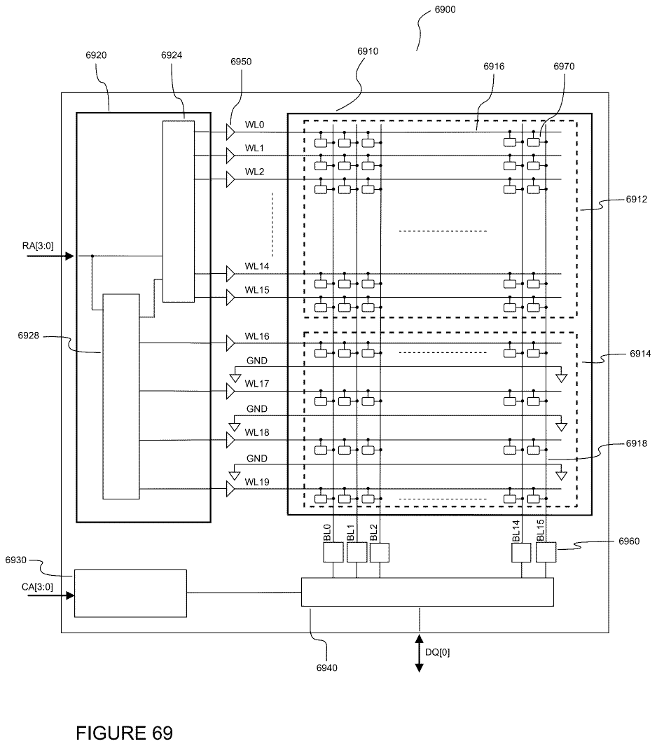

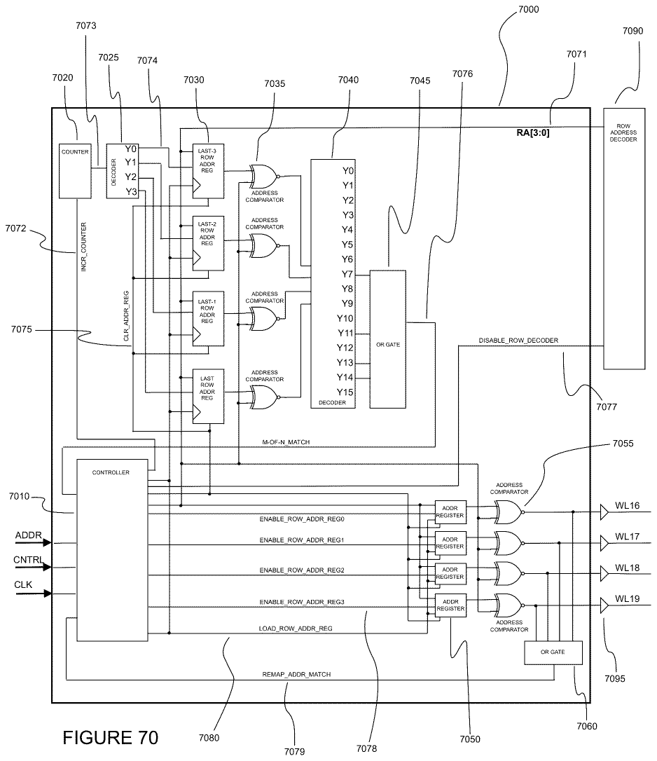

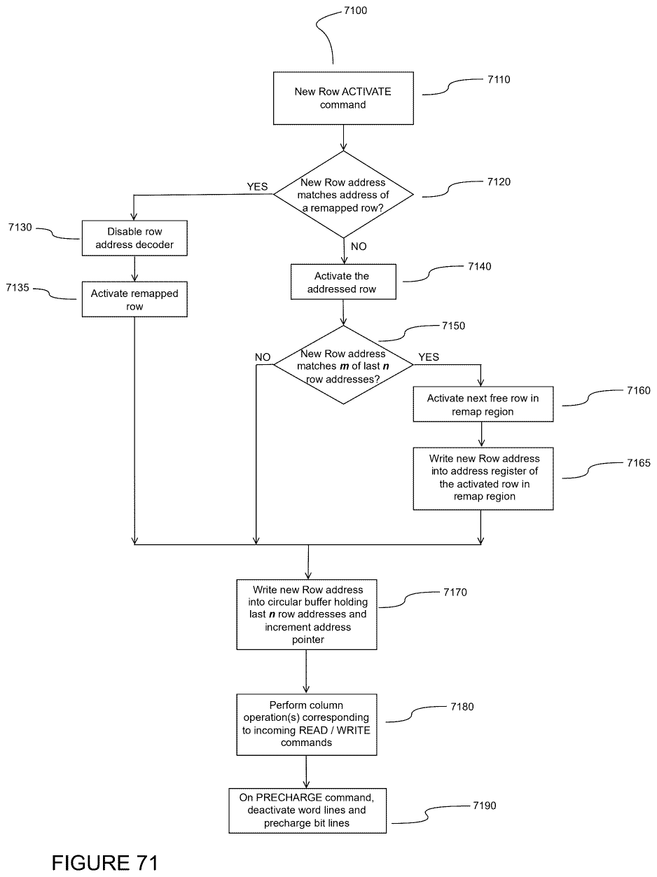

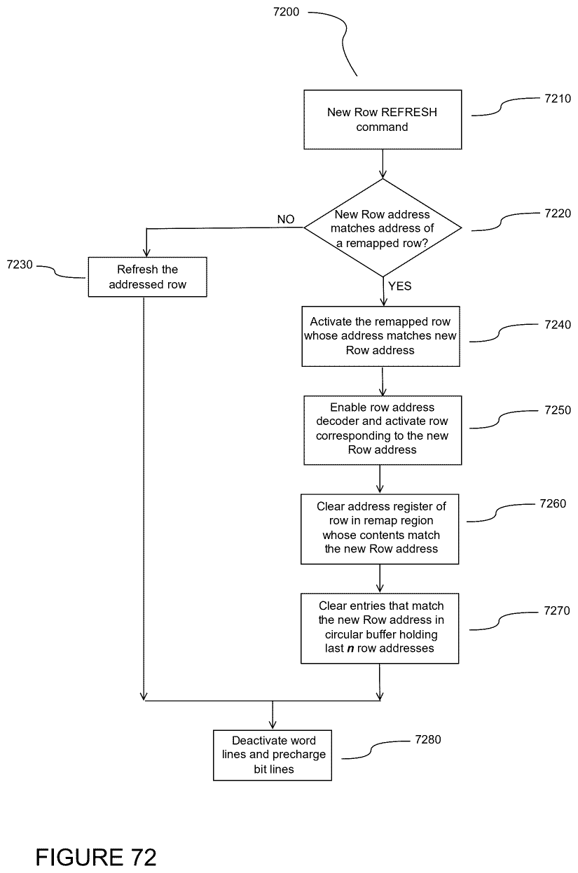

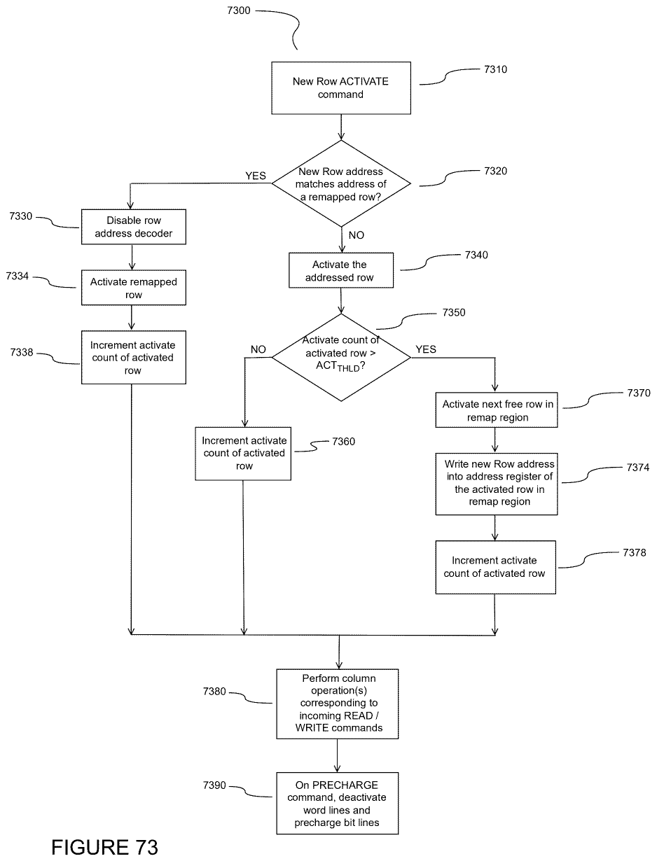

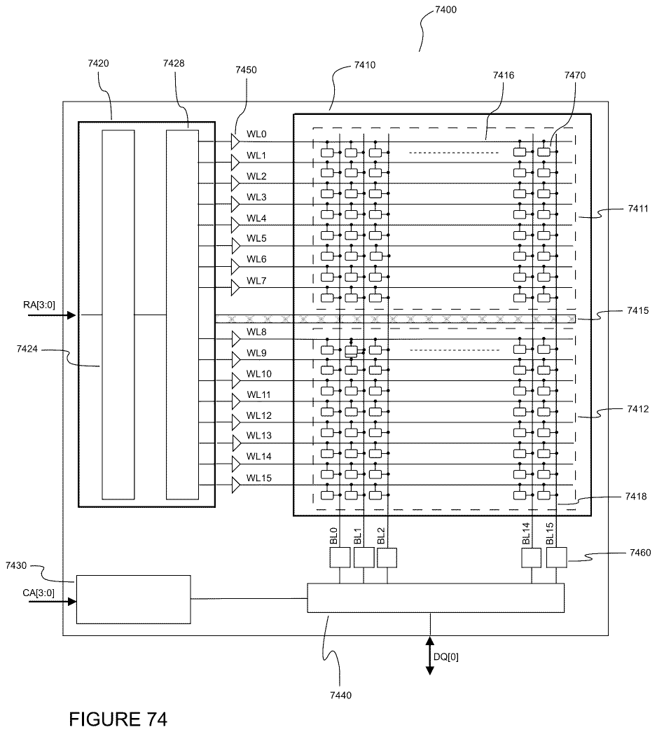

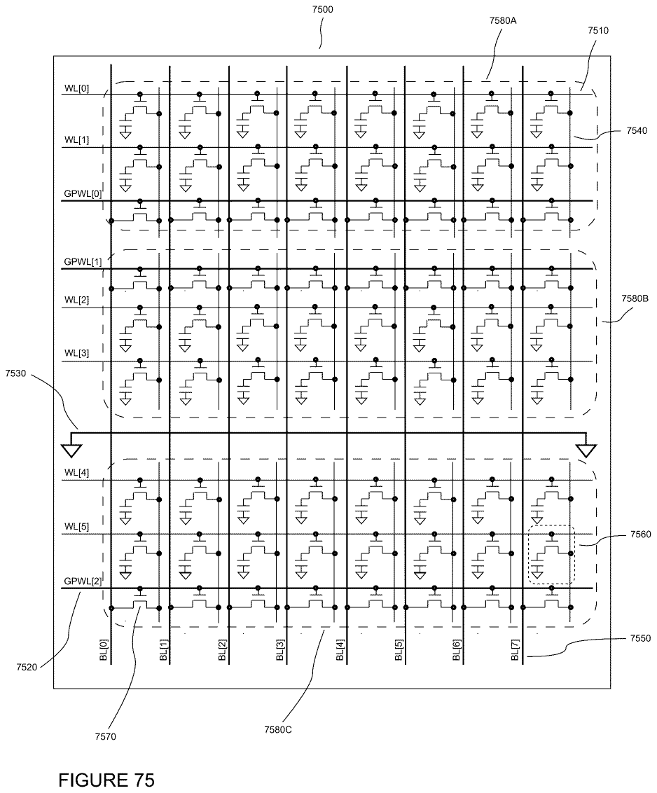

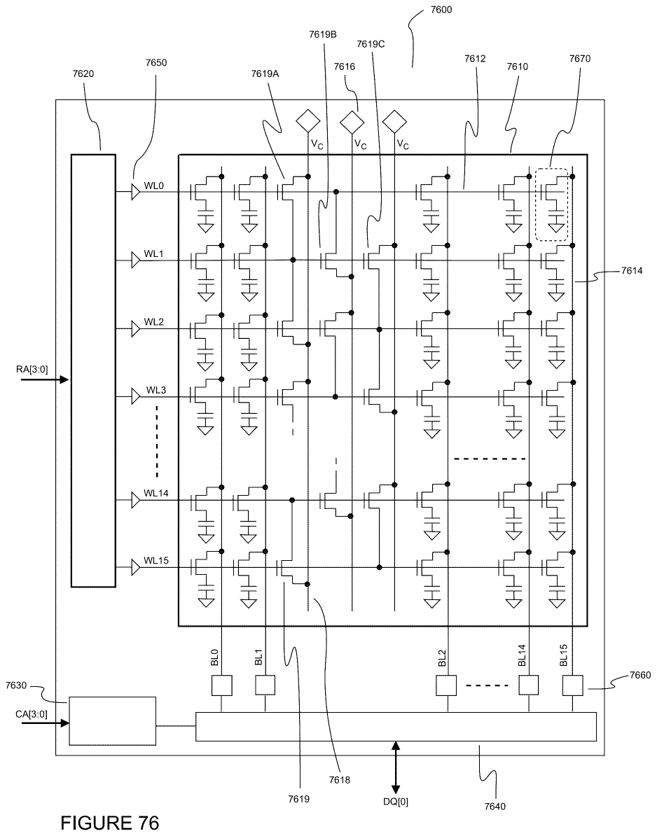

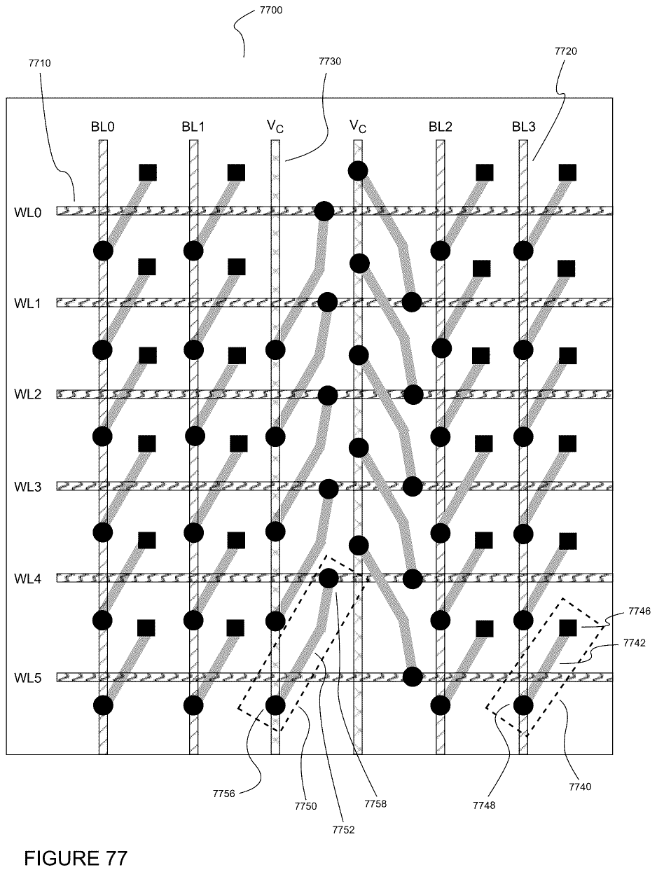

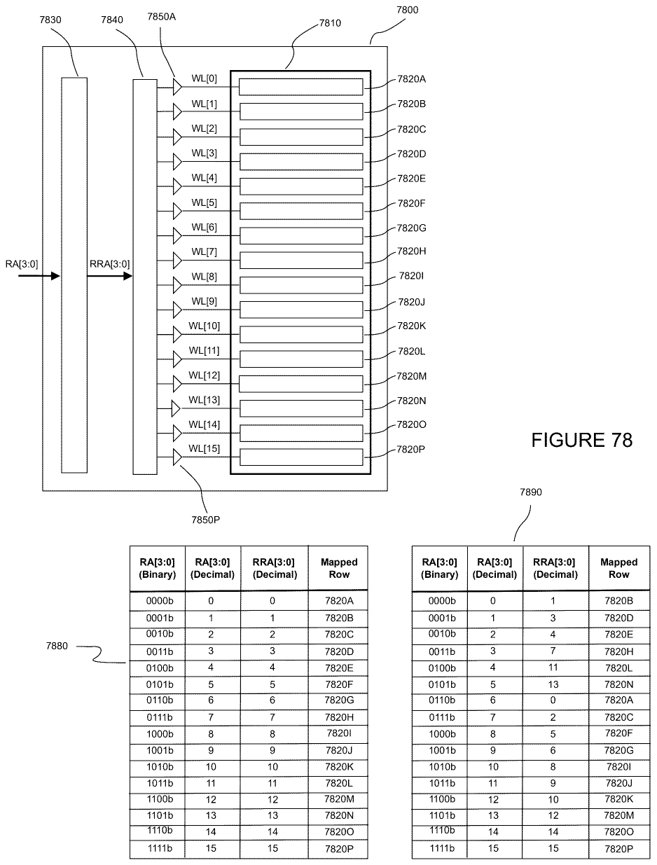

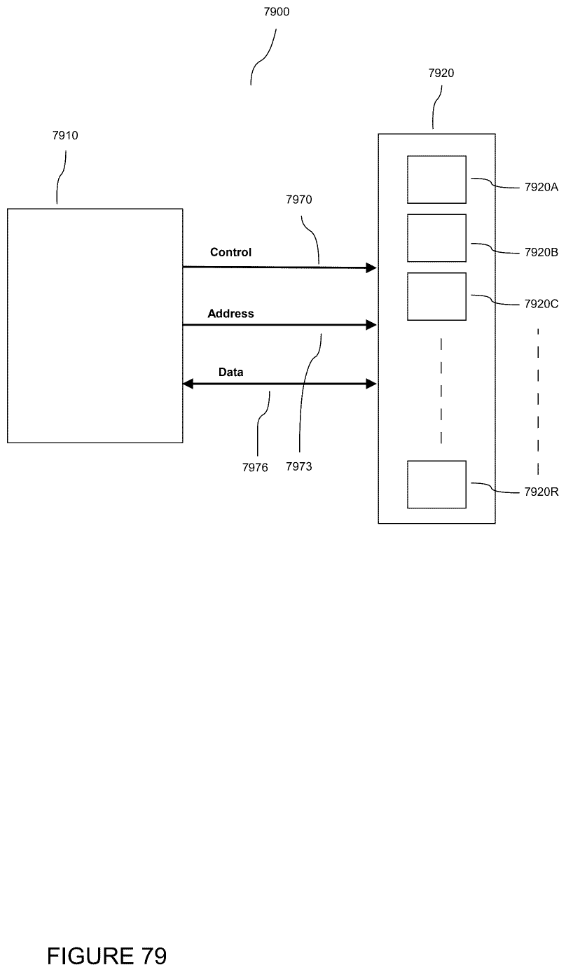

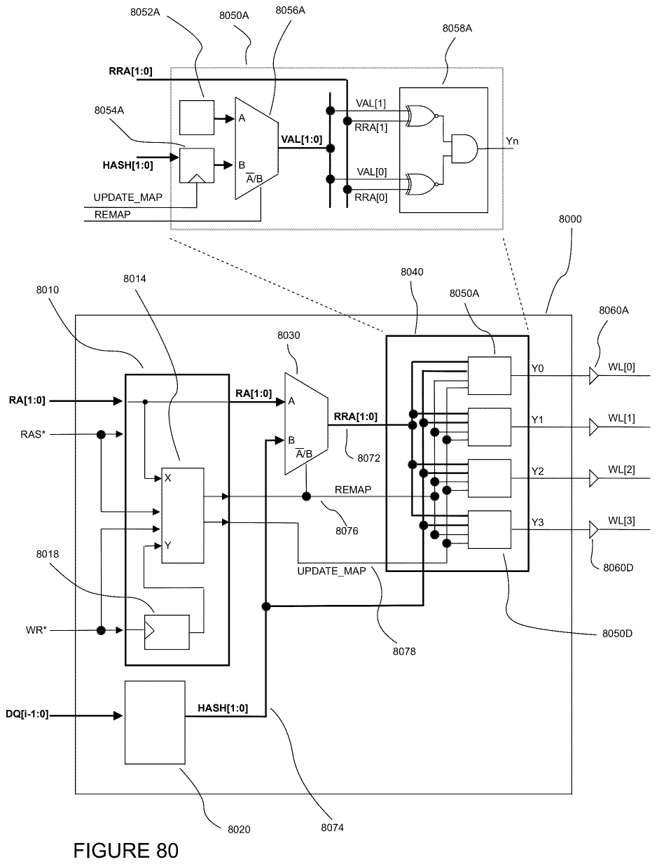

While a 16-row array is illustrated in FIG. 24 for the sake of simplicity, the remap logic may be used for any number of rows in the memory array. In the embodiment illustrated in FIG. 24 (and FIG. 25), the rows in the memory array may be assigned to one of two regions (REGION 0 or REGION 1). The assigned region number for each row may be stored in a storage element. As an example, a 0b may be stored in the storage element to indicate that a row is assigned to REGION 0 and a 1b may be stored in the storage element to indicate that a row is assigned to REGION 1. The storage element may either be volatile storage or non-volatile storage. The volatile storage may be a register, a flip-flop, an SRAM bit cell, a DRAM bit cell, or any circuit that is capable of storing one or more bits of information in a volatile manner. The non-volatile storage may be a fuse, an electrically programmable ROM (EPROM) bit cell, and electrically programmable and erasable ROM (EEPROM) bit cell, a NAND Flash bit cell, a NOR Flash bit cell, or any other circuit that is capable of storing one or more bits of information in a non-volatile manner. In various embodiments, the region number may be programmed into the storage element at any time after manufacture. For example, the region number may be programmed at the factory, during the boot operation, during run time, after error detection, upon receipt of a command from an external device, after periodic scrubbing or testing operation, etc. The region number may be programmed into a storage element for each row based on one or aspects of the DRAM device. In one embodiment, the region number may be programmed at the factory. In another embodiment, the region number may be stored external to the DRAM device and communicated to the DRAM device during boot time or during run time. In yet another embodiment, the DRAM device may itself determine the region number for each row based on one or more aspects of the DRAM device and write the region number into the storage element. It should also be noted that, in various embodiments, the region number may include any identifier (and even one that is not numeric) insofar as it is capable of identifying or being used to identify a region.

In FIG. 24, row address logic 2400 includes a 4-to-16 address decoder 2410, a 16×4 lookup table 2420 (i.e. table with 16 rows, where each row stores 4 bits), 4-bit address multiplexers 2430, 2433, and 2437, 4-bit counters 2440 and 2445, control logic 2450, 4-bit register 2455, row region blocks 2460A-2460P and word line drivers 2470A-2470P. Note that the decoder, address multiplexers, lookup table, counter, and register are all sized to match the number of rows in the memory array. If, for example, there are 1k rows in the memory array, then the decoder may be 10-to-1024, the address multiplexers, counters, and register may be 10-bits wide, and the lookup table may be 1024×10. Also, note that only row region block 2460A and word line driver 2470A are labeled in FIG. 24 to avoid cluttering the figure. Row region block 2460A (shown in expanded manner at the top of FIG. 24) includes storage element 2480A and an AND gate 2485A. It should be noted that storage element 2480A in FIG. 24 is shown as a non-volatile storage element strictly as an example. Non-volatile storage element 2480A may store the region number of row 0 of the memory array. The word line associated with row 0 is WL[0]. Similarly, non-volatile storage element 2480B may store the region number of row 1 of the array (with associated word line WL[1]), non-volatile storage element 2480C may store the region number of row 2 of the array (with associated word line WL[2]), and so on. FIG. 24 illustrates a fuse as the non-volatile storage 2480A (as an example), with the fuse being connected to VCC. In this example, AND gate 2485A may have weak pull downs (e.g. 100K resistor to GND) on its inputs. Fuse 2480A may be blown if row 0 is to be assigned to REGION 0 (i.e. 0b is stored in non-volatile storage 2480A). Then, the input of AND gate 2485A is no longer pulled up to VCC, and is, instead pulled down to GND by the pull down resistor. If 1b is to be stored (i.e. row 0 is assigned to REGION 1) in non-volatile storage 2480A, the fuse may be left intact, so that the input of AND gate 2485A may be pulled up to VCC. Note that other implementations may also be used. For example, the inputs of AND gate 2485A may have weak pull ups (e.g. 100K resistor to VCC) and the fuse may be connected to GND. As another example, a Flash bit cell may be connected to one input of AND gate 2485A and a logic 0 or a logic 1 may be stored in the Flash bit cell.

Multiplexer 2437 operates to select RA[3:0] or RRA[3:0] as the input to address decoder 2410. The selection may be determined by the logic state (0 or 1 respectively) of REMAP_ON signal 2498. Multiplexer 2437 provides the ability to bypass the remap lookup table 2420 and have RA[3:0] be the input to decoder 2410. This capability may be used, for example, during testing of the DRAM array. Multiplexer 2433 operates to select either the output of lookup table 2420 or the contents of counter B 2445 as RRA[3:0]. This selection may be determined by the logic state (0 or 1 respectively) of REMAP signal 2493. The contents of counter B 2445 may be used as RRA[3:0] during the remap operation. After the remap operation, the output of lookup table 2420 may be used as RRA[3:0]. Similarly, multiplexer 2430 operates to select either RA[3:0] or the contents of counter A 2440 as the input address of lookup table 2420. The selection may be determined by the state of REMAP signal 2493. The contents of counter A may be used as the input address to lookup table 2430 during the remap operation. After the remap operation is completed, RA[3:0] may be used as the input address to lookup table 2420. Note that the phrases “contents of counter X”, and “value of counter X” are used interchangeably in this application to mean the state of counter X's bits. For example, the state of the bits of a 4-bit counter may be 0101b (i.e. MSB=0, MSB-1=1, MSB-2=0, and LSB=1), and hence, the contents of the counter are 0101b, and the value of the counter is 0101b. Furthermore, the phrase “row pointed to by counter X” and “row pointed to by register X” used herein means the row whose address matches the state of counter X's bits or the row whose address matches the state of register X's bits. Again, as an example, if the state of the bits of a 4-bit counter is 1010b, the row pointed to by that counter will the row whose address is 1010b (i.e. row with decimal address 10).

During remap operation, counter B 2445 may be used to cycle through all the row addresses (0000b through 1111b in this example), and at each value of the counter, the stored row region number of the row pointed to by counter B 2445 may be driven onto ROW_RGN signal 2499 by the corresponding one of the row region blocks 2460A-2460P. This may then be read by control logic 2450 and a remap-or-skip action may be done, by either writing the value of counter B into the lookup table using the value of counter A as address, or skipping the current row pointed to by counter B and examining the next row respectively. The remap operation may remap all the rows assigned to REGION 0 in the first cycle or pass through all the row addresses (i.e. counter B increments from 0000b to 1111b), and may then remap all the rows assigned to REGION 1 in the second cycle or pass through all the row addresses. Register 2455 may operate to store the value of counter A 2440 after all the rows assigned to REGION 0 are remapped. Register 2455 may now indicate the address of the first row in REGION 1. Counter A 2440 may be incremented only when there is match between the current region number and the stored region number of the row being pointed to by counter B, and after the lookup table has been updated. This ensures that rows assigned to a particular region may be remapped sequentially and in ascending order, followed by rows assigned to the next region, and so on. This can be seen in table 2380 in FIG. 23, where rows 2330B, 2330D, 2330E, 2330H, 2330L, and 2330N (i.e., in ascending order) are mapped to RA[3:0]=0000b through RA[3:0]=0101b (i.e. sequentially). A more detailed explanation is illustrated in FIG. 25 and described below.

FIG. 25 shows a flow chart 2500 of the address remap logic illustrated in FIG. 24. As an option, any of the features of the present figure (and/or the description thereof) may be implemented in the context of the architecture and environment of any of the previous Figure(s) and/or any of the subsequent Figure(s).

After Power On, the remap operation may be initiated, either by a state machine in the DRAM device or on receiving a command from an external device. In step 2502, counters A and B may be reset. Then, in step 2504, REMAP and REMAP_ON signals may be driven active high while the value of an internal register REMAP_REGION may be set to 0b. Then, counter B may be used to step through all the rows in the memory array for remapping. In step 2506, the region number of the row pointed to by counter B may be read and in step 2508, the value may be compared to that of the REMAP_REGION register. If there is a match, the value of counter B may be written into the lookup table using the value of counter A as the address in step 2510. The lookup table write may be done by pulsing the UPDATE_SIGNAL high. Then, the value of counter A may be checked in step 2512 to see if it points to the last row in the array (i.e. value of counter A is 1111b). If the result of this compare operation is negative in step 2512, counter A may be incremented in step 2514. Next, the value of counter B may be checked in step 2516 to see if it points to the last row in the array (i.e. value of counter B is 1111b). If the compare operation in step 2516 returns a negative result, then counter B may be incremented in step 2524, and the state jumps to step 2506 so that the next row in the array may be examined for remapping. However, if the comparison of the region number of the current row does not match the value in the REMAP_REGION register in step 2508, counter A may not be incremented and the state may jump to step 2516. If counter B points to the last row in the memory array in step 2516, then counter B may be reset in step 2518, the value of counter A may be saved in step 2520, the value of REMAP_REGION may be set to 1b in step 2522, and a second cycle of reading the region number of all rows and comparing these to the 1b value in REMAP_REGION may be done. When all the rows in the array have been examined, first to check if they are assigned to REGION 0, and then to check if they are assigned to REGION 1, and the remap values stored in the lookup table, the value of counter A may point to the last row in the memory array in step 2512 (i.e. value of counter A will be 1111b). Then, the remap operation may be ended and the REMAP signal may be driven low. It should be noted that the remap logic of FIG. 24 and the flow chart in FIG. 25 require two cycles or passes of check/remap-or-skip operations for all the rows in the memory array since the rows are assigned to one of two regions (REGION 0 or REGION 1).

FIG. 26 illustrates remap logic 2600 in another embodiment. As an option, any of the features of the present figure (and/or the description thereof) may be implemented in the context of the architecture and environment of any of the previous Figure(s) and/or any of the subsequent Figure(s).

In this embodiment, the rows of a memory array may be assigned to one of four regions (REGION 0, REGION 1, REGION 2, or REGION 3). Hence, a 2-bit region number may be stored for each row in the array in storage elements {2680A, 2681A}-{2680P, 2681P}. That is, the 2-bit region number for row 0 of the array may be stored in storage elements 2680A and 2681A, the 2-bit number for row 1 may be stored in storage elements 2680B and 2681B, the 2-bit number for row 2 may be stored in storage elements 2680C and 2681C, and so on. The remap logic in FIG. 26 may operate in a manner similar to that of the remap logic illustrated in FIG. 24 except that 4 cycles or passes may be made through all the rows in the memory array-in the first pass, the rows programmed to be assigned to REGION 0 may be identified and their addresses stored sequentially in lookup table 2620; in the second pass, rows programmed to be assigned to REGION 1 may be identified and their addresses stored sequentially in lookup table 2620; in the third pass, rows programmed to be assigned to REGION 2 may be identified and their addresses stored sequentially in lookup table 2620; and in the fourth pass, rows programmed to be assigned to REGION 3 may be identified and their addresses stored sequentially in lookup table 2620. Similar to the remap logic shown in FIG. 24, in this embodiment, counter B 2645 may be incremented from 0000b through 1111b in each pass, and used to read the region numbers of the rows pointed to by counter B 2645. The 2-bit region number of each row may be driven onto ROW_RGN[1:0] bus 2699 during the read operation. If there is a match between ROW_RGN[1:0] value and the value of the internal register REMAP_REGION[1:0], the value of counter B may be written into the lookup table using the value of counter A 2640 as the address. Then, both counters A and B may be incremented and the process repeated for the next row. However, if there is a mismatch between ROW_RGN[1:0] and the value of REMAP_REGION[1:0], only counter B may be incremented and the process repeated for the next row. When counter B's value is 1111b, the value of counter A may be stored in one of the registers 2655A-2655C so as to mark the transition from one region to the next. Then, counter B may be reset (i.e. its contents set to 0000b), the value of REMAP_REGION[1:0] may be incremented, and the next pass through the rows may be done. The remap operation may be complete when counter A is to be incremented but its value is 1111b. As mentioned previously, address decoder 2610, lookup table 2620, address multiplexers 2630, 2633, and 2637, counter 2640 and 2645, and registers 2655A-2655C may all be sized to match the number of rows in the memory array.

FIG. 27 shows the flow chart 2700 of the remap operation of the embodiment illustrated in FIG. 26. As an option, any of the features of the present figure (and/or the description thereof) may be implemented in the context of the architecture and environment of any of the previous Figure(s) and/or any of the subsequent Figure(s).

After power is applied to the DRAM device, counters A and B may be reset in step 2702. Then, REMAP and REMAP_ON may be driven active high and 00b written to REMAP_REGION register in step 2704. Then, the region number of the row pointed to by counter B may be read in step 2706 and compared with the value of REMAP_REGION register in step 2708. If there is a match, the value of counter B may be written to the lookup table using the value of counter A as the address in step 2710. Then, if the value of counter A is not 1111b in step 2712, it may be incremented in step 2714. Then, counter B's value may be checked to see if it is 1111b in step 2716. If it is not, then counter B's value may be incremented in step 2724 and the process repeated for the row now being pointed to by counter B. However, if the value of counter B in step 2716 is equal to 1111b, then counter B may be reset in step 2718, the value of counter A may be saved in a register in step 2720, the value in REMAP_REGION may be incremented in step 2722, and the next pass through all the rows may be done. When counter A's value in step 2712 is equal to 1111b, the remap operation may be complete and REMAP signal may be driven low in step 2726. It should be noted that the remap logic of FIG. 26 and the flow chart in FIG. 27 require four cycles or passes of check/remap-or-skip operations for all the rows in the memory array since the rows are assigned to one of four regions (REGION 0, REGION 1, REGION 2, or REGION 3).

FIG. 28 illustrates remap logic 2800 of another embodiment. As an option, any of the features of the present figure (and/or the description thereof) may be implemented in the context of the architecture and environment of any of the previous Figure(s) and/or any of the subsequent Figure(s).

In this embodiment, only a single cycle or pass through all the rows in a memory array may be required to remap the rows to one of two regions (REGION 0 or REGION 1). Since a 2-region remap is illustrated, the region number for each row may be stored in storage element (2880A-2880P) that is capable of storing a 1-bit number. In this embodiment, remap logic 2800 includes row address decoder 2810, lookup table 2820, address multiplexers 2830, 2832, 2834, and 2836, counters 2840 (counter A), 2843 (counter B), and 2847 (counter C), control logic 2850, register 2855, row region circuits 2860A-2860P, and word line drivers 2870A-2870P. Row region circuit 2860A is shown in more detail at the top of the figure, and includes storage element 2880A. As in other embodiments, FIG. 28 shows a fuse 2880A as the storage element that stores the region number of each row, strictly as an example. Fuse 2880A acts as a strong pull up to VCC on one input of an AND gate, which may also have a weak pull down to GND. Fuse 2880A is blown if row 0 is assigned to REGION 0 as the weak pull down will result in a logic 0 being applied to the input of the AND gate. Fuse 2880A is kept intact if row 0 is assigned to REGION 1 as the fuse will ensure a logic 1 is applied to the input of the AND gate. However, other volatile storage elements or non-volatile storage elements may be used to store the region number of each row. When REMAP signal 2891 and REMAP_ON signal 2897 are high, counter C 2847 may provide the row address (through multiplexers 2834 and 2836) to row decoder 2810. The region number of the row being pointed to by counter C 2847 may be driven onto ROW_RGN signal 2899 and read by the control logic 2850. Depending on the value of the ROW_RGN signal 2899, control logic 2850 operates to store the value of counter C 2847 into the lookup table using either the value of counter A 2840 or counter B 2843 as the address. Multiplexer 2832 operates to select either counter A 2840 or counter B 2843 as the source of the address for the lookup table write based on the value of ROW_RGN signal 2899. Control logic 2850 also operates to reset counters A and C, and load counter B with 1111b at the start of the remap operation. It also operates to increment counters A and C (e.g. after the value of counter C is stored in the lookup table using value of counter A as the address for the write), or operates to increment counter C and decrement counter B (e.g. after the value of counter C is stored in the lookup table using value of counter B as the address for the write). Control logic 2850 may further operate to load the value of counter A into register 2855 at the end of the remap operation.

The flow chart 2900 of the remap operation of the embodiment illustrated in FIG. 28 is shown in FIG. 29. As an option, any of the features of the present figure (and/or the description thereof) may be implemented in the context of the architecture and environment of any of the previous Figure(s) and/or any of the subsequent Figure(s).

After power is applied to the DRAM device, counters A and C may be reset while counter B may be loaded with 1111b in step 2902. Then, REMAP and REMAP_ON signals may be driven high and 0b written to REMAP_REGION register in step 2904. Then, the region number of the row pointed to by register C may be read in step 2906 and compared to the region value in REMAP_REGION in step 2908. In the event of a match, the value of counter C may be written into the lookup table using the value of counter A as the address in step 2910. Then counter A may be incremented in step 2912. However, if the comparison in step 2908 returns a mismatch, the value of counter C may be written into the lookup table using the value of counter B as the address in step 2914. Then, the value of counter B may be decremented in step 2916. Next, the value of counter C may be checked to see if it matches 1111b in step 2918. If there is a mismatch, counter C may be incremented in step 2920 and the next row in the array remapped. However, if the comparison in step 2918 returns a match, the value of counter A may be saved in a register in step 2922. Next, REMAP may be driven low and REMAP_ON may be driven high in step 2924 and the remap operation may be ended.

FIG. 30 illustrates the row remapping of the embodiment illustrated in FIG. 28 and FIG. 29 in table 3080. As an option, any of the features of the present figure (and/or the description thereof) may be implemented in the context of the architecture and environment of any of the previous Figure(s) and/or any of the subsequent Figure(s).

DRAM bank 3000 includes memory array 3010, row address remap logic 3020, row address decoder 3040, and word line drivers 3050A-3050P. Memory array 3010 includes sixteen rows of bit cells 3030A-3030P. Note that FIG. 30 illustrates the same assignment of rows to regions as previously illustrated in FIG. 23. As in FIG. 23, the rows assigned to REGION 0 (i.e. 3030B, 3030D, 3030E, 3030H, 3030L, and 3030N) may be remapped in ordered (i.e. ascending, and sequential) manner to RA[3:0]=0000b through RA[3:0]=0101b. That is, the remapping of rows in REGION 0 in FIG. 30 may exactly match the remapping of REGION 0 rows in FIG. 23. However, rows assigned to REGION 1 may be remapped in descending order (and sequentially) in FIG. 30 whereas they may be remapped in ascending order and sequentially in FIG. 23. For example, row 3030A may be assigned to REGION 1 and remapped to RA[3:0]=1111b in FIG. 30, while row 2330A may be assigned to REGION 1 and remapped to RA[3:0]=0110b in FIG. 23. That is, row 2330A may be remapped to be the first row in REGION 1 in FIG. 23 while row 3030A may be remapped to be the last row in REGION 1 in FIG. 30. Table 3080 in FIG. 30 shows that the rows remapped to REGION 0 may have internal addresses 1, 3, 4, 7, 11, and 13 (i.e. in ascending manner, same as the remapping in FIG. 23) but rows remapped to REGION 1 may have internal address 15, 14, 12, 10, 9, 8, 6, 5, 2, and 0 (i.e. in descending manner, reverse of the remapping in FIG. 23). The embodiment illustrated in FIG. 28 and FIG. 29, may remap REGION 0 rows in ascending manner while remapping REGION 1 rows in descending manner because there is no a priori information about the number of rows assigned to each region. Hence, in this embodiment, counter A 2840 (of FIG. 28) may be incremented from 0000b while counter B 2843 (of FIG. 28) may be decremented from 1111b after an entry is made into the lookup table for a row assigned to REGION 0 or REGION 1 respectively. Note that counter A 2840 may be used as the address for lookup table writes for REGION 0 rows and counter B 2843 may be used as the address for lookup table writes for REGION 1 writes.

In another embodiment, where there is no a priori information about the number of rows assigned to each region, a first pass or cycle may be done through all the rows in the memory array and a count may be kept as to the number of rows assigned to REGION 0. In this pass, no writes to the lookup table may be done. For example, if 4 of the 16 rows in the memory array are assigned to REGION 0, the enumerated count after the first pass may be 0100b. Referring to FIG. 28, once the number of rows in REGION 0 is enumerated, this value may be written to counter B 2843 to indicate the address of the first row in REGION 1. Alternately, each time a REGION 0 row is detected in the first (i.e. enumeration) pass, control logic 2850 may increment counter B 2843 by pulsing high the DECR_CNTR_B signal 2884. In this embodiment, signal 2884 may properly be labeled as INCR_CNTR_B, and not DECR_CNTR_B. Similarly, in this embodiment, control logic 2850 may clear counter B 2843 at the start of the remap operation instead of loading it with 1111b. Hence, in this embodiment, signal 2883 may properly be labeled RESET_CNTR_B, and not LOAD_CNTR_B. In this embodiment, the first pass or cycle through all the rows may be referred to or called or treated as the enumeration pass or cycle. Then, a second pass or cycle may be made through all the rows and the lookup table updated with the entry for each row. This second pass may be referred to or called or treated as the remap pass or cycle. As before, the value of counter A 2840 may be used as the address for the lookup table write if the region number of the current row being pointed to by counter C 2847 is 0b (i.e. assigned to REGION 0) or the value of counter B 2843 may be used as the address for the lookup table write if the region number of the current row being pointed to by counter C 2847 is 1b (i.e. assigned to REGION 1). In this embodiment, however, the value of counter B 2843 may be incremented after it has been used as the address for a lookup table write. Of course, as in other embodiments, the value of counter A 2840 may be incremented after it has been used as the address for a lookup table write. The remapping in this embodiment may result in ascending and sequential remapping of rows in both regions. That is, the resulting remapping may be the same as that illustrated in table 2380 in FIG. 23.

In another embodiment, the size(s) of one or more of the regions may be communicated to the DRAM device by an external device. For example, in the case of remapping rows to one of two regions, the size of the first region or the size of the second region may be communicated to the DRAM device. The DRAM device may then use this information to determine the starting address in the lookup table for REGION 1, load this value into a counter (e.g. counter B 2843 of FIG. 28) at the start of the remap operation (e.g. in step 2902 of FIG. 29), and increment this counter after it has been used as the address to the lookup table for a write to the lookup table (e.g. in step 2916 of FIG. 29, except the counter is incremented and not decremented).

In yet another embodiment, the size(s) of one or more regions may be stored in the DRAM device itself in a non-volatile storage (e.g. fuses, EPROM bit cells, EEPROM bit cells, etc.). In this embodiment, the DRAM device may read the stored values, and optionally, use the values in one or more calculations, and write the starting addresses of the one or more regions in the lookup table into one or more counters, and perform the remapping operation. For example, the size of REGION 0 may be stored in non-volatile storage in the DRAM device. After power on, the DRAM device may read this value, compute the starting address of REGION 1 in the lookup table, write this value to a counter (e.g. counter B 2843 of FIG. 28) at the start of the remap operation (e.g. in step 2902 of FIG. 29), and perform the remapping operation.

While a 2-region remap logic is illustrated in FIG. 28, it can be easily modified to support remapping to more than 2 regions. For example, for a 4-region remapping, the enumeration pass or cycle described in the above embodiment may be modified to keep count of the number of rows in each of the four regions. At the end of the enumeration pass or cycle, the count of the number of rows in REGION 1, REGION 2, and REGION 3 may be written to 3 counters (e.g. counters 2840B-2840D) and 3 registers (e.g. 2855A-2855C). The counter corresponding to REGION 0 (e.g. counter 2840A) may be reset before, during, or after the enumeration pass. Hence, after the enumeration pass or cycle, counter 2840A may point to the first row in REGION 0 in the lookup table, counter 2840B may point to the first row in REGION 1 in the lookup table, counter 2840C may point to the first row in REGION 2 in the lookup table, and counter 2840D may point to the first row in REGION 3 in the lookup table. Note that counter B 2843 may not be needed in this embodiment. As before, counter C 2847 may be used to cycle through all the rows in the memory array. A 4-to-1 address multiplexer (e.g. 2832A) may be used to select the source of the address for a lookup table write based on the region number (i.e. value of ROW_RGN [1:0]) of the row being pointed to by counter C. The remapping in this embodiment may result in ascending and sequential remapping of rows in all four regions.

FIG. 31 illustrates remap logic 3100 in yet another embodiment. As an option, any of the features of the present figure (and/or the description thereof) may be implemented in the context of the architecture and environment of any of the previous Figure(s) and/or any of the subsequent Figure(s).

For the sake of clarity, the remap logic is illustrated in this figure for a memory array with 4 rows. However, the remap logic in this figure can easily be extended to support memory arrays with any number of rows. Remap logic 3100 includes address decoder 3110 address multiplexer 3120, counter A 3130, counter B 3135, register 3140, control logic 3150, row region blocks 3170A-3170D, and word line drivers 3180A-3180D. Address decoder 3110 includes four row address blocks 3160A-3160D, one per row of the memory array. Row address block 3160A is shown expanded at the top left of the figure while row region block 3170A is shown expanded at the top right of the figure.

Row address block 3160A includes registers 3163A and 3166A, multiplexer 3168A, and logic gates to compare VAL [1:0], the output of multiplexer 3168A, with RRA[1:0]. Register 3163A may hold the default row address of row 0 (associated with WL[0]) while register 3166A may hold the remapped row address of row 0. The default row address in register 3163A may be hard wired in the design or may be written after power is applied to the DRAM device, and may be the address of row 0 before remapping. Although a register (e.g. 3163A) is shown as holding the default address of a row (e.g. row 0), the default address may be hard wired in the row address block (e.g. 3160A). Register 3166A may be written with the value of counter A 3130 by pulsing UPDATE_MAP signal 3197 active high. Row region blocks 3170A-3170D may include storage elements 3175A-3175D respectively. When REMAP signal 3195 is active high, applying a row address on RRA[1:0] may return the region number of the corresponding row on ROW_RGN signal 3199. Multiplexer 3120 may operate to select either external row address RA[1:0] or the value of counter B 3135 (i.e. CNTR_B[1:0]) as the internal row address RRA[1:0] based on the logic value of REMAP signal 3195. Control logic 3150 may operate to reset counters A and B (through RESET_CNTR_A signal 3191 and RESET_CNTR_B signal 3193 respectively), and also increment counters A and B (through INCR_CNTR_A signal 3192 and INCR_CNTR_B signal 3194 respectively). Control logic 3150 may also act to store the value of counter A in register 3140 through the SAVE_CNTR_A_VAL signal 3196.

As in the previous embodiments, counter B 3135 may be used to step through the rows in the memory array during remap operation. At each value of counter B, the row region number of the corresponding row may be read on ROW_RGN signal 3199. In the event of a match between the value of ROW_RGN and the region value in an internal register REMAP_REGION (not shown in the figure), the value of counter A may be written into the remap row address register 3166A-3166D associated with the current row. Note that control logic 3150 may generate unique Enable signals to each of the row address blocks 3160A-3160D, so as to write the value of counter A 3130 into the row address block associated with the row currently being remapped. These Enable signals are not shown in FIG. 31 to avoid cluttering the figure. At the end of the remap operation, REMAP signal 3195 may be driven low and REMAP_ON signal 3198 may be driven high by control logic 3150, which may ensure that the remap row addresses in registers 3166A-3166D are compared with external row address RA[1:0] during normal operation of the DRAM device.

FIG. 32 illustrates the flow chart 3200 of the embodiment shown in FIG. 31. As an option, any of the features of the present figure (and/or the description thereof) may be implemented in the context of the architecture and environment of any of the previous Figure(s) and/or any of the subsequent Figure(s).

After power is applied to the DRAM device, counters A and B may be reset in step 3202. Then, REMAP signal may be driven high, REMAP_ON signal driven low, and a value of 0b stored in internal register REMAP_REGION in step 3204. The region number of the row pointed to by counter B may be read in step 3206 and compared with the value in REMAP_REGION in step 3208. In the event of a match, the value of counter A may be written into the remap row address register (one of 3166A-3166D in FIG. 31) of the corresponding row (i.e. row pointed to by counter B) in step 3210. Next, counter A's value may be checked to see if it matches 11b in step 3212. If there is no match, then counter A may be incremented in step 3214. Next, counter B's value may be checked to see if it matches 11b in step 3216. In the case of a mismatch, counter B may be incremented in step 3224, and the flow may return to step 3206 to examine and possibly remap the next row. However, if counter B's value matches 11b in step 3216, counter B may be reset in step 3218, the value of counter A may be stored in step 3220, a value of 1b may be written into the REMAP_REGION register in step 3222, and the flow may return to step 3206 to examine and remap the rows assigned to REGION 1. If the comparison of counter A's value and 11b returns a match in step 3212, then REMAP signal may be driven low while REMAP_ON signal may be driven high in step 3226, and the remap operation exited.

It should be noted that all the embodiments illustrated in this application describe remapping of rows of a memory array into 2 regions or 4 regions. However, all the embodiments may be easily extended to 3 regions, 5 regions, or any number of regions.

It should also be noted that all the embodiments illustrated so far in this application describe remapping of rows of a memory array on a per-row basis. That is, the granularity of the remapping operation or the unit for remapping is one row. However, the embodiments may be easily modified for remapping a plurality (or set) of rows as the unit for remapping, as shown in FIG. 33, wherein remap logic 3300 operates to remap a set of four rows as the unit or granularity of remapping. Of course, any plurality of rows may be grouped into a unit of remapping. Strictly as an example, FIG. 33 illustrates remapping of a memory array with sixteen rows. As an option, any of the features of the present figure (and/or the description thereof) may be implemented in the context of the architecture and environment of any of the previous Figure(s) and/or any of the subsequent Figure(s).

Remap logic 3300 includes address decoder 3310, lookup table 3320 address multiplexers 3330, 3332, and 3335, counters 3340 (counter A) and 3345 (counter B), register 3355, control logic 3350, row region blocks 3360A-3360D, and word line drivers 3370A-3370P. In this embodiment, only the first row in the set of four rows may have an associated region block 3360A-3360D. As in previous embodiments, region blocks 3360A-3360D may include storage elements 3380A-3380D, which are shown as fuses pulled up to VCC in this figure strictly as an example. As before, and strictly as an example, AND gates 3385A-3385D may have weak pull downs (e.g. 100k resistor to GN) on the input pins. The input to the address decoder 3310 is from multiplexer 3335, which operates to select either RA[3:0] or RRA[3:0] as the output based on the logic state of REMAP_ON signal 3398. Multiplexer 3335 may enable direct access from an external device (e.g. controller, automatic test equipment, etc.) to the memory array, for example, during testing of the array.

In operation, counter A 3340 and counter B 3345 may be reset by control logic 3350 at the start of the remapping operation. Control logic 3350 may read the row region number of row 0 on ROW_RGN signal 3399. If there is a match between ROW_RGN and the value in the internal REMAP_REGION register, the value of counter B 3345 may be stored in the lookup table 3320 using the value of counter A 3340 as the address. Then, counters A and B may be incremented three times, and at each increment, the value of counter B may be stored in the lookup table using the value of counter A as the address. Then, counters A and B may be incremented again, and the row region number of the row pointed to by counter B may be read and compared to the REMAP_REGION register value. If, however, there is no match between ROW_RGN and the REMAP_REGION register value, counter B may be incremented four times, and the region number of the row pointed to by counter B now may be read and compared to the REMAP_REGION value. That is, control logic 3350 may successively read the region values of rows 0, 4, 8, and 12 (decimal) on ROW_RGN signal 3399. If there is a match between the ROW_RGN value and the value of REMAP_REGION internal register, the row pointed to by counter B and the three successive rows (i.e. all four rows in a set) may be remapped. As in several of the embodiments described previously, sets of rows assigned to REGION 0 may be first identified and remap information written to the lookup table, and then sets of rows assigned to REGION 1 may be identified and remap information written to the lookup table. The transition between REGION 0 and REGION 1 may be stored in register 3355.

In the embodiments illustrated previously, a region number may be assigned to a plurality of bit cells and stored in volatile or non-volatile storage before the remap operation. In one embodiment, a plurality of bit cells may be tested as part of the remap operation and remapped to a one of a plurality of regions. That is, the region number of the plurality of bit cells being tested may be inferred from the result(s) of the test. This embodiment is illustrated in FIG. 34. As an option, any of the features of the present figure (and/or the description thereof) may be implemented in the context of the architecture and environment of any of the previous Figure(s) and/or any of the subsequent Figure(s).

Note that, in this figure, a row of bit cells is shown as the plurality of bit cells to be remapped, and furthermore, the rows are to be remapped to either REGION 0 or REGION 1 based on one or more aspects of the memory device, strictly as an example. Other groupings of bit cells may be mapped to any number of regions by appropriate modifications.

In FIG. 34, remap logic 3400 includes address decoder 3410, lookup table 3420, multiplexers 3430, 3432, 3434, and 3436, counters 3440, 3443, and 3447, control logic 3450, and 4-bit register 3455. In operation, control logic 3450 may reset counter A 3440 and counter C 3447, and may load counter B 3443 with 1111b through RESET_CNTR_A signal 3481, RESET_CNTR_C signal 3485, and LOAD_CNTR_B signal 3483 respectively. Control logic 3450 may also increment counter A and counter C, and decrement counter B by INCR_CNTR_A signal 3482, INCR_CNTR_C signal 3486, and DECR_CNTR_B signal 3484 respectively. Multiplexer 3432 operates to select either the contents of counter A or the contents of counter B as its output based on the value of the ROW_RGN signal 3491 from control logic 3450. Multiplexer 3430 may select RA[3:0] as the input to lookup table 3420 during normal operation and may select the output of multiplexer 3432 as the input address to lookup table during remap operation, when REMAP signal 3494 from control logic 3450 is high. Multiplexer 3434 may select the output of the lookup table as the source of RRA[3:0] during normal operation and select the contents of counter C as RRA[3:0] during remap operation, when REMAP signal is high. Multiplexer 3436 may select RA[3:0] as the input address to decoder 3410 before remap is enabled (i.e. when REMAP_ON signal 3495 is low; for example, during testing of array after manufacture), and may select RRA[3:0] as the input to address decoder 3410 after remap operation has been completed. ROW_TEST_VAL signal 3497 may be input to control logic 3450 and may communicate the result(s) of the test of the row being pointed to by counter C during remap operation, where the test is based on one or more aspects of the memory device.

FIG. 35 shows the flow chart 3500 of the remap operation in the embodiment of FIG. 34. As an option, any of the features of the present figure (and/or the description thereof) may be implemented in the context of the architecture and environment of any of the previous Figure(s) and/or any of the subsequent Figure(s).

After power is applied to the memory device, counters A and C may be reset while counter B may be loaded with 1111b in step 3502. Next, REMAP and REMAP_ON signals may be driven high in step 3504. Then, the row pointed to by counter C may be tested on one or more aspects of the memory device. For example, a write-read-compare sequence may be performed on the row using a specific data pattern to measure the minimum time needed for a write to be successful. In another example, a write-read-compare operation may be performed on the row with a specific time interval between the write and the read operations to measure the retention time of the cells in the row. The test may be performed based on one or more aspects of a first region, wherein the first region has the more desirable aspects. For example, a first region may be defined as having a retention time of x ns while a second region may be defined as having a retention time of y ns. In the case of x>y, the row may be tested for retention time of x ns. The result of the test may be checked in step 3508. If the result is positive or TRUE (e.g. the row exhibits the desired one or more aspects of the first region), then the row may be remapped to a first region by writing the contents of counter C into the lookup table using the contents of counter A as the address. This may be done in step 3510. Then, counter A may be incremented in step 3512. However, if the result of the step is negative or FALSE (e.g. the row does not exhibit the desired one or more aspects of the first region), the row may be mapped to a second region by writing the contents of counter C into the lookup table using the contents of counter B as the address. This may be done in step 3514. Then, counter B may be decremented in step 3516. Next, the contents of counter C may be compared to 1111b in step 3518. If the comparison returns a false result, counter C may be incremented in step 3520 and the flow may return to step 3506, so that the next row may be tested and remapped. However, if the comparison in step 3518 returns a true result, then the value of counter A may be stored in a register in step 3522. Finally, the remap operation may be ended in step 3524 by driving REMAP signal low while continuing to drive REMAP_ON signal high.

In the embodiments illustrated previously, the remap logic is shown to use one or more counters for assigning the remapped addresses. As a result, the remapped addresses are assigned sequentially. For example, if rows with addresses x, x+n, and x+m (where n<m) are to be remapped to a first region, the use of counters for assigning remapped addresses may result in rows with addresses x, x+n, and x+m being remapped to addresses y, y+1, and y+2, or to addresses y, y−1, and y−2 respectively depending on whether a counter in the remap logic is being incremented or decremented. However, the use of counters for remapping is a design choice and is shown strictly as an example. Other logic circuits or design choices may be used in the remap logic. For example, in the embodiment illustrated in FIG. 24, counter B 2445 may be replaced with a circuit or logic block that generates a random or pseudo-random number between 0000b and 1111b each time control logic 2450 pulses the INCR_CNTR_B signal 2495 high. An example of a pseudo-random number generator is an LFSR, a linear feedback shift register. In another example, counter B 2445 in FIG. 24 may be replaced with a circuit or logic block that generates a 4-bit Gray code. Of course, other design choices are also possible. For example, random or pseudo-random number generator may be used instead of counter C 2847 in FIG. 28.

FIG. 36 shows an example row remapping using a random or pseudo-random number generator in the remap logic. As an option, any of the features of the present figure (and/or the description thereof) may be implemented in the context of the architecture and environment of any of the previous Figure(s) and/or any of the subsequent Figure(s).

DRAM bank 3600 includes memory array 3610, row address remap logic 3620, row address decoder 3640, and word line drivers 3650A-3650P. Memory array 3610 includes sixteen rows of bit cells 3630A-3630P. Note that FIG. 36 illustrates the same assignment of rows to regions as previously illustrated in FIG. 23 and FIG. 30. As in FIG. 23 and FIG. 30, rows 3630B, 3630D, 3630E, 3630H, 3630L, and 3630N may be assigned to REGION 0 and remapped to RA[3:0]=0000b through RA[3:0]=0101b. However, the remapping may be done in a random or pseudo-random manner, and not in the sequential manner shown in FIG. 23 and FIG. 30. Similarly, the rows assigned to REGION 1 may be remapped to RA[3:0]=0110b through 1111b, but the remapping may be done in a random or pseudo-random manner, and not in the sequential manner shown in FIG. 23 and FIG. 30.

FIG. 37 shows memory system 3700, which includes controller 3720 and DRAM device 3740. As an option, any of the features of the present figure (and/or the description thereof) may be implemented in the context of the architecture and environment of any of the previous Figure(s) and/or any of the subsequent Figure(s).

Controller 3720 may be a memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, or any device that is capable of being in communication with a DRAM device. Control signals 3770 and address 3773 may mostly flow from the controller 3720 to the DRAM device 3740 while data signals 3776 may flow bi-directionally between the DRAM device and controller. DRAM device 3740 is shown to include four banks 3745, 3746, 3747, and 3748, as well as I/O circuit block 3742, but of course DRAM device 3740 may include a different number of banks. Note that the term bank may typically be used in the context of a DRAM device. In the context of a Flash device, the term plane may be used equivalently. Bank and plane may both refer to a memory array that is capable of performing memory accesses in parallel with accesses to other arrays, and has an external address that is unique to it. That is, each bank or plane or array may be addressed uniquely.

In various embodiments, DRAM device 3740 may perform a remap operation after power is applied to the device. The remap operation may be performed at various times during operation including during boot time, at periodic intervals, upon specific commands from controller 3720, after error detection and/or correction, during scrubbing operations, etc. The remap operation may be initiated by the DRAM device 3740 itself or by controller 3720. After remap operation is complete, the rows in each bank of DRAM device 3740 may be remapped and assigned to a plurality of regions. Strictly as an example, assume that rows are to be assigned to either REGION 0 or REGION 1. After remap operation is complete, the rows in banks 3745-3748 may be remapped based on their respective region numbers. In some instances, the number of rows assigned to REGION 0 in bank 3745 may be different from the number of rows assigned to REGION 0 in banks 3746-3748. Similarly, the number of rows assigned to REGION 1 in each of the banks 3745-3748 may be different. It may be advantageous to equalize the sizes of REGION 0 and REGION 1 across all the banks of DRAM device 3740. Of course, memory system 3700 may be operated with differing sizes of REGION 0 and REGION 1 in each of the banks 3745-3748. After remapping, and, optionally, equalizing the region sizes, memory system 3700 may operate with region-specific parameters or conditions.

FIG. 38 shows flow chart 3800 for equalizing the sizes of the regions in banks 3745-3748 in DRAM device 3740 before normal operation. As an option, any of the features of the present figure (and/or the description thereof) may be implemented in the context of the architecture and environment of any of the previous Figure(s) and/or any of the subsequent Figure(s).

After power is applied to DRAM device, it may be configured in step 3802. Configuration may include setting device operating parameters like access latency, I/O circuit drive strength, etc. Then, the DRAM device may perform remap operation on all the banks in step 3804. The remap operation may be performed sequentially for each bank, or a first number of banks may be remapped in parallel, then a second number of banks may be remapped in parallel, and so on, or all banks may be remapped in parallel. Then, information about the remap operation may be included in the communication between the DRAM device and the controller in step 3806. For example, the controller may query the DRAM device about the size of each region in each of the banks and the DRAM device may reply with this information. Alternately, the DRAM device may send the region size information to the controller at the end of the remap operation. Finally, in step 3808, the sizes of the regions in all the banks of the device may be equalized. The equalization may be done by the DRAM device itself or the controller may select the size of each region and communicate this to the DRAM device. Once the region sizes are equalized in all the banks, the controller and/or the DRAM device may operate with region-specific parameters or conditions during normal operation in step 3810. For example, if the rows were assigned to regions based on access latency, the controller and/or DRAM device may operate with a first latency for access to rows in a first region and operate with a second latency for accesses to rows in a second region. In a further example, if retention time was the aspect used to assign rows to regions, then the controller and/or DRAM device may operate with first refresh timings for rows in a first region and with second refresh timings for rows in a second region.

FIG. 39 shows an example 3900 of remapping and equalizing the size of the regions across all the banks of a DRAM device in the embodiment illustrated in FIG. 37 and FIG. 38. As an option, any of the features of the present figure (and/or the description thereof) may be implemented in the context of the architecture and environment of any of the previous Figure(s) and/or any of the subsequent Figure(s).

DRAM device 3910 may include four banks 3910A-3910D. Each bank is shown with 8 rows. For example, bank 3910A may include rows 3910A-1 through 3910A-8. Note that 8 rows are shown per bank for the sake of clarity. DRAM devices may have large number of rows per bank, typically in the several thousands. As shown, before remapping, bank 3910A may have seven REGION 0 rows and one REGION 1 row. Similarly, bank 3910B may have four REGION 0 rows and four REGION 1 rows. Bank 3910C may have six rows REGION 0 rows and two REGION 1 rows, and bank 3910D may have three REGION 0 rows and five rows REGION 1 rows. In this example, bank 3910D is shown to have the fewest number REGION 0 rows. The same DRAM device after remapping is labeled 3930 in this figure. All the REGION 0 rows in each of the banks 3930A-3930D may be remapped into a region with consecutive row addresses, then all REGION 1 rows in banks 3930A-3930D may be remapped into a region with addresses consecutive to those of the REGION 0 rows. In the event of REGION 0 having more desirable aspect(s) (e.g. REGION 0 has smaller access latency than REGION 1, REGION 0 has longer retention time than REGION 1, etc.), rows assigned to REGION 0 may be operable as REGION 1 rows without deleterious effects on memory system 3700, whereas operating REGION 1 rows as REGION 0 rows may have deleterious effects. Since bank 3910D is shown to have only three rows that are operable as REGION 0 rows whereas all other banks are shown to have more than three REGION 0 rows, the equalization operation may result in all banks 3910A-3910D having three REGION 0 rows. This is shown in DRAM device 3960. All banks 3960A-3960D may have three REGION 0 rows and five REGION 1 rows.

FIG. 40 illustrates memory system 4000, that includes controller 4010, memory module 4020, and a plurality of DRAM devices 4020A-4020N. As an option, any of the features of the present figure (and/or the description thereof) may be implemented in the context of the architecture and environment of any of the previous Figure(s) and/or any of the subsequent Figure(s).

Each of the memory devices is shown to include four banks and I/O circuit block as an example. Of course, the memory devices may include any number of banks. For example, DRAM device 4020N includes four banks 4045N-4048N and I/O circuit block 4042N. Controller 4010 may be a memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, or any device that is capable of being in communication with a DRAM device. Examples of memory module 4020 include single inline memory module (SIMM), dual inline memory module (DIMM), etc. Although FIG. 40 shows memory module 4020 as a separate printed circuit board (PCB), it must be understood that DRAM devices 4020A-4020N may be mounted on the same PCB as controller 4010, or may be mounted on the same substrate as controller 4010. Controller 4010 and DRAM devices 4020A-4020N may also be implemented as a system-in-package (SiP), dies stacked on wafers, dies stacked on dies, wafers stacked on wafers, organized as a 2.5D stack, organized as a 3D stack, etc. Control signals 4070 and address signals 4073 may mostly flow from the controller 4010 to memory module 4020 while data signals 4076 may flow bi-directionally between the memory module and controller.

FIG. 41 shows the flow chart 4100 of the remap operation of memory system 4000. As an option, any of the features of the present figure (and/or the description thereof) may be implemented in the context of the architecture and environment of any of the previous Figure(s) and/or any of the subsequent Figure(s).

After power is applied to the DRAM devices, they may be configured with the appropriate device operating parameters in step 4102. Then, a remap operation may be performed on all banks of all memory devices 4020A-4020N in step 4104. The remap operation may be initiated by the DRAM devices themselves or by a command received from controller 4010. The remap operation may be done on all banks of a memory device, and in all memory devices in any sequence. For example, remap operation may be done in memory device 4020A, then in memory device 4020B, then in memory device 4020C, and so on. In another example, remap operation may be done in all memory devices 4020A-4020N at the same time. Within each memory device, remap operation may be done one bank at a time, multiple banks at a time, or on all banks at the same time. Next, communication between controller and DRAM devices may include information about the remap operation in step 4106. Examples of information may be region sizes in each bank in each DRAM, the minimum region sizes in each DRAM, etc. For example, in a 2-region remapping, each of the DRAM devices 4020A-4020N may communicate the sizes of REGION 0 and REGION 1 in each bank to the controller. Alternately, each of the DRAM devices may communicate the sizes of REGION 0 in each bank of the device and the controller may use this information to calculate the sizes of REGION 1 in each bank of each device. In another example, each of the DRAM devices 4020A-4020N may communicate the minimum size of REGION 0 across all its banks to the controller. Based on the information exchange, the sizes of REGION 0 and REGION 1 across all the banks and all the DRAM devices may be equalized in step 4108. The equalization may be done by the DRAM devices themselves or the controller may select the size of each region and communicate this to the DRAM devices. The region sizes may be equalized on a per-bank basis across all the DRAM devices. For example, banks 4045A-4045N may have equal region sizes, banks 4046A-4046N may have equal region sizes, but the sizes of the regions in banks 4045A-4045N may be different from the sizes of the regions in banks 4046A-4046N. The region sizes may also be equalized across all the banks in all the DRAM devices. After equalization, the controller and/or the DRAM devices may operate with region-specific parameters or conditions during normal operation in step 4110. For example, if the rows were assigned to regions based on access latency, the controller and/or DRAM devices may operate with a first latency for access to rows in a first region and operate with a second latency for accesses to rows in a second region. In a further example, if retention time was the aspect used to assign rows to regions, then the controller and/or DRAM devices may operate with first refresh timings for rows in a first region and with second refresh timings for rows in a second region. Of course, the equalization of the region sizes in all the banks of each of the DRAM devices 4020A-4020N, and/or across all the DRAM devices 4020A-4020N is optional. The memory system 4000 may operate with different region sizes within a DRAM device or between the DRAM devices 4020A-4020N.

In another embodiment, the assigning of rows to regions (e.g. with the use of region numbers) and remapping of rows to a plurality of regions may be done before DRAM devices are used in memory systems (e.g. at the factory, before DRAM devices are mounted on a PCB, etc.). For example, the remap logic of FIG. 31 may be used in this embodiment, and the remapped address of each row may be stored in non-volatile manner in register 3166A of the corresponding row address block 3160A. Note that UPDATE_MAP signal 3197 may not be needed in this case, and REMAP_ON signal 3198 may be set permanently to active high (i.e. 1b) after the remapping operation. Of course, other design choices may be used to do the remapping in the factory, for example, in this embodiment. The sizes of the regions in DRAM device(s) may be stored in the DRAM device(s) or in an external device. In this embodiment, the region-size equalization process may not include remap operation(s). For example, in this embodiment, flow chart 4100 may not include step 4104.

In another embodiment, the DRAM device(s) in a memory system may be selected (from a large number of devices) such that the sizes of the regions in the banks of the selected DRAM device(s) may be within a narrow range of values. Strictly as an example, DRAM devices 4020A-4020N of FIG. 40 may be selected such that the size of REGION 0 in a first bank of each of the DRAM devices 4020A-4020N is an integer number between x−4 and x+4, where x is an integer; the size of REGION 0 in a second bank of each of the DRAM devices is an integer number between y−4 and y+4, where y is an integer; the size of REGION 0 in a third bank of each of the DRAM devices is an integer between z−4 and z+4, where z is an integer; and so on. This may provide the optional benefit of minimizing the number of rows with more desirable one or more aspects being operated with less desirable one or more aspects. Again, as an example, the selection process described above may minimize the number of rows that have longer retention time (e.g. remapped to a first region capable of meeting a first retention time) from being refreshed more often than necessary (e.g. by being assigned to a second region during the process to equalize the sizes of the first and second regions in the DRAM devices, where the second region is capable of meeting a second retention time, and the first retention time is larger than the second retention time).

FIG. 42 illustrates another embodiment. In this embodiment, a row in a memory array in a DRAM device may be disabled and a spare row may be configured or mapped to replace the disabled row. As an option, any of the features of the present figure (and/or the description thereof) may be implemented in the context of the architecture and environment of any of the previous Figure(s) and/or any of the subsequent Figure(s).

The disabling and replacement may be done at boot time, during DRAM configuration time, during run time, after error detection, after error detection and correction, after testing of the array, after scrubbing, after periodic operation, or at any time during the lifetime of the DRAM device. Strictly as an example, a memory array with four rows (associated with WL[0] through WL[3]) and two spare rows (associated with WL[S0] and WL[S1]) is illustrated in FIG. 42. Remap logic 4200 includes address decoder 4210, address multiplexer 4220, register 4230, counter 4235, control logic 4240, address decoder 4250, row remap blocks 4265A-4265B, row disable blocks 4270A-4270D, word line drivers for WL[3:0] 4280A-4280D, and word line drivers for WL[S0:S1] 4285A-4285B. Row remap block 4265A is shown expanded at the top left of FIG. 42, and row disable block 4270A is shown expanded at the top right of FIG. 42.

In normal operation, RA[1:0] may be selected as RRA[1:0] by multiplexer 4220 as REMAP signal 4294 may be driven low by control logic 4240. However, when a row in the memory array is to be disabled and replaced with a spare row, REMAP_ROW signal 4296 may be driven high while the address of the row to be disabled (and replaced) may be driven onto REMAP_RA[1:0] bus 4297 and latched into register 4230. Register 4230 outputs the latched address on MAP_ROW[1:0] bus 4298. Control logic 4240 may initiate a disable-and-replace operation when REMAP_ROW signal is high by driving REMAP signal 4294 high, which may cause multiplexer 4220 to select MAP_ROW[1:0] as RRA[1:0]. Address decoder 4210 may drive the corresponding output (one of Y0-Y3) high. Control logic 4240 may then pulse UPDATE_MAP signal 4293 high, which may latch a logic high in one of flip flops 4275A-4275D, thus disabling the row pointed to by register 4230. At the same time, RRA[1:0] may be loaded into register 4268A, thus remapping a spare row (say, spare row 0, associated with WL[S0]) to the row disabled in this operation. Control logic 4240 may then increment counter 4235, so that the next spare row (say, spare row 1, associated with WL[S1]) may be used for the next disable-and-replace operation. Finally, control logic 4240 may drive REMAP signal low to resume normal operation.

In one embodiment, the disabling of a row and the replacement by a spare row may be enabled after the equalization of region sizes within a DRAM device and/or across a plurality of DRAM devices. In this embodiment, one of the plurality of regions in one or more DRAM devices may be made non-accessible to an external device (e.g. controller), and rows with weak or non-functional bit cells may be remapped to this region. However, equalization of region sizes may result in one or more fully functional rows being assigned to this non-accessible region. In such cases, the fully functional rows remapped to the non-accessible region may be treated as spare rows, and used to replace rows in other regions, when the rows in the other regions are the targets of disable operations.

It should be noted that each of the embodiments described previously may incorporate elements, architectural features, circuits, logic blocks, signals, or any implementation details from other embodiments. For example, any of the embodiments of FIG. 24, FIG. 26, and FIG. 28 may be implemented such that remap logic in these embodiments has an enumeration pass or cycle to determine the number of rows assigned to each of the regions, followed by a remap pass or cycle through all the rows in the memory array. In another example, any of the embodiments of FIG. 24, FIG. 26, and FIG. 28 may use the row address blocks of the embodiment of FIG. 31 (e.g. blocks 3170A-3170D) instead of a lookup table (e.g. lookup table 2420, lookup table 2620, etc.) to store the remapped addresses of the rows in the memory array. In yet another example, any of the embodiments of FIG. 24, FIG. 26, FIG. 28, FIG. 31, and FIG. 33 may be implemented without row region blocks (e.g. 2460A-2460P, 3360A-3360D, etc.) and instead assign region numbers to each row and remap it based on the result of testing each row on one or more aspects of the memory device as implemented in the embodiment of FIG. 34.

FIG. 43 shows a simplified but representative diagram of a bank 4300 of a current art DRAM device. As an option, any of the features of the present figure (and/or the description thereof) may be implemented in the context of the architecture and environment of any of the previous Figure(s) and/or any of the subsequent Figure(s).

Bank 4300 includes an array 4310 of bit cells, row address decoder 4320, and column control circuit 4330. Column control circuit 4330 includes a plurality of sense amplifiers and column address decoders 4332, and a multiplexer-demultiplexer (mux-demux) circuit 4334. Furthermore, array 4310 includes a plurality of memory array tiles (MATs), one of which is labeled 4360. A MAT is a sub-array of bit cells, and may include local sense amplifiers, and optionally, local word line drivers. A plurality of MATs may be arranged in a rectangular fashion and connected to form a DRAM bank. The MAT 4360 illustrated in FIG. 43 includes a sub-array with 256 rows and 256 columns of bit cells. The 256×256 organization of MAT 4360 is strictly for example purposes. The number of rows and columns of bit cells in a MAT is a design decision of a DRAM manufacturer.

It can be seen from FIG. 43 that activating a row (by energizing or driving a word line high) may cause the charge in each of the 8k bit cells in the selected row to be placed on the corresponding bit line. This charge may then be sensed and stored by the associated sense amplifier. In other words, the sense amplifiers may store the contents of the 8k bit cells in the selected row at the end of the row activation operation. A subsequent column operation may be done to access a smaller portion of the data stored in the sense amplifiers by means of a column address.

FIG. 43 shows column circuit sense amplifier and data latch circuit 4332 connecting to 256 bit lines (on the array side) and 4 data lines (on the I/O side). The column circuit 4332 may include at least one of the following circuits: a sense amplifier, a data latch, and a decoder, and other circuits. Column control circuit 4330 is shown to receive a 7-bit column address CA[7:0]. As bank 4300 is shown to have 8k bit cells per row, a 7-bit column address may indicate that each column address may select a smaller (i.e. <8k bits) data set from column circuits 4332. Of the 7 column address bits, 1 address bit (e.g. CA[6], the most significant column address bit) may be used to select 16 of the 32 column circuits 4332, and the remaining 6 address bits (e.g. CA[5:0]) may be used to select a 4-bit nibble (out of the 64 nibbles in each circuit 4332) from each of the 16 selected column circuits 4332. Thus, for each column access (by means of a column address), 64 bits of data may be selected and made available to the mux-demux circuit 4334. In the case of a read operation, the mux-demux circuit 4334 may act to receive 64 bits of data from column circuits 4332 and transmit the data 8 bits at a time on the data I/O lines (i.e. on DQ[7:0]). Similarly, in the case of a write operation, the mux-demux circuit 4334 may act to receive 8 bits of data at a time from the data I/O lines (i.e. from DQ[7:0]) and then transmit 64 bits of data to the column circuits 4332. By designing the I/O lines to operate at 8 times the speed of a column operation, DRAM designers may ensure that DRAM devices are capable of streaming data to or from an external device without any “dead” time. This technique is commonly referred to as prefetching. To illustrate this technique better, assume that a column access takes 16 ns. That is, from the time a column address is valid at the input of column control circuit 4330, 16 ns is needed to read 64 bits of data from column circuits 4332 or write 64 bits of data to column circuits 4332. By designing the I/O lines (i.e. DQ[7:0]) to transmit or receive 8 bits of data at 2 ns intervals, the DRAM device may be capable of reading or writing an entire row of data without any idle or dead time. Prefetching may be used to provide high I/O bandwidth whilst allowing DRAM cores to operate at lower speeds. The number of bits fetched from or sent to the column circuits for each column operation (read or write respectively) may typically be referred to as the prefetch size. Bank 4300 illustrated in FIG. 43 is shown with a prefetch of 8. That is, each column address corresponds to [8*number of DQ pins] bits of data, or 64 bits (i.e. 8 bytes) in this case as bank 4300 is shown to have 8 DQ pins. The external column address is typically in terms of the prefetch size. That is, the external column address may correspond to a group of bits equal to the prefetch size (i.e. a prefetch block). Hence, the prefetch block may be said to be 64 bits in size for bank 4300, and each column address may be said to correspond to a prefetch block.

FIG. 44 shows a simplified view of a bank 4400 of a DRAM device. As an option, any of the features of the present figure (and/or the description thereof) may be implemented in the context of the architecture and environment of any of the previous Figure(s) and/or any of the subsequent Figure(s).

Bank 4400 includes an array of bit cells 4410, row address decoder 4420, and column control circuit 4430. The column control circuit 4430 includes column circuit 4432 and mux/demux circuit 4434. Array 4410 includes a plurality of MATs, one of which is labeled 4460. Note that MAT 4460 is shown to include just one row of bit cells with 4 columns. That is, each MAT corresponds to a nibble of data. This simplification is used to better illustrate various embodiments. Array 4410 is shown with 64 word lines and 128 sense amplifiers, with a MAT at each intersection of a word line and a group of 4 bit lines. Row address RA[5:0] may be used to select one of the 64 rows. Column address CA[2:0] may be used to select 16 bits of data (i.e. 4 nibbles) from the 128 bit lines (i.e. from 32 nibbles). Bank 4400 is shown to have 4 I/O lines, and thus may be considered to implement a prefetch of 4. That is, each prefetch block may correspond to 16 bits (or 4 nibbles) with respect to bank 4400. The bank organization shown in FIG. 44 will be used to illustrate and explain several of the below embodiments.

FIG. 45 shows an expanded view of column control circuit 4430 of FIG. 44. As an option, any of the features of the present figure (and/or the description thereof) may be implemented in the context of the architecture and environment of any of the previous Figure(s) and/or any of the subsequent Figure(s).

Column control circuit 4500 includes 8 column circuits 4510-4517, and column address decoder 4530. Each of the 8 column circuits may connect to 16 bit lines. Decoder 4530 may select one of the 8 column circuits 4510-4517 based on the input column address CA[2:0]. The selected column circuit may then be electrically connected to 16 data lines DQ[15:0], which may connect to the mux/demux circuit 4434 of FIG. 44. Again, for the purpose of simplicity, the mux/demux circuit is not shown in FIG. 45. In the DRAM bank illustrated in FIG. 44 and FIG. 45, a weak or bad bit may cause bit errors, if no error detection and/or correction technique is used, either within the DRAM device or across multiple DRAM devices operating in parallel. The mapping of the column address CA[2:0] to the 32 nibbles in the DRAM bank illustrated in FIG. 44 and FIG. 45 is shown in FIG. 46. Note that the nibble addresses (in decimal) are given in the heading row at the top. As an option, any of the features of the present figure (and/or the description thereof) may be implemented in the context of the architecture and environment of any of the previous Figure(s) and/or any of the subsequent Figure(s).

FIG. 47 illustrates one embodiment of a repair of one or more bad or weak bits in a row of bit cells. As an option, any of the features of the present figure (and/or the description thereof) may be implemented in the context of the architecture and environment of any of the previous Figure(s) and/or any of the subsequent Figure(s).

Bank 4700 of a DRAM device includes an array of bit cells 4710, row address decoder 4720, and column control circuit 4730. Column control circuit includes column circuit 4732, mux/demux circuit 4734, and repair logic circuit 4736. Array 4710 may include 64 word lines, wherein each word line may include 128 bit cells for data storage that may connect to bit lines BL[127:0], 16 bit cells for repair that may connect to bit lines BL[143:128], and 4 bit cells for repair address (i.e. address of prefetch block with weak or bad bits) that may connect to bit lines ABL[3:0]. The location of the weak or bad bit may be stored in 3 of the 4 repair address bits per row, while the remaining bit may be used to indicate if the stored address is valid or not. Since 3 bits are used to store the address of the weak or bad bits in a row, the repair may be done at a prefetch block granularity. In other words, in the event of weak or bad bits within a prefetch block, the entire prefetch block may be marked as weak or bad and may be the repair target. Accordingly, the 16 bit cells (i.e. a prefetch block worth of bit cells) in each row connected to bit lines BL[143:128] may be used for the repair operation.

FIG. 48 shows a more detailed illustration of the column control circuit 4730. As an option, any of the features of the present figure (and/or the description thereof) may be implemented in the context of the architecture and environment of any of the previous Figure(s) and/or any of the subsequent Figure(s).

Column control circuit 4800 includes 9 column circuits 4810-4818, column address decoder 4820, repair logic circuit 4830, address multiplexer 4840, and incrementer circuit 4850. It should be noted that decoder 4820 may select one of the 9 column circuits 4810-4818, where column circuit 4818 may be used for a repair operation. ABL[3:0] may supply the address of a prefetch block containing weak or bad bits (e.g. on ABL[2:0]) as well as a Valid bit (e.g. on ABL[3]) to repair logic circuit 4830 upon the activation of a row. If the Valid bit is set, repair logic circuit 4830 may compare the address of the prefetch block to be repaired with the incoming column address CA[2:0]. If address CA[2:0] is less than the address of the prefetch block to be repaired, repair logic circuit may cause multiplexer 4840 to provide address CA[2:0] as the input to address decoder 4820. However, if the Valid bit is set and address CA[2:0] is equal to or greater than the address of the prefetch block to be repaired, then repair logic circuit 4830 may cause multiplexer 4840 to provide the output of incrementer circuit 4850 as the input to address decoder 4820. The incrementer circuit 4850 may increment the incoming address CA[2:0] by 1. To illustrate the repair operation, say that prefetch block 5 (i.e. corresponding to CA[2:0]=101b) of row 8 contains one or more weak or bad bits. When row 8 is activated, ABL[3]=1b may indicate that the repair address is valid, and ABL[2:0]=101b. Prefetch blocks in row 8 corresponding to addresses (on CA[2:0]) 000b, 001b, 010b, 011b, and 100b (i.e. prefetch blocks 0, 1, 2, 3, and 4) may be accessed normally. However, when an external device may access prefetch blocks corresponding to addresses 101b, 110b, and 111b (i.e. prefetch blocks 5, 6, 7), the repair logic circuit 4830 may map the accesses to prefetch blocks corresponding to addresses 110b, 111b, and 1000b (i.e. prefetch blocks 6, 7, and 8). Thus, prefetch block corresponding to address 101b (i.e. prefetch block 5) may be mapped out and not used as it has weak or bad bits.

An expanded view of repair logic circuit 4830 is shown at the bottom of FIG. 48, where inputs X [2:0] and Y[2:0] may be compared with each other. XOR gate 4831 may compare X2 and Y2. If the two inputs are not the same, then AND gate 4834A may check if X2 is 1b. If X2 is 1b, then Y2 may be 0b, in which case, it may be determined that X [2:0]>Y[2:0]. However, if X2 and Y2 are the same, then XOR gate 4832 may compare X1 and Y1. As before, if the two inputs are not the same, then AND gate 4834B may check if X1 is 1b, in which case, X [2:0]>Y[2:0]. However, if X1 and Y1 are the same, then XOR gate 4833 may be used to compare X0 and Y0. As before, if the two inputs are not the same, then AND gate 4834C may check if X0=1b, in which case, X [2:0]>Y[2:0]. As can be seen, the most significant bit in the two operands or addresses are compared first. Only if they are the same, the next significant bit in the two operands are compared. If the outputs of XOR gates 4831, 4832, and 4833 are all 0b, then it may determined, through means of OR gates 4836A and 4836B, that X [2:0]=Y[2:0]. Similarly, by means of OR gates 4835A and 4835B, it may be determined if X [2:0]>Y[2:0]. The determination of X [2:0]>Y[2:0] and X [2:0]=Y[2:0] is conditional on the address of the block with weak or bad bits being Valid (i.e. X3 set to 1b). Of course, if neither X [2:0]>Y[2:0] or X [2:0]=Y[2:0] is true, then it may be determined that X [2:0]<Y[2:0].

An example mapping of column address CA[2:0] to the nibble addresses for the embodiment described above is shown in FIG. 49. Note that the nibble addresses (in decimal) are given in the heading row at the top. As an option, any of the features of the present figure (and/or the description thereof) may be implemented in the context of the architecture and environment of any of the previous Figure(s) and/or any of the subsequent Figure(s).

FIG. 50 shows another embodiment, wherein the repair is done at a sub-prefetch block granularity. As an option, any of the features of the present figure (and/or the description thereof) may be implemented in the context of the architecture and environment of any of the previous Figure(s) and/or any of the subsequent Figure(s).

Bank 5000 of a DRAM device is shown as having a prefetch block of 16 bits (i.e. 4 nibbles), and the repair in this embodiment is at a nibble granularity. In other words, one nibble in one prefetch block in each row may be mapped out as part of the repair operation. Of course, it should be noted that the nibble granularity repair is shown strictly as an example. The embodiment may be modified for a byte (i.e. 8 bits) level or word level (i.e. 16 bits) granularity, or even for a prefetch block (i.e. 32 bits) level granularity.

Bank 5000 includes an array of bit cells 5010, row address decoder 5020, and column control circuit 5030. Column control circuit 5030 includes column circuit 5032, mux/demux circuit 5034, and repair logic circuit 5036. Array 5010 may include 64 word lines, wherein each word line may include 128 bit cells for data storage that may connect to bit lines BL[127:0], 4 bit cells for repair that may connect to bit lines BL[131:128], and 6 bit cells for bad/weak bit address that may connect to bit lines ABL[5:0]. Since the repair is at the nibble level and each row includes 32 nibbles, 5 bits may be needed to store the location of the nibble with weak or bad bits. Additionally, another bit may be required to indicate if the stored address is valid or not. It should be noted that the finer the granularity of the repair, the more the bits needed to store the address of the repair target while the fewer the bits needed for the repair operation.

FIG. 51 illustrates the column control circuit 5030 of FIG. 50 in greater detail. As an option, any of the features of the present figure (and/or the description thereof) may be implemented in the context of the architecture and environment of any of the previous Figure(s) and/or any of the subsequent Figure(s).

Column control circuit 5100 includes 8 column circuits 5110-5117, column address decoder 5120, and repair logic circuit 5130. Each of the column circuits 5110-5117 may connect to 16 data bit lines, and the 4 repair bit lines (i.e. BL[131:128]). Upon activation of a row, ABL[4:0] may supply the address of a nibble containing weak or bad bits to repair logic circuit 1130, while a Valid bit on ABL[5]) may indicate that the nibble address is valid. Repair logic circuit 5130 may compare ABL[4:2] with the incoming column address CA[2:0]. If the addresses are the same and the Valid bit is set, repair logic circuit 5130 may drive an active high REPLACE signal to all the column circuits 5110-5117. Repair logic circuit 5130 may also decode ABL[1:0] and drive the 4 decoder outputs (i.e. Z[3:0]) to column circuits 5110-5117. Column address decoder 5120 may decode the incoming column address CA[2:0] and enable one of the column circuits 5110-5117 to electrically connect to the data lines DQ[15:0]. If the REPLACE signal is high, the enabled column circuit may substitute the repair nibble (connected to BL[131:128]) for the data nibble with weak or bad bits. The nibble to be replaced or repaired may be indicated by the decoded signals Z[3:0].

An example mapping of column address CA[2:0] to the nibble addresses for the embodiment described above is shown in FIG. 52. As an option, any of the features of the present figure (and/or the description thereof) may be implemented in the context of the architecture and environment of any of the previous Figure(s) and/or any of the subsequent Figure(s).

Note that the nibble addresses (in decimal) are given in the heading row at the top. A diamond symbol in the column corresponding to the repair (i.e. spare) nibble of a row indicates that the repair nibble is used to repair a nibble with bad or weak bit(s) in that particular row. The nibble with bad or weak bit(s) is indicated by a gray rectangle on a row.

FIG. 53 illustrates another embodiment, wherein the repair is done at a nibble (i.e. sub-prefetch block) granularity. As an option, any of the features of the present figure (and/or the description thereof) may be implemented in the context of the architecture and environment of any of the previous Figure(s) and/or any of the subsequent Figure(s).

Bank 5300 of a DRAM device is shown as having a prefetch block of 16 bits (i.e. 4 nibbles), and the repair in this embodiment is at a nibble granularity. In other words, one nibble in one prefetch block in each row may be mapped out as part of the repair operation. Of course, it should be noted that the nibble granularity repair is shown strictly as an example. The embodiment may be modified for a byte (i.e. 8 bits) level or word level (i.e. 16 bits) granularity, or even for a prefetch block (i.e. 32 bits) level granularity.

Bank 5300 includes an array of bit cells 5310, row address decoder 5320, and column control circuit 5330. Column control circuit 5330 includes column circuit 5332, mux/demux circuit 5334, and repair logic circuit 5336. Array 5310 may include 64 word lines, wherein each word line may include 128 bit cells for data storage that may connect to bit lines BL[127:0], 4 bit cells for repair that may connect to bit lines BL[131:128], and 6 bit cells for bad/weak bit address that may connect to bit lines ABL[5:0]. Since the repair is at the nibble level and each row includes 32 nibbles, 5 bits may be needed to store the location of the weak or bad bits. Additionally, another bit may be required to indicate if the stored address is valid or not.

FIG. 54 illustrates the column control circuit 5330 of FIG. 53 in greater detail. As an option, any of the features of the present figure (and/or the description thereof) may be implemented in the context of the architecture and environment of any of the previous Figure(s) and/or any of the subsequent Figure(s).

Column control circuit 5400 may include 8 column circuits 5410-5417, column address decoder 5420, and repair logic circuit 5430. Each of the column circuits 5410-5417 may connect to 20 data bit lines, wherein the 4 bit lines connecting to the most significant data lines of a column circuit also connect to the least significant data lines of the next column circuit. For example, BL[19:16) connect to the 4 most significant data lines of column circuit 5410 and connect to the 4 least significant data lines of column circuit 5411. Upon activation of a row, ABL[4:0] may supply the address of a nibble containing weak or bad bits to repair logic circuit 5430, while a Valid bit on ABL[5]) may indicate that the nibble address is valid. Repair logic circuit 5430 may include an address comparison circuit 5432, AND gates 5434 and 5436, and address decoder 5438. The address comparison circuit 5432 may be implemented similar to that shown in FIG. 48 (see circuit 4830). Of course, the address comparison circuit 5432 may be implemented in any other way.

Address comparison circuit 5432 may compare ABL[4:2] with the incoming column address CA[2:0] and output two signals: X=Y (if CA[2:0]=ABL[4:2]) and X>Y (if CA[2:0] >ABL[4:2]). Both the X=Y and the X>Y outputs are gated by the Valid bit on ABL[5]. Output signal X=Y may be connected to the SKIP input of the column circuits 5410-5417, while output signal X>Y may be connected to the ALLSKP input of the column circuits 5410-5417. Column address decoder 5420 may decode the incoming column address CA[2:0] and act to electrically connect one of the column circuits 5410-5417 to the DQ[15:0] signals.

The incoming column address CA[2:0] appended with 00b may indicate the address of the first nibble in a prefetch block. For example, prefetch block with address 001b may include nibble 4 (with address 00100b) through nibble 7 (with address 00111b). The repair address on ABL[5:0] may provide the address of the nibble with weak or bad bits. If CA[2:0] is less than ABL[4:2], then it may be taken that none of the nibbles in the prefetch block corresponding to address CA[2:0] contain weak or bad bits. However, if CA[2:0] matches ABL[4:2], then one of the 4 nibbles in the prefetch block corresponding to address CA[2:0] may contain the weak or bad bits. The exact location of the nibble with the weak or bad bits may be indicated by Z[3:0], output by decoder 5438 based on ABL[1:0].

In the case that CA[2:0] is less than ABL[4:2], neither the SKIP nor the ALLSKP inputs of column circuits 5410-5417 may be active. This may cause the column circuits to electrically connect D[3:0], D[7:4], D[11:8], and D[15:12] to Q[3:0], Q[7:4], Q[11:8], and Q[15:12] respectively.

In the case that CA[2:0] is the same as ABL[4:2], the SKIP input of column circuits 5410-5417 may be active while ALLSKP input may be inactive. If the P0 input of the selected column circuit be active, the column circuit may electrically connect D[7:4], D[11:8], D[15:12], and D[19:16] to Q[3:0], Q[7:4], Q[11:8], and Q[15:12] respectively. If the P1 input of the selected column circuit be active, the column circuit may electrically connect D[3:0], D[11:8], D[15:12], and D[19:16] to Q[3:0], Q[7:4], Q[11:8], and Q[15:12] respectively. If the P2 input of the selected column circuit be active, the column circuit may electrically connect D[3:0], D[7:4], D[15:12], and D[19:16] to Q[3:0], Q[7:4], Q[11:8], and Q[15:12] respectively. And if the P3 input of the selected column circuit be active, the column circuit may electrically connect D[3:0], D[7:4], D[11:8], and D[19:16] to Q[3:0], Q[7:4], Q[11:8], and Q[15:12] respectively.

In the case that CA[2:0] is greater than ABL[4:2], the ALLSKP input of the column circuits 5410-5417 may be active while the SKIP input may be inactive. In this case, the selected column circuit may electrically connect D[7:4], D[11:8], D[15:12], and D[19:16] to Q[3:0], Q[7:4], Q[11:8], and Q[15:12] respectively.

From the above description, it can be understood that in this embodiment, the repair logic circuit 5430 may act to skip the nibble with the weak or bad bits and shift right all the nibbles with address equal to or greater than the address of the nibble to be repaired. For example, say nibble 6 of row 10 contains weak or bad bits. The repair logic circuit maps the 32 nibbles of row 10 that are accessible by an external device to nibbles 0 through 5 and nibbles 7 through 32. That is, nibble 6 is skipped. An example mapping of column address CA[2:0] to the nibble addresses for the embodiment described above is shown in FIG. 55. As an option, any of the features of the present figure (and/or the description thereof) may be implemented in the context of the architecture and environment of any of the previous Figure(s) and/or any of the subsequent Figure(s).

Note that the nibble addresses (in decimal) are given in the heading row at the top. Also note that the same repair map is used in FIG. 55 as was used in FIG. 52 to allow comparison of the repair mechanism of the embodiment shown in FIG. 50 and FIG. 51 with the repair mechanism of the embodiment shown in FIG. 53 and FIG. 54.

FIG. 56 illustrates another embodiment, wherein the repair is done at a nibble (i.e. sub-prefetch block) granularity. As an option, any of the features of the present figure (and/or the description thereof) may be implemented in the context of the architecture and environment of any of the previous Figure(s) and/or any of the subsequent Figure(s).

Bank 5600 of a DRAM device is shown as having a prefetch block of 16 bits (i.e. 4 nibbles), and the repair in this embodiment is at a nibble granularity. In other words, one nibble in one prefetch block in each row may be mapped out as part of the repair operation. Of course, it should be noted that the nibble granularity repair is shown strictly as an example. The embodiment may be modified for a byte (i.e. 8 bits) level or word level (i.e. 16 bits) granularity, or even for a prefetch block (i.e. 32 bits) level granularity.

Bank 5600 includes an array of bit cells 5610, row address decoder 5620, and column control circuit 5630. Column control circuit 5630 includes column circuit 5632, mux/demux circuit 5634, and repair logic circuit 5636. Array 5610 may include 64 word lines, wherein each word line may include 128 bit cells for data storage that may connect to bit lines BL[127:0], 4 bit cells for repair that may connect to bit lines BL[131:128], and 6 bit cells for bad/weak bit address that may connect to bit lines ABL[5:0]. ABL[5] may be used as a Valid bit to indicate if the address in ABL[5:0] is valid or not.

FIG. 57 illustrates the column control circuit 5630 of FIG. 56 in greater detail. As an option, any of the features of the present figure (and/or the description thereof) may be implemented in the context of the architecture and environment of any of the previous Figure(s) and/or any of the subsequent Figure(s).

Column control circuit 5700 includes 4 column address generator circuits, one of which is labeled 5730, 4 column address decoder circuits, one of which is labeled 5720, and 4 data selection circuits, one of which is labeled 5710. Each of the data selection circuits 5710 may include 33 transceivers 5715-0 through 5715-32, wherein each transceiver may connect to a data nibble (e.g. DQ[3:0]). Each transceiver may also have an output enable signal OE, which may select which of the transceiver may drive the DQ[3:0] outputs of the data selection circuit 5710. Column address generator circuit 5730 may include an adder 5732, address multiplexer 5734, and inverter 5736. Column address decoder circuit 5720 may include address decoder 5724 and OR circuit 5728.

If a row has a valid repair address, column address generator circuit 5730 may act to swizzle the column address such that the next most significant nibble from the nibble with weak or bad bits may be mapped to nibble 0 (i.e. the nibble corresponding to address 00000b). For example, if nibble 13 of row 6 has weak or bad bits, column address generator circuit 5730 acts to swizzle row 6 such that the nibble 0 addressable by an external device is mapped to nibble 14, nibble 1 addressable by an external device is mapped to nibble 15, and so on, till nibble 31 addressable by an external device is mapped to nibble 12. In essence, nibble 13 is mapped to nibble 32 and hence, not addressable by an external device since the external device sees only 32 nibbles (i.e. nibble 0 through 31) per row.

Using the example above, say that an external logic device wishes to access the first 4 nibbles of row 6. The external logic device may accordingly communicate column address CA[2:0]=00b to a DRAM device in the embodiment of FIG. 56. Since nibble 13 in this row has weak or bad bits, the column address generator circuit 5730 may swizzle the column addresses such that DQ[3:0] is now mapped to nibble 14. This may be done by adding the address of nibble with the weak or bad bits (i.e. ABL[4:0]), 00001b (which may point to the nibble immediately after the nibble with the weak or bad bits), and CA[2:0] appended with 00b. That is, 01101b (decimal 13) may be added with 00001b (decimal 1) and 00000b (decimal 0) to obtain the swizzled address of the first nibble in this row. In this example, this may be 01110b (decimal 14). Hence, the data bits in nibble 14 may be output on DQ[3:0]. Similarly, the addition of ABL[4:0], 00001b, and CA[2:0] appended with 01b may generate the address of the second nibble in this row. That is, the data bits in nibble 15 may be output on DQ[7:4]. Similarly, the addresses of the third and fourth nibble in this row may be obtained by adding ABL[4:0], 00001b, CA[2:0] appended with 10b, and ABL[4:0], 00001b, CA[2:0] appended with 11b respectively.

Accordingly, upon activation of a row, ABL[4:0] may supply the address of a nibble containing weak or bad bits to repair logic circuit 5730, while a Valid bit on ABL[5]) may indicate that the nibble address is valid. Adder 5732 may add the address on ABL[4:0], the incoming column address CA[2:0] appended with a 2-bit value, and 00001b. The 2-bit value may be 00b, 01b, 10b, and 11b for column address generator circuits 5730 that generate addresses used to select DQ[3:0], DQ[7:4], DQ[11:8], and DQ[15:12] respectively. The result of the addition operation may provide a 6-bit address ACA[5:0] since the highest value of CA[2:0] appended with 11b may be 11111b and the highest value on ABL[4:0] may be 11111b. Depending on the value of ABL[5] (i.e. the Valid bit), multiplexer 5734 may select either the output of adder 5732 or CA[2:0] appended with 000b as the input to address decoder 5720.

Since each row of the DRAM bank 5600 may have 33 nibbles, modulo-33 arithmetic may be used to calculate the addresses of the target nibbles. Instead of using modulo-33 arithmetic to map the external address to the internal nibbles, the embodiment shown in FIG. 56 and FIG. 57 uses a modulo-64 arithmetic to select the appropriate 4 nibbles for each external column address while still swizzling the nibble address of a row. For example, if the external column address is 28 (decimal) and the address on ABL[5:0] is 6 (decimal), the addition of the two addresses will result in an address of 34 (decimal), which should correspond to address 1 (decimal) if modulo-33 arithmetic is used. However, the method used in this embodiment may alias address 34 (decimal) to address 1 (decimal) by using a 6-bit decoder 5724 and appropriately mapping the 64 outputs of the decoders to 33 select signals for data selection 5710. In the aliasing scheme used in this embodiment, outputs Y0 through Y32 of decoder 5724 may enable nibbles 0 through 32 respectively. Additionally, outputs Y33 through Y63 of decoder 5724 may enable nibbles 0 through 30 respectively. The aliasing may be done by OR′ing Y0 and Y33 as the output enable or select signal for nibble 0, OR′ing Y1 and Y34 as the output enable or select signal for nibble 1, and so on.

Column address decoder circuit 5720 may may generate 33 enable signals OE[32:0], based on address ACA[5:0] generated by column address generator circuit 5730. ACA[5:0] may be decoded by decoder 5724, which may drive one of its 64 outputs Y[63:0] high based on the value of ACA[5:0]. The 64 outputs of decoder 5724 may be input to OR circuit 5728, which may generate 33 output enable signals OE[32:0]. As mentioned above, the mapping of the 64 outputs of decoder 5724 to the 33 output enable signals OE[32:0] of OR circuit 5728 is shown in TABLE 1.

The OE[32:0] signals from the column address decoder circuit 5720 may be input to data selection circuit 5710. Data selection circuit 5710 may use these enable signals to select the addressed nibble. As shown, transceiver 5715-0 may select BL[3:0] (i.e. nibble 0) if OE0 is high; transceiver 5715-1 may select BL[7:4] (i.e. nibble 1) if OE1 is high, and so on.

TABLE 1

| | |
|---|---|
| OE SIGNAL | OR INPUTS FOR OE |

| | | |
|---|---|---|
| OE0 | Y0 | Y33 |
| OE1 | Y1 | Y34 |
| OE2 | Y2 | Y35 |
| OE3 | Y3 | Y36 |
| OE4 | Y4 | Y37 |
| OE5 | Y5 | Y38 |
| OE6 | Y6 | Y39 |
| OE7 | Y7 | Y40 |
| OE8 | Y8 | Y41 |
| OE9 | Y9 | Y42 |
| OE10 | Y10 | Y43 |
| OE11 | Y11 | Y44 |
| OE12 | Y12 | Y45 |
| OE13 | Y13 | Y46 |
| OE14 | Y14 | Y47 |
| OE15 | Y15 | Y48 |
| OE16 | Y16 | Y49 |
| OE17 | Y17 | Y50 |
| OE18 | Y18 | Y51 |
| OE19 | Y19 | Y52 |
| OE20 | Y20 | Y53 |
| OE21 | Y21 | Y54 |
| OE22 | Y22 | Y55 |
| OE23 | Y23 | Y56 |
| OE24 | Y24 | Y57 |
| OE25 | Y25 | Y58 |
| OE26 | Y26 | Y59 |
| OE27 | Y27 | Y60 |
| OE28 | Y28 | Y61 |
| OE29 | Y29 | Y62 |
| OE30 | Y30 | Y63 |
| OE31 | Y31 | |
| OE32 | Y29 | |

Of course, it should be noted that the modulo-64 arithmetic described above is a design choice. Other methods may be used to generate the output enable signals OE[32:0] for the data selection circuits 5710.

An example mapping of column address CA[2:0] to the nibble addresses for the embodiment described above is shown in FIG. 58. As an option, any of the features of the present figure (and/or the description thereof) may be implemented in the context of the architecture and environment of any of the previous Figure(s) and/or any of the subsequent Figure(s).

Note that the nibble addresses (in decimal) are given in the heading row at the top. Also note that the same repair map is used in FIG. 58 as was used in FIG. 52 and FIG. 55 to allow comparison of the repair mechanism of the embodiments shown in FIGS. 50 and 51 and in FIGS. 53 and 55 with the repair mechanism of the embodiment shown in FIGS. 56 and 57.

The descriptions of the various embodiments above may mostly be in the context of a read operation. However, the repair operation may work in a similar manner in the case of write operations as the column circuits may be capable of bi-directional operation. Additionally, transceivers, mux/demux circuits, and other circuits in the data path may all be capable of bi-directional operation.

In the various embodiments described above, the address of the prefetch block or sub-prefetch block with weak or bad bits may be stored in the DRAM device itself in a non-volatile storage (e.g. fuses, EPROM bit cells, EEPROM bit cells, etc.). In one embodiment, after power up and as part of the initialization and calibration process, the DRAM device may read the stored addresses from the non-volatile storage, and write the addresses to the bit cells in each row designed to store the repair address. That is, the DRAM device may read the stored address for row 0 and write it to the bit cells in row 0 designed to store the repair address, then read the stored address for row 1 and write it to the bit cells in row 1 designed to store the repair address, and so on. Additionally, the Valid bit for each row may also be read from non-volatile storage and written to the bit cell designed to store the Valid bit.

FIG. 59 shows a flow chart of the initialization process of this embodiment. As an option, any of the features of the present figure (and/or the description thereof) may be implemented in the context of the architecture and environment of any of the previous Figure(s) and/or any of the subsequent Figure(s).

In another embodiment, the bit cells designed to store the Valid bit and the repair address may themselves be non-volatile bit cells (e.g. fuses, EPROM bit cells, EEPROM bit cells, etc.) such that a row activation may cause these non-volatile bit cells to place the stored value on the associated bit lines. For example, the bit cells connecting to bit lines ABL[5:0] in the DRAM bank 5600 of FIG. 56 may be non-volatile bit cells.

In another embodiment, the Valid bits and the repair addresses for the rows may be stored external to the DRAM device (e.g. in a register, in a serial presence detect or SPD device, on a memory module such as a DIMM, in a boot ROM, in an EPROM device on the motherboard, in an SSD, in a hard disk drive, etc.) and be sent to the DRAM during the power on and initialization process.

FIG. 60 shows a flow chart of the initialization process of this embodiment. As an option, any of the features of the present figure (and/or the description thereof) may be implemented in the context of the architecture and environment of any of the previous Figure(s) and/or any of the subsequent Figure(s).

In yet another embodiment, the DRAM device may perform a scrubbing operation on all the rows and determine if a row has weak or bad bits. As part of the scrubbing operation, the DRAM device may write one or more data patterns to each of the rows, read back the data in the rows, and compare the read data with the written data to identify any weak or bad bit cells in a row. Of course, the scrubbing operation may also include using ECC techniques to identify weak or bad bits in a row. The DRAM device may then write the location of the weak or bad bits in a row to the bit cells in that row designed to store the repair address, and then set the repair address Valid bit for that row. The DRAM device may also clear the repair address Valid bits for rows that do not have weak or bad bits. The scrubbing operation may be done during device initialization after power is applied, or may be done periodically, or may be done at a command from an external device (e.g. memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, or any device that is capable of being in communication with a DRAM device). The scrubbing operation may be done by the DRAM itself or it may be done by the DRAM in communication with an external device.

FIG. 61 shows a flow chart of the repair process of this embodiment. As an option, any of the features of the present figure (and/or the description thereof) may be implemented in the context of the architecture and environment of any of the previous Figure(s) and/or any of the subsequent Figure(s).

Note that the flow chart in FIG. 61 describes a scrubbing operation done by the DRAM device. However, this can be easily modified for a scrubbing operation done by the DRAM device in communication with an external device. In this case, the address of the row to be scrubbed or the data pattern to be used for the scrubbing operation or both may be communicated by the external device to the DRAM device. Furthermore, the DRAM device may read back the data from the row undergoing scrubbing and detect one or more miscompares with the written data and update, if necessary, the repair information for that row. Alternately, the external device may read back the contents of the row undergoing scrubbing, identify miscompares with the written data, and communicate repair information to the DRAM device.

FIG. 62 shows memory system 6200, which includes controller 6220 and DRAM device 6240. As an option, any of the features of the present figure (and/or the description thereof) may be implemented in the context of the architecture and environment of any of the previous Figure(s) and/or any of the subsequent Figure(s).

Controller 6220 may be a memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, or any device that is capable of being in communication with a DRAM device. Control signals 6270 and address 6273 may mostly flow from the controller 6220 to the DRAM device 6240 while data signals 6276 may flow bi-directionally between the DRAM device and controller. Controller 6220 may identify weak or bad bits in one or more rows of the DRAM device 6240 and communicate the valid repair address(es) to the DRAM device. The identification of weak or bad bits may be performed at various times during operation including during boot time, at periodic intervals, after error detection and/or correction, during scrubbing operations, etc.

FIG. 63 illustrates memory system 6300, that includes controller 6310, memory module 6320, and a plurality of DRAM devices 6320A-6320N. As an option, any of the features of the present figure (and/or the description thereof) may be implemented in the context of the architecture and environment of any of the previous Figure(s) and/or any of the subsequent Figure(s).

Controller 6310 may be a memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, or any device that is capable of being in communication with a DRAM device. Examples of memory module 6320 include single inline memory module (SIMM), dual inline memory module (DIMM), etc. Although FIG. 63 shows memory module 6320 as a separate printed circuit board (PCB), it must be understood that DRAM devices 6320A-6320N may be mounted on the same PCB as controller 6310, or may be mounted on the same substrate as controller 6310. Controller 6310 and DRAM devices 6320A-6320N may also be implemented as a system-in-package (SiP), dies stacked on wafers, dies stacked on dies, wafers stacked on wafers, organized as a 2.5D stack, organized as a 3D stack, etc. Control signals 6370 and address signals 6373 may mostly flow from the controller 6310 to memory module 6320 while data signals 6376 may flow bi-directionally between the memory module and controller. Controller 6320 may identify weak or bad bits in one or more rows of DRAM devices 6320A-6320N and communicate the valid repair address(es) to the DRAM devices. The identification of weak or bad bits may be performed at various times during operation including during boot time, at periodic intervals, after error detection and/or correction, during scrubbing operations, etc.

FIG. 64 shows a flow chart of the repair process described above in the context of memory systems 6200 and 6300. As an option, any of the features of the present figure (and/or the description thereof) may be implemented in the context of the architecture and environment of any of the previous Figure(s) and/or any of the subsequent Figure(s).

In another embodiment, the rows with no weak or bad bits may be remapped to a first region while rows with valid repair addresses (i.e. rows with weak or bad bits) may be remapped to a second region. Then, each of the regions may be operated with region specific parameters or conditions. For example, the region containing rows with no weak or bad bits may be operated with a first latency while the region containing rows with valid repair addresses (i.e. rows with weak or bad bits) may be operated with s second latency.

It should be noted that all the embodiments illustrated in this application describe repair of one prefetch block or sub-prefetch block per row. However, all the embodiments may be easily extended to repair multiple prefetch blocks or multiple sub-prefetch blocks per row.

It should also be noted that all the embodiments illustrated so far in this application describe repair of rows of a memory array on a per-row basis. That is, the granularity of the repair operation is one row. However, the embodiments may be easily modified for repairing a plurality (or set) of rows as the unit for repair.

Each of the embodiments described previously may incorporate elements, architectural features, circuits, logic blocks, signals, or any implementation details from other embodiments. Furthermore, one or more of the embodiments may be combined and implemented. For example, a DRAM device may be designed to include the repair method described in the embodiment shown in FIG. 50 and FIG. 51 (i.e. replace the sub-prefetch block with weak or bad bits with spare bit cells, which may be called the Replace method), and the repair method described in the embodiment shown in FIG. 53 and FIG. 54 (i.e. skip the sub-prefetch block with weak or bad bits, which may be called the Skip method). Repair information (addresses, Valid bits) may be stored in non-volatile storage before DRAM devices are used in memory systems (e.g. at the factory, before DRAM devices are mounted on a PCB, etc.). After power is applied to the DRAM device, the repair information stored in non-volatile storage may be transferred to the repair bit cells of the rows and the Replace repair method may be used to repair prefetch blocks or sub-prefetch blocks with weak or bad bits. Next, any additional weak or bad bits in one or more rows may be identified during operation (e.g. run time, after scrubbing operations, etc.) and the repair information (i.e. repair addresses and Valid bits) may be written to a second set of repair bit cells of the rows. Then, the Skip repair method may be used to repair a second prefetch block or sub-prefetch block in each row of the DRAM device.

FIG. 65 shows a simplified view of a portion of a bank of a DRAM device. As an option, any of the features of the present figure (and/or the description thereof) may be implemented in the context of the architecture and environment of any of the previous Figure(s) and/or any of the subsequent Figure(s).

The portion 6500 includes an array 6510 of bit cells arranged in a matrix of 6 rows and 6 columns (i.e. a 6×6 array), row address decoder 6570, word line drivers 6550, column decoder 6580, sense amplifiers 6560, and column selection logic 6590. Array 6510 includes a plurality of word lines 6530, a plurality of bit lines 6540, and a plurality of bit cells 6520. Each of the bit cells 6520 includes an access transistor 6523, and a capacitor 6526 that stores a charge representing either a logic 1 or a logic 0. As mentioned previously and also widely reported, frequent accesses to a row (e.g. row 2, that is, the row controlled by word line WL2) may disturb the charge stored in the bit cells of row 1 (i.e. controlled by word lines WL1) and row 3 (i.e. row controlled by word line WL3), and may even disturb the charge stored in the bit cells of row 0 and row 4 (i.e. rows controlled by word lines WL0 and WL4 respectively). Although refreshing row 1 and row 3 may restore the charge stored in the bit cells of row 1 and row 3 and thus ameliorate the disturbance caused by repeated accesses to row 2, multiple refreshes to row 1 and row 3 may disturb the charge stored in the bit cells of row 0 and row 4.

FIG. 66 shows a simplified view of a bank of a DRAM device in one embodiment. As an option, any of the features of the present figure (and/or the description thereof) may be implemented in the context of the architecture and environment of any of the previous Figure(s) and/or any of the subsequent Figure(s).

In the embodiment of FIG. 66 and the succeeding embodiments, an external logic device may be a memory controller, a microprocessor, a central processing unit (CPU), an application processor, a graphics processor unit (GPU), an artificial intelligence processor (AI processor), a machine learning processor (ML processor), a tensor processing unit (TPU), an accelerated processing unit (APU), a network processing unit (NPU), an application specific integrated circuit (ASIC), a System-on-Chip (SoC), a field programmable gate array (FPGA), a CXL endpoint, a HBM logic die, a HMC logic die, a register, a buffer, a logic die or layer, or any device that is capable of being in communication with a DRAM device. The controller may be packaged with one or more memory (e.g. DRAM) devices or may be packaged separately.

DRAM bank 6600 includes memory array 6610, row address logic 6620, column address decoder 6630, column selection logic 6640, word line drivers 6650, and sense amplifiers 6660. The number of rows and the number of columns of bit cells in bank 6600 are deliberately chosen to be small to better illustrate this embodiment. It should be noted that this embodiment may be designed for any number of rows and columns. Row address logic 6620 includes row address decoder 6624, and row remap logic 6628. Memory array 6610 includes two regions 6612 (MAIN REGION) and 6614 (REMAP REGION), each of which includes a plurality of word lines 6616, a plurality of bit lines 6618, and a plurality of bit cells 6670. Strictly as an example, region 6612 is shown to include 16 rows and 16 columns of bit cells, while region 6614 is shown to include 4 rows and 16 columns of bit cells. Of course, region 6612 and region 6614 may include any number of rows and columns. Bank 6600 may present itself to the rest of the memory system as a 16×16 array of bit cells (i.e. an array with bit cells organized as 16 rows and 16 columns).

In operation, row address remap logic 6628 may keep track of the last n row activate commands from an external logic device (e.g. logic die or layer, register, buffer, controller, processor, etc.), and remap a row from region 6612 to region 6614 if that row is (or was) the target of m activates of the last n activates, where m and n are integer numbers, and m≤n. Since frequently accessed rows may be remapped from region 6612 to region 6614 in this embodiment, region 6612 may contain the less frequently accessed rows. It should be noted that in any mapping of rows across the two regions 6612 and 6614, only 16 rows in bank 6600 may be accessible by an external logic device in the memory system, even though bank 6600 may have 20 rows of bit cells. For example, after power is applied to the memory system and the DRAM devices initialized, all the 16 rows in region 6612 may be accessible by an external logic device while none of the rows in region 6614 may be accessible by the external logic device. During operation, one of the rows (say, row 7) may be much more frequently accessed by the external logic device. The row remap logic 6628 may then act to remap row 7 from region 6612 to row 16 in region 6614. Now, 15 rows in region 6612 (i.e. rows 0-6 and 8-15) and 1 row (i.e. row 16) in region 6614 may now be accessible by the external logic device. Hence, it can be seen that both before the remap operation and after the remap operation, only 16 rows in bank 6600 may be accessible by the external logic device.

Region 6612 and region 6614 may have the same electrical or logical design/configuration/connection (e.g. netlist, schematics, BOM, etc.), and the same physical design (e.g. word line pitch, bit line pitch, layout, fabrication steps, etc.) in this embodiment. Since region 6614 may contain only the most frequently accessed rows, and since each row activate operation may also result in restoring the charge stored in the bit cells of that row, the remapped rows in region 6614 may effectively be refreshed more frequently than the rows in region 6612. Thus, the data or charge disturbance caused by frequent accesses may be minimized in this embodiment.

FIG. 67 illustrates a simplified view of a bank of a DRAM device in another embodiment. As an option, any of the features of the present figure (and/or the description thereof) may be implemented in the context of the architecture and environment of any of the previous Figure(s) and/or any of the subsequent Figure(s).

DRAM bank 6700 includes memory array 6710, row address logic 6720, column address decoder 6730, column selection logic 6740, word line drivers 6750, and sense amplifiers 6760. The number of rows and the number of columns of bit cells in bank 6700 are deliberately chosen to be small to better illustrate this embodiment. It should be noted that this embodiment may be designed for any number of rows and columns. Row address logic 6720 includes row address decoder 6724, and row remap logic 6728. Memory array 6710 includes two regions 6712 (MAIN REGION) and 6714 (REMAP REGION), each of which includes a plurality of word lines 6716, a plurality of bit lines 6718, and a plurality of bit cells 6770. Strictly as an example, region 6712 is shown to include 16 rows and 16 columns of bit cells, while region 6714 is shown to include 4 rows and 16 columns of bit cells. Of course, region 6712 and region 6714 may include any number of rows and columns. Bank 6700 may present itself to the rest of the memory system as a 16×16 array of bit cells (i.e. an array with bit cells organized as 16 rows and 16 columns).

In operation, row address remap logic 6728 may keep track of the last n row activate commands from an external logic device (e.g. logic die or layer, register, buffer, controller, processor, etc.), and remap a row from region 6712 to region 6714 if that row is (or was) the target of m activates of the last n activates, where m and n are integer numbers, and m≤n. As in the embodiment of FIG. 66, frequently accessed rows may be remapped from region 6712 to region 6714, and thus region 6712 may contain the less frequently accessed rows. It should be noted that in any mapping of rows across the two regions 6712 and 6714, only 16 rows in bank 6700 may be accessible by an external logic device in the memory system, even though bank 6700 may have 20 rows of bit cells.

While region 6712 and region 6714 may have the same electrical or logical design/configuration/connection (e.g. netlist, schematics, etc.), the physical design (e.g. word line pitch, bit line pitch, layout, fabrication steps, etc.) of region 6712 may be different from that of region 6714 in this embodiment. For example, the word line pitch may be larger in region 6714 than in region 6712. The word line pitch in region 6714 may be chosen so as to minimize the disturbance of the charge stored in the bit cells of neighboring rows when a row in region 6714 is activated repeatedly. For example, the word line pitch may be chosen to minimize disturbance of the charge stored in the bit cells of rows 16 and 18 when row 17 is activated frequently. Thus, the data or charge disturbance caused by frequent accesses may be minimized in this embodiment.

FIG. 68 shows a simplified view of a bank of a DRAM device in yet another embodiment. As an option, any of the features of the present figure (and/or the description thereof) may be implemented in the context of the architecture and environment of any of the previous Figure(s) and/or any of the subsequent Figure(s).

DRAM bank 6800 includes memory array 6810, row address logic 6820, column address decoder 6830, column selection logic 6840, word line drivers 6850, and sense amplifiers 6860. The number of rows and the number of columns of bit cells in bank 6800 are deliberately chosen to be small to better illustrate this embodiment. It should be noted that this embodiment may be designed for any number of rows and columns. Row address logic 6820 includes row address decoder 6824, and row remap logic 6828. Memory array 6810 includes two regions 6812 (MAIN REGION) and 6814 (REMAP REGION), each of which includes a plurality of word lines 6816, a plurality of bit lines 6818, and a plurality of bit cells 6870. Strictly as an example, region 6812 is shown to include 16 rows and 16 columns of bit cells, while region 6814 is shown to include 7 rows and 16 columns of bit cells. Of course, region 6812 and region 6814 may include any number of rows and columns. Bank 6800 may present itself to the rest of the memory system as a 16×16 array of bit cells (i.e. an array with bit cells organized as 16 rows and 16 columns).

In operation, row address remap logic 6828 may keep track of the last n row activate commands from an external logic device (e.g. logic die or layer, register, buffer, controller, processor, etc.), and remap a row from region 6812 to region 6814 if that row is (or was) the target of m activates of the last n activates, where m and n are integer numbers, and m≤n. As in the embodiments of FIG. 66 and FIG. 67, frequently accessed rows may be remapped from region 6812 to region 6814, and thus region 6812 may contain the less frequently accessed rows. It should be noted that in any mapping of rows across the two regions 6812 and 6814, only 16 rows in bank 6800 may be accessible by an external logic device in the memory system, even though bank 6800 may have 23 rows of bit cells.

While region 6812 and region 6814 may have the same electrical or logical design/configuration/connection (e.g. netlist, schematics, etc.), and the same physical design (e.g. word line pitch, bit line pitch, layout, fabrication steps, etc.), only some of the rows in region 6814 may be used in the remap operations. The other rows in region 6814 may be treated as dummy rows and may act as shields for the rows used in the remap operations. This can be seen in FIG. 68, where DWL0 (dummy WL0) may act as a shield between WL16 and WL17, DWL1 may act as a shield between WL17 and WL18, and DWL2 may act as a shield between WL18 and WL19. In some embodiments, the capacitors and/or the transistors of the bit cells of the dummy rows may be different from the capacitors and/or the transistors of the bit cells of the other rows. For example, the physical dimensions of the capacitors of bit cells of the dummy rows may be different from that of the capacitors of bit cells of rows used for charge storage. Of course, in other embodiments, the capacitors and/or transistors of bit cells in all the rows (including the dummy rows) may be the same. Thus, the data or charge disturbance caused by frequent accesses may be minimized in this embodiment.

FIG. 69 illustrates a simplified view of a bank of a DRAM device in another embodiment. As an option, any of the features of the present figure (and/or the description thereof) may be implemented in the context of the architecture and environment of any of the previous Figure(s) and/or any of the subsequent Figure(s).

DRAM bank 6900 includes memory array 6910, row address logic 6920, column address decoder 6930, column selection logic 6940, word line drivers 6950, and sense amplifiers 6960. The number of rows and the number of columns of bit cells in bank 6900 are deliberately chosen to be small to better illustrate this embodiment. It should be noted that this embodiment may be designed for any number of rows and columns. Row address logic 6920 includes row address decoder 6924, and row remap logic 6928. Memory array 6910 includes two regions 6912 (MAIN REGION), and 6914 (REMAP REGION), each of which includes a plurality of word lines 6916, a plurality of bit lines 6918, and a plurality of bit cells 6970. Strictly as an example, region 6912 is shown to include 16 rows and 16 columns of bit cells, while region 6914 is shown to include 4 rows and 16 columns of bit cells. Of course, region 6912 and region 6914 may include any number of rows and columns. Bank 6900 may present itself to the rest of the memory system as a 16×16 array of bit cells (i.e. an array with bit cells organized as 16 rows and 16 columns).

In operation, row address remap logic 6928 may keep track of the last n row activate commands from an external logic device (e.g. logic die or layer, register, buffer, controller, processor, etc.), and remap a row from region 6912 to region 6914 if that row is (or was) the target of m activates of the last n activates, where m and n are integer numbers, and m≤n. As in the embodiments of FIG. 66, FIG. 67, and FIG. 68, frequently accessed rows may be remapped from region 6912 to region 6914, and thus region 6912 may contain the less frequently accessed rows. It should be noted that in any mapping of rows across the two regions 6912 and 6914, only 16 rows in bank 6900 may be accessible by an external logic device in the memory system, even though bank 6900 may have 20 rows of bit cells.

In this embodiment, region 6912 and region 6914 may have dissimilar electrical or logical design/configuration/connection (e.g. netlist, schematics, etc.), and/or physical design (word line pitch, bit line pitch, layout, fabrication steps, etc.). Region 6914 may include shield lines between each pair of word lines, which may act to reduce the disturbance of the charge stored in the bit cells of neighboring rows when a particular row in region 6914 is activated repeatedly. The shield lines in FIG. 69 are shown as being connected to GND strictly as an example. The shield lines may be conductors connected to any voltage rail (e.g. positive voltage, negative voltage, GND), left floating, or connected to any signal (e.g. a time varying signal). For example, the word lines in memory array 6910 may be poly lines, and the shield lines may also be poly lines that may be connected to GND. Thus, the data or charge disturbance caused by frequent accesses may be minimized in this embodiment.

In the embodiments of FIG. 66, FIG. 67, FIG. 68, and FIG. 69, m and n may be chosen by the manufacturer and hard coded or hard wired into the DRAM device during its design or manufacture, or selected by the memory system designer or user during the design of the memory system, or selected at run time, and programmed into the DRAM during power up or initialization of the DRAM device. Furthermore, the values of m and n may be stored in fuses or in non-volatile storage in the system. The values of m and n may be stored within a DRAM device or may be communicated to the DRAM device by an external device (e.g. logic die or layer, register, buffer, controller, processor, SPD, non-volatile memory device, etc.). In embodiments where the values of m and n are communicated by an external device, the DRAM device may initiate the communication of the values of m and n or an external device may initiate the communication.

Additionally, in the embodiments of FIG. 66, FIG. 67, FIG. 68, and FIG. 69, the MAIN REGION and the REMAP REGION are shown as being contiguous. In various embodiments, the rows of bit cells of the REMAP REGION may be distributed among the rows of bit cells of the MAIN REGION. That is, the MAIN REGION and the REMAP REGION may be non-contiguous.

FIG. 70 shows a more detailed view of the row remap logic of the embodiments of FIG. 66, FIG. 67, FIG. 68, and FIG. 69. As an option, any of the features of the present figure (and/or the description thereof) may be implemented in the context of the architecture and environment of any of the previous Figure(s) and/or any of the subsequent Figure(s).

Row remap logic 7000 includes remap controller 7010, counter 7020, decoders 7025 and 7040, registers 7030 that hold the last n row addresses, row address comparators 7035 and 7055, OR gates 7045 and 7060, and remapped row address registers 7050. It should be noted that the values of m and n are shown as 3 and 4 respectively in FIG. 70 strictly as an example. Row remap logic 7000 shown in FIG. 70 may be designed to support any values of m and n.

In operation, remap controller 7010 may receive address, control, and clock signals from an external logic device (e.g. logic die or layer, register, buffer, controller, processor, etc.) and may generate signals necessary for row remap operations. Upon receiving a row activate command or a specific signal from an external logic device (e.g. logic die or layer, register, buffer, controller, processor, etc.), remap controller 7010 may forward the received row address RA[3:0] on bus 7071 to row address registers 7030 and 7050, address comparators 7035 and 7055, and row address decoder 7090. Address comparators 7055 may compare the received row address with the remapped row addresses previously stored in remapped row address registers 7050. If there is a match, the address comparator 7055 that detected the match may be drive its corresponding word line driver (i.e. word line driver that is in communication with the comparator) high. That is, in the case of a match, one of the word line drivers connected to WL[19:16] may be driven high. As shown, the outputs of address comparators 7055 may also be connected to OR gate 7060. In the event of a match, OR gate 7060 may assert the REMAP_ADDR_MATCH signal 7079, that may be connected to remap controller 7010, to signal that the received row address matches the address of a remapped row. Remap controller 7010 may then act to disable the outputs of row address decoder 7090 by asserting DISABLE_ADDR_DECODER signal 7077, as the row corresponding to the received address has previously been relocated to the REMAP REGION.

In the case that the received row address does not match any of the remapped row addresses in address registers 7050 (i.e. the target row is in the MAIN REGION), row address decoder 7090 may then decode the address and drive the corresponding word line high in conjunction with a word line driver. This may then cause the contents of the addressed row to be placed on the bit lines (e.g. 6818 in FIG. 68) of the DRAM bank (e.g. 6800 in FIG. 68), and sensed by the associated sense amplifiers (e.g. 6860 of FIG. 68).

Furthermore, the received row address may be compared by address comparators 7035 against the last n received row address that are stored in address registers 7030. Each of the comparators 7035 may compare the received row address with the row address stored in the corresponding row address register 7030 (i.e. register that is in communication with the comparator), and may output a high if there is a match. The outputs of all address comparators 7035 may be input to decoder 7040. The outputs of decoder 7040 that correspond to input codes with at least 3 logic 1's (as m=3 is used as an example in this figure) may then be input to OR gate 7045. As can be seen from FIG. 70, outputs Y7 (corresponding to input ′b0111), Y11 (corresponding to input ′b1011), Y13 (corresponding to input ′b1101), and Y14 (corresponding to input ′b1110) are input to OR gate 7045. If any of the inputs to OR gate 7045 is high, OR gate 7045 may assert the M-OF-N_MATCH signal 7076, that may be connected to remap controller 7010, to signal that the received address meets the requirement for being a frequently activated row.

Remap controller 7010 may then act to load the received row address into the next unused row in the REMAP REGION by asserting the corresponding one of the ENABLE_ROW_ADDR_REG[3:0] signals 7078 and may then assert the LOAD_ROW_ADDR_REG signal 7080. After the received row address has been stored in one of row address registers 850, the corresponding address comparator 7055 may detect a match, and may drive the corresponding one of word lines WL[19:16] high in conjunction with a word line driver. It should be noted that timing of driving the one of WL[19:16] high may be chosen carefully so as to not disturb the values stored in the sense amplifiers (e.g. 6860 of FIG. 68), or conflict with column operation(s) to the DRAM bank (e.g. 6800 of FIG. 68). The result of driving the one of WL[19:16] high may effectively cause the transfer of the contents of the row in the MAIN REGION corresponding to the received row address to a row in the REMAP REGION. After this transfer, the word line corresponding to the received row address in the MAIN REGION may optionally be driven low.

The LOAD_ROW_ADDR_REG signal 7080 asserted by remap controller 7010 may also cause the received row address to be loaded into the row address register 7030 enabled by decoder 7025. Decoder 7025 may decode the contents of counter 7020, and assert one of its outputs 7074 which may then enable the row address register 7030 that contains the n^{th} previously received row address. It should be noted that counter 7020, decoder 7025, and address registers 7030 may act together as a circular buffer that stores the last n row addresses received. It should also be noted that counter 7020 may be designed as a log (n)-bit counter so as to rollover when the count is incremented beyond n−1, in order to implement the circular buffer. Accordingly, counter 7020 may be implemented as a 2-bit counter in FIG. 70 as n is 4 in this figure (strictly as an example). Remap controller 7010 may then pulse assert INCR_COUNTER signal 7072 to increment counter 7020.

After column operation(s) to the activated row have been done, the external logic device may issue a PRECHARGE command to the DRAM device. Upon receiving the PRECHARGE command, remap controller 7010 may act to de-assert all the word line drivers in the DRAM bank (e.g. 6800 in FIG. 68), and precharge all the bit lines. The exact mechanism of de-asserting all the word line drivers may be implementation specific. In some embodiments, the assertion of the one of WL[19:16] may be done when a PRECHARGE command is received. This may then cause the contents of the sense amplifiers to be written to bit cells of the row corresponding to the one of WL[19:16], after which all the active word line drivers may be driven low and bit lines precharged. As mentioned previously, the exact timing of the transfer of a row from the MAIN REGION (e.g. region 6912 in FIG. 69) to the REMAP REGION (e.g. region 6914 in FIG. 69) may be implementation dependent.

Remap controller 7010 may also clear the contents of row address registers 7030 and 7050 by asserting the CLR_ADDR_REG signal 7075. This may preferably be done when power is first applied to the DRAM device. In some embodiments, the remap controller 7010 may optionally act to move the remapped rows from the REMAP REGION (e.g. region 6814 in FIG. 68) to the MAIN REGION (e.g. region 6812 in FIG. 68) periodically. For example, after the refresh logic has cycled through all the rows in a DRAM bank (e.g. bank 6800 in FIG. 68), remap controller 7010 may move remapped rows from the REMAP REGION to the MAIN REGION. In other embodiments, this restore operation may be done when a specific signal is received from an external logic device, or may be done when the pattern of row activates changes, or under any other condition. After the restore operation has been completed, remap controller 7010 may clear the contents of address registers 7030 and 7050 by asserting the CLR_ADDR_REG signal 7076. In other embodiments, remap controller 7010 may have the capability to individually clear each of the remapped row address registers 7050, which may allow remap controller 7010 to move one or more of the remapped rows from the REMAP REGION to the MAIN REGION (e.g. during a refresh of a remapped row) and then clear the corresponding address register 7050.

It should be noted that embodiment of FIG. 70 shows the row remap logic as being fully implemented in the DRAM device itself. Thus, the row remap operation may be done by the DRAM device in a manner that may be transparent to the rest of the memory system. In other embodiments, some or all of the row remap logic may be implemented in an external logic device (e.g. logic die or layer, register, buffer, controller, processor, etc.). In such embodiments, the row remapping operation may be done by the external logic device and the DRAM device acting together. Strictly as an example, an external logic device (e.g. logic die, register, buffer, controller, processor, etc.) may include counter 7020, decoders 7025 and 7040, row address registers 7030, address comparators 7035, OR gate 7045, a part or all of remap controller 7010, and the connecting signals. The external logic device may capture and store the row addresses of the last n row activate commands, compare the current row address with the stored n row addresses, detect if the current address matches m of the n stored row addresses, and send a specific signal to one or more DRAM devices to remap the row corresponding to the received row address. In other embodiments, the remapped row address registers 7050, address comparators 7050, and OR gate 7060 may also be implemented in an external logic device. In such embodiments, the external logic device may send a specific signal to one or more DRAM device(s) to remap the row corresponding to the received row address, and provide the destination row address for the remap operation. That is, the external logic device may provide the address of a row in the REMAP REGION to which the contents of the row corresponding to the current row address may be moved. Furthermore, when a remapped row is being activated, the external logic device may substitute the address of the corresponding row in the MAIN REGION with the address of the remapped row in the REMAP REGION. Hence, the remap logic may be partitioned between one or more external logic devices and one or more DRAM devices in many ways.

FIG. 71 shows a simplified view of a flow chart 7100 of one embodiment (e.g. that illustrated in FIG. 70) of an address remap logic. As an option, any of the features of the present figure (and/or the description thereof) may be implemented in the context of the architecture and environment of any of the previous Figure(s) and/or any of the subsequent Figure(s).

The remap operation may be initiated when a new row ACTIVATE command may be received in step 7110 by the DRAM device or by an external logic device. In step 7120, the received row address may be compared against the addresses of previously remapped rows. If there is a match, the row address decoder (of the MAIN REGION) may be disabled in step 7130, and the remapped row may be activated in step 7135. If the received row address does not match the address of any of the remapped rows in step 7120, the addressed row (in the MAIN REGION) may be activated in step 7140. Then, the received address may be compared in step 7150 against the last n row addresses received to detect if the received row address matches m of the last n row addresses. If the received address matches m of the last n row addresses, then the next free row in the REMAP REGION may be activated in step 7160, so as to transfer the contents of the addressed row from the MAIN REGION to the REMAP REGION. Then, the received row address may be written into the remapped row address register corresponding to the just activated row in the REMAP REGION in step 7165.

Next, the newly received row address may be written into a circular buffer that holds the last n received row addresses and the pointer to the circular buffer incremented in step 7170. Then, column operations corresponding to incoming READ and/or WRITE commands may be performed by the DRAM device in step 7180. Then, when a PRECHARGE command is received, all word lines may be deactivated and the bit lines precharged in step 7190.

As previously mentioned, in some embodiments, one or more remapped rows may optionally be moved back or restored to the MAIN REGION after the one or more rows have been refreshed or when a specific signal from an external logic device is received by a DRAM device.

FIG. 72 illustrates a simplified view of the flow chart 7200 of a restore operation. As an option, any of the features of the present figure (and/or the description thereof) may be implemented in the context of the architecture and environment of any of the previous Figure(s) and/or any of the subsequent Figure(s).

When a new row REFRESH command (or a specific signal) is received in step 7210, the row address may be compared against the addressed of the remapped rows in step 7220. If the received row address does not match the address of any of the remapped rows, then the target row (in the MAIN REGION) may be refreshed in step 7230. However, if the received row address matches the address of a remapped row in step 7220, the remapped row (in the REMAP REGION) may be activated in step 7240. Next, the row address decoder may be activated and the row in the MAIN REGION that corresponds to the received row address may be activated in step 7250. This may then transfer the contents of remapped row to the MAIN REGION. Then, the remapped row address register corresponding to the refreshed row in the REMAP REGION may be cleared in step 7260. Furthermore, entries in the circular buffer that match the received row address may be cleared in step 7270. Finally, the word lines may be deactivated and the bit lines precharged in step 7280.

Some newer JEDEC standards allow DRAM device makers to include bit cells in each row that may be used exclusively to keep a count of the number of times that the row has been activated. For example, JEDEC allows DRAM device makers to optionally include this feature in DDR5 DRAM devices. In memory systems that include such DRAM devices, the row remap logic may be implemented differently from the remap logic in systems where DRAM devices do not have this feature.

FIG. 73 shows a simplified view of the flow chart 7300 of the row remap logic of one embodiment where the DRAM devices may have the capability to store the number of activates of each row in that row itself. As an option, any of the features of the present figure (and/or the description thereof) may be implemented in the context of the architecture and environment of any of the previous Figure(s) and/or any of the subsequent Figure(s).

When a new row ACTIVATE command (or a specific signal from an external logic device) is received in step 7310, the received row address may be compared with the addresses of the remapped rows in step 7320. In the event of a match, the row address decoder (of the MAIN REGION) may be disabled in step 7330, the remapped row (in the REMAP REGION) may be activated in step 7334, and the activate count of the row may be incremented in step 7338.

However, if the received row address does not match the address of any of the remapped rows in step 7320, the row (in the MAIN REGION) may be activated in step 7340. Next, the activate count of this row may be compared with a ACT_{THLD} parameter, which may represent a warning threshold to indicate that the row may be prone to being frequently activated. The value of ACT_{THLD} may be chosen by the manufacturer (e.g. at design or manufacturing time) or may be set by the memory system designer or user (e.g. at run time). If the activate count of the activated row is less than or equal to the ACT_{THLD} in step 7350, the activate count of the row may be incremented in step 7360. If, on the other hand, the activate count exceeds ACT_{THLD} in step 7350, then the row may be subject to a remap operation. In step 7370, the next free row in the REMAP REGION may be activated, the received row address may be written into the corresponding remapped row address register in step 7374, and the activate count of the row in the REMAP REGION may be incremented in step 7378. In some embodiments, the row corresponding to the received row address in the MAIN REGION may optionally now be deactivated.

Column operations corresponding to incoming READ and/or WRITE commands may then be performed in step 7380. Finally, when a PRECHARGE command is received, the word lines may be deactivated and bit lines precharged in step 7390.

A refresh of a row of a DRAM device may restore the contents of the bit cells of that row. Accordingly, for example, if row p of a DRAM device is accessed frequently, such accesses may disturb the contents (i.e. stored charge) of the bit cells of rows p−1 and p+1, and possibly, the contents of the bit cells of rows p−2 and p+2. In current art DRAM devices, refresh commands or operations are done at the individual row level. In other words, the granularity of refresh commands or operations is 1 row. The interval between successive refresh operations may typically specified by the t_{REFI} parameter. For example, in a DRAM device with 8k rows and retention time of 64 ms (i.e. all bit cells in the DRAM device are guaranteed to hold the charge for 64 ms), t_{REFI} may be 64 ms, 8,192=7.8 ms. Accordingly, in this example, a row p+1 may be refreshed 7.8 ms after row p was refreshed. However, in current art DRAM devices, refreshes to rows may be deferred for up to q*t_{REFI}, where q is an integer and t_{REFI} is the refresh interval. For example, in DDR3 DRAM devices, 8 rows may be refreshed within a time interval of 8*t_{REFI}. So, an external logic device may defer refreshing 8 rows for approximately 8*7.8 ms and then 8 refresh operations may be scheduled back-to-back. That is, an external logic device may issue 8 consecutive or back-to-back refresh commands to a DRAM device. This feature may provide great flexibility to the external logic device in scheduling memory accesses (e.g. read, write, etc.) and refresh operations to improve the performance of the memory system without impacting the integrity of the data stored in memory. However, this feature may also exacerbate the disturbance of the charge stored in bit cells of one or more rows due to frequent accesses to a neighboring row. For example, an external logic device may defer refreshes to rows p+1 and p+2 and prioritize accesses to row p. However, row p may be accessed a large number of times before the deferred refreshes to rows p+1 and p+2 are done. Accordingly, deferred refreshes may exacerbate the disturbance of the charge stored in the bit cells of rows p+1 and p+2 caused by frequent accesses to row p.

FIG. 74 illustrates a simplified view of a bank of a DRAM device in yet another embodiment. As an option, any of the features of the present figure (and/or the description thereof) may be implemented in the context of the architecture and environment of any of the previous Figure(s) and/or any of the subsequent Figure(s).

DRAM bank 7400 includes memory array 7410, row address logic 7420, column address decoder 7430, column selection logic 7440, word line drivers 7450, and sense amplifiers 7460. Row address logic 7420 includes row management logic 7424, and row address decoder 7428. The number of rows and the number of columns of bit cells in bank 7400 are deliberately limited to better illustrate this embodiment. It should be noted that this embodiment may be designed for any number of rows and columns. Memory array 7410 includes two groups or regions of rows 7411 and 7412, each of which includes a plurality of word lines 7416, a plurality of bit lines 7418, and a plurality of bit cells 7470. As shown, each of the region 7411 and 7412 includes 8 rows and 16 columns of bit cells. Bank 7400 may present itself to the rest of the memory system as a 16×16 array of bit cells (i.e. an array with bit cells organized as 16 rows and 16 columns). Region 7411 and region 7412 may be separated by a guard band 7415. In various embodiments, guard band 7415 may be a larger row pitch, a row of bit cells (e.g. a dummy row, a row of bit cells that may not be used to store data, etc.), a shield line (e.g. a conductor connected to one of: GND, a voltage, a signal, left floating, etc.), or any other means that may reduce the disturbance of the charge stored in a row of bit cells in one region when a row in a neighboring region is accessed frequently. For example, guard band 7415 may be implemented in any way so as to reduce the disturbance of the charge stored in the bit cells of row 8 (i.e. row belonging to region 7412) when row 7 (i.e. row belonging to region 7411) may be accessed frequently.

In operation, refreshes to bank 7400 may be specified and done at the region level. In other words, a refresh command (e.g. from an external logic device, from internal self-refresh logic, etc.) may be directed at a region or group of rows. For example, a refresh command may specify region 7411 as the target, and the row management logic 7424 in bank 7400 may refresh all the rows in region 7411 as an atomic operation (e.g. sequentially, without interruption). Furthermore, row management logic 7424 may keep track of the regions that include the most frequently activated rows. That is, the tracking may be done at the region level. For example, if row 11 is much more frequently activated than the remaining rows in memory array 7410, the row management logic 7424 may mark or denote region 7412 as being frequently activated.

The embodiment of FIG. 21 includes group word lines (e.g. GPWL[0]) that may be activated when a row in that group is accessed. A group word line may connect to the gate terminals of group access transistors, wherein these group access transistors do not have associated capacitors. As such, the group word line may act as a guard band for the rows in that group.

FIG. 75 shows a simplified view of a bank of a DRAM device in another embodiment. As an option, any of the features of the present figure (and/or the description thereof) may be implemented in the context of the architecture and environment of any of the previous Figure(s) and/or any of the subsequent Figure(s).

Bank 7500 includes three groups of word lines 7580A-7580C, a shield line 7530, a plurality of bit lines BL[7:0], one of which is labeled 7550, and a plurality of bit cells, one of which is labeled 7560. Each group is shown to include two word lines (one of which is labeled 7510), a group word line 7520, and a plurality of local bit lines, one of which is labeled 7540. The number of word lines per group is deliberately kept small to better illustrate this embodiment. The groups may be designed such that the odd numbered groups (e.g. groups 7580A, 7580C) may have the group word line at the bottom of the group, while the even numbered groups (e.g. group 7580B) may have the group word line at the top of the group. Consequently, two group word lines may act as a guard band between an odd numbered group and an even numbered group. For example, GPWL[0] and GPWL[1] may act as a guard band for the rows of bit cells in groups 7580A and 7580B by providing a distance between WL[1] and WL[2], where the distance may be larger than the word line pitch. Furthermore, a guard band may be inserted between an even numbered group and an odd numbered group. For example, a guard band 7530 may be inserted between group 7580B and 7580C. While guard band 7530 is shown as a grounded shield line in FIG. 75, the guard band 7530 may be implemented in any other manner.

In the embodiments of FIG. 74 and FIG. 75, regions that are marked or denoted as being frequently activated may be refreshed more often than regions that are not marked or denoted as being frequently activated. In some embodiments, the regions with the highest number of activates may be marked as being frequently activated, and hence refreshed more frequently than the other regions. For example, in a DRAM bank with 8 regions, if the number of activates of each of the regions 0 through 7 are 1, 1, 0, 6, 8, 4, 2, and 5 respectively, regions 3 and 4 (i.e. the regions with activate counts of 6 and 8 respectively) may be marked as being frequently activated regions, and thus refreshed more frequently than the remaining regions. In other embodiments, regions with activate counts greater than a threshold value may be marked as being more frequently activated. For example, in the case as described above, if the threshold is set as 4, then regions 3, 4, and 7 (i.e. regions with activate counts 6, 8, and 5 respectively) may be marked as being more frequently activated, and thus refreshed at a higher rate than the other regions. Of course, any method may be used to identify and mark frequently activated regions.

In such embodiments, the DRAM device may manage the frequency of refreshes of each region by itself or may act together with an external logic device to manage the frequency of refreshes. For example, the DRAM device may indicate to an external logic device to temporarily pause communicating new commands to the DRAM device, refresh one or more frequently accessed regions, and then may indicate to the external logic device that it is ready to receive new commands. In another example, an external logic device may keep track of the activate counts of each of the regions and communicate refreshes to the DRAM device in a manner such that frequently accessed regions are refreshed more often than the other regions.

FIG. 76 shows a simplified view of a bank of a DRAM device in another embodiment. As an option, any of the features of the present figure (and/or the description thereof) may be implemented in the context of the architecture and environment of any of the previous Figure(s) and/or any of the subsequent Figure(s).

Bank 7600 includes memory array 7610, row decoder 7620, column decoder 7630, column selection logic 7640, word line drivers 7650, sense amplifiers 7660, and voltage source(s) 7616. Memory array 7610 includes a plurality of word lines 7612, a plurality of bit lines 7614, a plurality of bit cells 7670, a plurality of voltage lines 7618, and a plurality of transistors 7619, three of which are labeled as 7619A, 7619B, and 7619C. Voltage lines 7618 may connect to voltage source(s) 7616. Each word line 7612 may connect to the gate terminals of one or more transistors 7619. The source terminals of transistors 7619 may be connected to voltage lines 7618. The drain terminal of each of the transistor 7619 may be connected to a neighboring word line. The number of rows and the number of columns of bit cells in bank 7600 are deliberately limited to better illustrate this embodiment. It should be noted that this embodiment may be designed for any number of rows and columns. It should also be noted that source and drain terminals may be interchangeable for a typical MOS transistor.

In operation, when a word line 7612 is driven high by its corresponding word line driver 7650, it may cause a voltage change on the neighboring word lines due to parasitic coupling. Transistor(s) 7619 controlled by the energized word line 7612 that is driven high may turn on and clamp the neighboring word line(s) to voltage V_{C}, to limit the undesirable voltage change by shunting the charge injected by the coupling to V_{C}. In various embodiments, V_{C} may be GND, a positive voltage, a negative voltage, a time-varying signal, or a high impedance (e.g. floating) signal. For example, when WL0 is driven high, transistor 7619A may turn on and clamp WL1 to V_{C}. Similarly, when WL1 is driven high, transistors 7619B and 7619C may turn on, and clamp WL0 and WL2 respectively to V_{C}. Clamping word lines to V_{C} at one or more points along the entire length of a word line may provide multiple shunt or discharge paths to V_{C}. That is, undesirable noise coupled to a word line may be shunted or discharged by one or more transistors 7619 at one or more nodes along the length of the word line. That is, transistor(s) 7619 may act as clamping transistors.

The embodiment shown in FIG. 76 includes transistors 7619 that clamp the one or two neighboring word lines to V_{C}. For example, WL0 has only one neighboring word line, so it controls only one transistor 7619A, which acts to clamp WL1 to V_{C}. WL1, on the other hand, has two neighboring word lines (i.e. WL0 and WL2), and so controls two transistors 7619B and 7619C, that act to clamp WL0 and WL2 to V_{C} respectively. However, this embodiment can easily be extended to include clamping more than the one or two nearest neighboring word lines. For instance, in another embodiment, each word line may control transistors 7619 that may act to clamp the nearest two, three, or four neighboring word lines. In such an embodiment, driving WL0 high may cause transistors 7619 controlled by WL0 to clamp WL1 and WL2 to V_{C}. Similarly, driving WL1 high may cause transistors 7619 controlled by WL1 to clamp WL0, WL2, and WL3 to V_{C}. Furthermore, driving WL2 high may cause transistors 7619 controlled by WL2 to clamp WL0, WL1, WL3, and WL4 to V_{C}.

FIG. 77 illustrates a simplified view of an example layout 7700 of a portion of DRAM bank 7600 of the embodiment of FIG. 76. As an option, any of the features of the present figure (and/or the description thereof) may be implemented in the context of the architecture and environment of any of the previous Figure(s) and/or any of the subsequent Figure(s).

As shown, layout 7700 includes word lines WL[5:0] 7710 which may be implemented in poly, and bit lines BL[5:0] 7720 which may be implemented in a metal layer. DRAM bit cell 7740 may include diffusion 7742, capacitor 7746, and bit line contact or via 7748. Clamping transistor 7750 may include diffusion 7752, contact or via to V_{C} 7756, and word line contact or via 7758. It should be noted that layout 7700 is strictly an example. The exact layout and layer details may be implementation dependent and may vary from DRAM maker to DRAM maker. For example, the word lines and the bit lines may be implemented on other layers of the DRAM die. Also, the orientation of the word lines, bit lines, and diffusion may be different. Furthermore, neighboring bit cells may share a bit line contact. Similarly, a plurality of clamping transistors may share a via to V_{C}. As such, the embodiment of FIG. 76 may be physically and logically implemented in any manner chosen by the DRAM maker according to their fabrication process.

The embodiments of FIG. 76 and FIG. 77 show each word line controlling one clamping transistor to clamp each of the neighboring word lines to V_{C} strictly as an example. For example, in FIG. 76, transistors 7619B and 7619C turn on when WL1 is driven high, and clamp WL0 and WL2 respectively to V_{C}. Other embodiments may have a plurality of clamping transistors that are controlled by a word line to clamp each of the neighboring word lines to V_{C} at multiple places. For example, in one embodiment, row n may have one transistor 7619 to clamp the word line of row n−1 to V_{C} and one transistor 7619 to clamp the word line of row n+1 to V_{C} for every 256 bit cells. Say that this embodiment has 2048 bit cells in each row; then row n may have 8 transistors 7619 to clamp word line n−1 and 8 transistors 7619 to clamp word line n+1 to V_{C}. Moreover, the clamping transistors 7619 may be distributed along the length of word line n. That is, the locations of the clamping transistors may be spread out along the length of word line n. Any number of clamping transistors 7619 may be used by the DRAM maker in each row to minimize or eliminate the disturbance of charge stored in bit cells due to frequent accesses to neighboring rows.

FIG. 78 illustrates a simplified block diagram of a bank of a DRAM device in yet another embodiment. As an option, any of the features of the present figure (and/or the description thereof) may be implemented in the context of the architecture and environment of any of the previous Figure(s) and/or any of the subsequent Figure(s).

In this embodiment, bank 7800 of a DRAM device includes memory array 7810, row remap logic 7830, row decoder 7840, and a plurality of word line drivers 7850A through 7850P. Memory array 7810 includes 16 rows of bit cells 7820A through 7820P. Note that memory array 7810 is shown to include 16 rows of bit cells strictly as an example. Memory array 7810 may include any number of rows. Also note that many other blocks of DRAM bank 7800 (e.g. column decoder, column selection logic, sense amplifiers, etc.) are not shown to simplify the figure. Each row in DRAM bank 7800 may have an internal or physical address and an external or virtual address. In some embodiments, the physical address of a row may correspond to the physical location of that row in the memory array. For example, if FIG. 78 is the top view of memory array 7810, moving from the top of the page to the bottom of the page, the physical addresses of the 16 rows in memory array 7810 may increment sequentially from 0 to 15. That is, the row with physical address 0 may be closest to the top of the page, the row with physical address 1 may be the row immediately below the row with physical address 0, and so on. It should be clear that row decoder 7840 may be designed to reflect the physical addresses of the rows. That is, if RRA[3:0] in FIG. 78 is ′0000b, then decoder 7840 may drive the word line driver 7850A high, so that row 7820A may be activated. Similarly, if RRA[3:0] is ′1111b, decoder 7840 may drive the word line driver 7850P high, so that row 7820P may be activated. The physical address of a row in FIG. 78 may be denoted as p{m}, where m may be an integer value ranging from 0 to 15. It should be noted that m may equal the number of rows in bank 7800.

Each row in DRAM bank 7800 may also have an external or virtual address v{n}, where n may be an integer value ranging from 0 to 15. It should be noted that n may equal the number of rows in bank 7800. The virtual address may correspond to the row address received by DRAM bank 7800 from an external logic device (e.g. logic die or layer, register, buffer, controller, processor, etc.). That is, the virtual address may correspond to row address RA[3:0]. Row remap logic 7830 may act to transform or convert the virtual address to a physical address. For example, table 7880 shows the virtual and physical row addresses of rows 7820A through 7820P of DRAM bank 7800 before any remapping is done. In other words, v{m}=p{n}, for 0 £m, n £15 before any remapping is done. Table 7890 shows the virtual address and physical addresses of rows 7820A through 7820P after an example row remapping or row address transformation or row address conversion. As can be seen from both these tables, row 7820A may correspond to virtual address ′0000b before any remapping is done, and may correspond to virtual address ′0110b after remapping is done. The terminology v{m}: p{n}, where 0 £m, n £15, may be used to denote the virtual and physical addresses of each row of DRAM bank 7800. Accordingly, row 7820A may be denoted as v{0}: p{0} before any remapping in Table 7880 and as v{0}: p{6} after remapping in Table 7890. It should be noted that rows 7820A through 7820P are in the physical domain.

Furthermore, in this embodiment, DRAM bank 7800 may maintain two lists or tables of row addresses. One of these tables (e.g. HIGH_ACT table) may include the physical row addresses of rows that are the most frequently activated, while the other table (e.g. LOW_ACT table) may include the physical row addresses of rows that are the least frequently activated. Two predefined values, MIN_HI_ACT and MAX_LO_ACT, may be used to determine entries in the HIGH_ACT and LOW_ACT tables respectively. That is, the physical addresses of rows with activate counts equal to or greater than MIN_HI_ACT may be stored in the HIGH_ACT table. Similarly, the physical addresses of rows with activate counts less than or equal to MAX_LO_ACT may be stored in the LOW_ACT table. The activate counts of each row may be enumerated and stored in the DRAM device in many ways. For example, the activate count may be stored in a field in each row and incremented when that row is either activated or precharged. In another example, the counts may be stored in a separate SRAM array inside the DRAM device and a row count may be incremented during the row's activate or precharge operation. In addition, each activate count field may also include a SWAP bit.

In operation, when the activate count of a row in the HIGH_ACT table exceeds a threshold value ACT_THLD, row remap logic 7830 may act to swap the contents of that row with the contents of another row from the LOW_ACT table. The value of ACT_THLD may preferably be set higher than MIN_HI_ACT. For example, say that the HIGH_ACT table contains physical row addresses (in decimal) 0, 4, 9, and 11 (i.e. rows 7820A, 7820E, 7820J, and 7820L respectively), while the LOW_ACT table contains physical row addresses (in decimal) 2, 6, 7, 13, 14, and 15 (i.e. rows 7820C, 7820G, 7820H, 7820N, 78200, and 7820P respectively). It should be noted that the virtual address of each of the rows may be the same as the physical address before any remapping is done. Now, say that the activate count of row 7820E exceeds ACT_THLD when it is activated or precharged. Then, the row remap logic may act to swap row 7820E with, say, row 7820H. That is, the virtual to physical mapping of rows 7820E and 7820H may change from v{4}: p{4} and v{7}: p{7} respectively to v{4}: p{7} and v{7}: p{4} respectively. Additionally, the SWAP bit of row 7820H may be set to indicate that it now contains the contents of a swapped row. It should be noted that the activate count of the rows and the corresponding SWAP bit may not be swapped during the remap operation. In other words, the activate count and the corresponding SWAP bit may be tied to the physical address and may not move during a remap operation. If rows adjacent to frequently activated rows are refreshed more frequently, associating activate counts and SWAP bits with physical row addresses may ensure that rows adjacent to a frequently activated row that has since been relocated or remapped are included among the rows that are to be refreshed more often than the other rows. For example, if row 7820E was a frequently activated row, rows 7820D and 7820F may be more likely to have undergone charge disturbance (i.e. may be victim rows) than other rows and should be more frequently refreshed in the case that such a scheme is used to ameliorate the effects of frequent activates. Just relocating row 7820E (i.e. the aggressor row) may not ameliorate the charge disturbance already experienced by rows 7820D and 7820F.

In the event that a frequently activated row continues to be activated repeatedly after remapping, the activate count of the row may increase. If the activate count becomes greater than MAX_LO_ACT, the physical address of the row may be removed from the LOW_ACT table. Further activates to the row may increment the activate count. If the activate count becomes equal to or greater MIN_HI_ACT, the physical address of the row may be added to the HIGH_ACT table. Additional activates to this row may cause the activate count to exceed ACT_THLD, which may then cause the row to be swapped with another row in the LOW_ACT table. For example, repeated and frequent activates to row v{4}: p{7} may cause the activate count of row 7 to become higher than MAX_LO_ACT. In this event, physical address (decimal) 7 (i.e. row 7820H) may be removed from the LOW_ACT table. If the activate count of row 7 (i.e. activate count of row 7820H) becomes equal to or greater than MIN_HI_ACT, physical address (decimal) 7 (i.e. row 7820H) may be added to the HIGH_ACT table. Then, if the activate count exceeds ACT_THLD, row 7820H may be swapped with a row in the LOW_ACT table.

The SWAP bit associated with each row may indicate to the row remap logic that a frequently activated row has been remapped to this physical address. The row remap logic may then select a row from the LOW_ACT table whose SWAP bit has not been set (i.e. is logic 0). For example, say, the HIGH_ACT table includes physical row addresses (decimal) 1 and 4, the LOW_ACT table include physical row addresses (decimal) 7, 10, and 15. Also say, row 4's (i.e. row 7820E's) activate count exceeded ACT_THLD and hence, is to be swapped with row 7 (i.e. with row 7820H). After the swap operation, row 7820E now corresponds to v{7}: p{4}, row 7820H corresponds to v{4}: p{7}, the HIGH_ACT table includes physical row addresses (decimal) 1 and 4, the LOW_ACT table include physical row addresses (decimal) 7, 10, and 15, and the SWAP bit of row 7 (i.e. row 7820H) is set (i.e. is logic 1). Now, say that the activate count of row 1 (i.e. activate count of row 7820B) exceeds ACT_THLD. Since the SWAP bit of row 7 is set, the row remap logic may swap row 1 with either row 10 or 11, but not with row 7 since its SWAP bit is set. In various embodiments, the sizes (i.e. number of entries) of the HIGH_ACT table and the LOW_ACT table may be the same, the size of the HIGH_ACT table may be smaller than that of the LOW_ACT table, or the size of the HIGH_ACT table may be larger than that of the LOW_ACT table. It may be advantageous to make the size of the LOW_ACT table larger than the size of the HIGH_ACT table so as to spread the activates over a larger number of rows but of course, other sizes of the two tables may be implemented.

A pseudo-code of the remap logic of the embodiment of FIG. 78 is shown below.

| | |
|---|---|
| const int MIN_HI_ACT = C1; | /* C1 is predefined constant */ |
| const int MAX_LO_ACT = C2; | /* C2 is predefined constant */ |
| const int ACT_THLD = C3; | /* C3 is predefined constant */ |
| const int NUM_ROWS_DEVICE = C4; | /* C4 is number of rows in device */ |
| const int NUM_ENTRIES_HI_ACT = C5; | /* C5 predefined constant */ |
| const int NUM_ENTRIES_LOW_ACT = C6; | /* C6 is predefined constant */ |

int HIGH_ACT[NUM_ENTRIES_HI_ACT] = 0;
int LOW_ACT[NUM_ENTRIES_LOW_ACT] = 0;
int RefreshCount = 0;
int ActivateCount[NUM_ROWS_IN_DEVICE] = 0;
int main( )
{
if new_cmd == ACTIVATE {

| | |
|---|---|
| activate NewRow; | /* NewRow is row address of ACTIVATE command */ |

} else if new_cmd == READ {

| | |
|---|---|
| read NewCol; | /* NewCol is column address of READ command */ |

} else if new_cmd == WRITE {

| | |
|---|---|
| write NewCol; | /* NewCol is column address of WRITE command */ |

```
  } else if new_cmd == PRECHARGE {
    ActivateCount[NewRow]++;
    if ActivateCount[NewRow] ³ ACT_THLD {
      select row in LOW_ACT table with SWAP bit == 0;
      swap NewRow in HIGH_ACT table with selected row in LOW_ACT table;
      set SWAP bit of NewRow entry in LOW_ACT table = 1;
    }
    } else if ActivateCount[NewRow] ³ MIN_HI_ACT {
      add NewRow to HIGH_ACT table;
    } else if ActivateCount[NewRow] < MAX_LO_ACT {
      add NewRow to LOW_ACT table;
    } else if ActivateCount[NewRow] > MAX_LO_ACT && NewRow is in LOW_ACT table {
      remove NewRow from LOW_ACT table;
    }
    precharge row;
```

| | |
|---|---|
| } else if new_cmd == REFRESH { | /* optional |

```
    refresh row;
    RefreshCount++;
    if RefreshCount == NUM_ROWS_IN_DEVICE {
      restore all rows to original locations;
      clear HIGH_ACT and LOW_ACT tables;
      RefreshCount = 0;
    }
  }
}
```

Strictly as an option, all row remapping may be reversed in this embodiment (i.e. all rows restored to the original locations such that the virtual address of each row in a DRAM bank may match the physical address; that is, v{m}=p{n} for all values of m, n), and HIGH_ACT and LOW_ACT table entries cleared after all the rows in the DRAM bank have been refreshed. This row mapping restore operation may be done after every complete refresh of the DRAM bank or after every p complete refreshes, where p is an integer. For example, DRAM makers may specify that all the rows in the DRAM device must be refreshed once every 64 ms. That is, every row must be refreshed within a 64 ms window. In such case, the row mapping may be restored and all entries in the HIGH_ACT and LOW_ACT tables cleared every 64 ms, or every p*64 ms, where p is a positive integer.

While the activate count enumeration and storage, the identification of rows with high activation and low activation counts (i.e. the HIGH_ACT and LOW_ACT tables), and the row remapping in the embodiment of FIG. 78 are all described as being implemented in the DRAM device itself, in other embodiments, some or all of these functions may be implemented in a device external to the DRAM device. For example, a register device, logic die, processor, or controller (e.g. CXL controller, memory controller, etc.) may be designed to enumerate and store the activate count of each row of the DRAM device, identify the most frequently activated and the least frequently activated rows, and remap one or more frequently activated rows with one or more less frequently activated rows in cooperation with a DRAM device. In another example, a register, logic die, processor, or controller (e.g. CXL controller, memory controller, etc.) may enumerate and store the activate counts of all the rows, and may communicate to a DRAM device that the row address currently being input to the DRAM device should be remapped. The DRAM device may then, for example, relocate the row from a first region (e.g. MAIN REGION) to a second region (e.g. REMAP REGION).

The DRAM bank 7800 of the embodiment of FIG. 78 may include registers or a lookup table to store remapped addresses. Additionally, the embodiments of FIG. 66, FIG. 67, FIG. 68, and FIG. 69 all include row remap logic, one embodiment of which is shown in FIG. 70. Row remap logic 7000 in FIG. 70 is shown to include address registers 7050 to store the remapped row addresses. It should be noted that remapped row addresses may also be stored in any storage circuit, such as an SRAM array, EEPROMs, NAND or NOR Flash array, etc. It should also be noted that, in various embodiments, the all the remapping (e.g. as in the embodiments of FIG. 66, FIG. 67, FIG. 68, FIG. 69, and FIG. 78) may be done during an activate operation, or all the remapping may be done during a precharge operation, or a first portion of the remapping may be done during an activate operation and a second portion may be done during a precharge operation.

Additionally, some or all of the access disturbance protection means in the embodiments described above may optionally be implemented in one or more external logic devices (e.g. logic die or layer, register, buffer, controller, processor, etc.). The one or more logic devices may operate with one or more DRAM devices to reduce or eliminate disturbance of the data stored in the one or more DRAM devices due to frequent activates of one or more rows of the DRAM device(s).

FIG. 79 illustrates a memory system 7900 that includes controller 7910, memory module 7920, and a plurality of DRAM devices 7920A-7920R. As an option, any of the features of the present figure (and/or the description thereof) may be implemented in the context of the architecture and environment of any of the previous Figure(s) and/or any of the subsequent Figure(s).

Controller 7910 may be a memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, or any device that is capable of being in communication with a DRAM device. Examples of memory module 7920 include single inline memory module (SIMM), dual inline memory module (DIMM), etc. Although FIG. 79 shows memory module 7920 as a separate printed circuit board (PCB), it must be understood that DRAM devices 7920A-7920R may be mounted on the same PCB as controller 7910, or may be mounted on the same substrate as controller 7910. Controller 7910 and DRAM devices 7920A-7920R may also be implemented as a system-in-package (SiP), dies stacked on wafers, dies stacked on dies, wafers stacked on wafers, organized as a 2.5D stack, organized as a 3D stack, etc. Control signals 7970 and address signals 7973 may mostly flow from the controller 7910 to memory module 7920 while data signals 7976 may flow bi-directionally between the memory module and controller. Memory system 7900 may have advanced error correction capability (e.g. Chipkill™, etc.) that may be capable of continuing to operate when any one of the DRAM devices 7920A-7920R fails.

As described previously, in the embodiment illustrated in FIG. 24, counter B 2445 may be replaced with a circuit or logic block that generates a random or pseudo-random number between 0000b and 1111b each time control logic 2450 pulses the INCR_CNTR_B signal 2495 high. An example of a pseudo-random number generator is an LFSR, a linear feedback shift register. Memory devices 7920A-7920R of memory system 7900 may include remap logic that remaps rows to regions in a random or pseudo-random manner, an example of which is illustrated in FIG. 36. Furthermore, such random or pseudo-random number generating circuits or logic blocks may be designed, configured, or operated such that the number generating circuit or logic block in each of the memory devices 7920A-7920R may generate a unique sequence of row addresses. For example, the number generating circuit or logic block in device 7920A may generate a random or pseudo-random sequence of row addresses that is different from the sequence of row addresses generated by the number generating circuits or logic blocks in each of the other memory devices 7920B-7920R. For example, the number generating circuits or logic blocks in each of the memory devices 7920A-7920R may be linear feedback shift registers (LFSRs) that have unique characteristic polynomials (i.e. unique arrangement of feedback taps). In another example, the number generating circuits may be random number generators with unique seed values. For example, in DRAM device 7920A, the row with row address RA[3:0]=0010b (decimal 2) may have rows with row addresses RA[3:0]=0110b (decimal 6) and RA[3:0]=1100b (decimal 14) respectively as neighbors after remapping, whereas in DRAM device 7920B, the row with row address RA[3:0]=0010b (decimal 2) may have rows with row addresses RA[3:0]=0000b (decimal 0) and RA[3:0]=1000b (decimal 8) respectively after remapping.

This may provide an optional improvement to the reliability of memory system 7900 in that it provides better protection against disturbance of charge stored in one or more rows of bit cells due to repeated accesses to a neighboring row of bit cells. Since DRAM devices 7920A-7920R may each have a unique, and different, row remapping, repeated memory accesses to a first row may disturb different victim rows in each of the devices. For example, repeated accesses to row with row address RA[3:0]=0010b (decimal 2) may disturb the charge stored in different rows in each of the DRAM devices 7920A-7920R. Note that such repeated accesses may be caused by malicious software programs, such as Rowhammer (also called as row hammer, RowHammer, Row Hammer, etc.). If memory system 7900 were to have advanced error correction capability like Chipkill™, the memory system may be able to recover from Rowhammer, as a read to the neighboring victim row may result in incorrect values being read from only one memory device. For example, after repeated accesses to row with row address RA[3:0]=0010b (decimal 2), an access to row with row address RA[3:0]=0000b (decimal 0) may result in incorrect data being read from DRAM device 7920B while the remaining DRAM devices 7920A and 7920C-7920R may return the correct data. Therefore, the Chipkill™ capability of memory system 7900 may correct the incorrect data and thus, continue operating without errors.

Providing memory devices with programmable row addresses may optionally provide flexibility to memory device designers and manufacturers to design and develop special purpose memory devices. For example, remapping row addresses may enable content addressable memory devices, translation lookaside buffers, lookup tables, etc. that have one or more desirable characteristics. Such devices may typically have an entry per row, where the entry may include an index or key field and a corresponding value field.

FIG. 80 illustrates the row remap logic 8000 in yet another embodiment. As an option, any of the features of the present figure (and/or the description thereof) may be implemented in the context of the architecture and environment of any of the previous Figure(s) and/or any of the subsequent Figure(s).

Row remap logic 8000 includes control block 8010, hash function generator 8020, multiplexer 8030, and row address decoder 8040. Control block includes control logic 8014 and counter 8018. Row address decoder 8040 includes a plurality of row address blocks, wherein each row of bit cells of the memory device may have a corresponding row address block. One such row address block is labeled 8050A. An expanded view of row address block 8050A is shown at the top of the figure. Row address block 8050A includes default row address register 8052A, remap row address register 8054A, multiplexer 8056A, and address comparator 8058A. Each of the outputs of row address decoder 8040 may connect to a corresponding word line driver, one of which is labeled 8060A. It should be noted that row remap logic 8000 is shown for a limited number of rows and row address bits (4 and 2, respectively) to better illustrate this embodiment. Of course, this embodiment may be easily extended to support any number of rows. It should also be noted that while the default row address is shown as being stored in a register 8052A strictly as an example, other storage options may also be used. For example, the default row address may be hard wired in the device.

In operation, after power on or after a reset operation, counter 8018 and the plurality of remap row address registers 8054A-8054D may be reset or cleared. An external device (e.g. memory controller, microprocessor, central processing unit (CPU), application processor, graphics processor unit (GPU), artificial intelligence processor (AI processor), machine learning processor (ML processor), tensor processing unit (TPU), accelerated processing unit (APU), network processing unit (NPU), application specific integrated circuit (ASIC), System-on-Chip (SoC), field programmable gate array (FPGA), CXL endpoint, buffer, register, HBM logic die, HMC logic die, or any device that is capable of being in communication with a memory device) may load the memory device with pairs of tags and values. Index or key may be alternate terms for a tag. Each tag may have a value associated with it.

Say that an external device writes a tag and the associated value to row 0 of the memory device. Control block 8010 may compare the incoming row address (e.g. 00b) with the value in counter 8018. Since the two values may be equal, control block 8010 may place a logic 0 on REMAP signal 8076. This may cause multiplexer 8030 to select RA[1:0] as RRA[1:0] (i.e. make RRA[1:0]=RA[1:0]). Since REMAP signal 8076 is low, multiplexer 8056A may drive the default row address (in register 8052A) onto VAL [1:0]. Address comparator 8058A may compare VAL [1:0] to RRA[1:0], and since the two values may match, drive Y0 high. This may then enable word line driver 8060A to energize, and enable a write to row 0.

During the write operation, hash function generator 8020 may output a hash value of the tag portion of the write data, DQ[i−1:0] on signal lines HASH [1:0] 8074. At the end of the write operation, counter 8018 may increment from 00b to 01b. Furthermore, control block 8010 may pulse UPDATE_MAP signal 8078 high. This may cause HASH [1:0] to be stored in the remap row address register 8054A. An external device may then write tag and value pairs to rows 1, 2, and 3 in a similar manner. Note that control block 8010 may generate individual Enable signals to each of the row address blocks 8050A-8050D. These Enable signals may be used to enable the storing of the remap address in the correct one of remap row address registers 8054A-8054D. In other words, only one of Enable signals may be active when a row remapping operation is done. These Enable signals are not shown in FIG. 80 to avoid cluttering the figure.

Now, to do a query or reverse lookup using a tag, the external device may send a tag to the memory device and expect the associated or paired value to be returned by the memory device. Say, that the external device sends the tag stored in row 2 (i.e. RA[1:0]=10b). Hash function generator 8020 may generate the hash function of the tag received from the external device. Furthermore, since RA[1:0] may be less than the value in counter 8018 (i.e. 100b), control block 8010 may drive REMAP signal 8076 high. This may cause multiplexer 8030 to place HASH [1:0] onto RRA[1:0]. Similarly, multiplexer 8056C may place the contents of remap row address register 8054C onto signal lines VAL [1:0]. Since the remap row address register was programmed with the hash function of the tag in row 2, address comparator 8058C may detect a match and drive Y2 high. This may result in a read of the contents of row 2, and the value in row 2 may be returned to the external device.

In cases where the tag has a large number of bits (e.g. 48 or 64 bits), the hash function generator may output the same hash value for more than one value of the tag. That is, the hash function generator may output a many-to-one mapping. For example, say that the tag stored in row 0 and the tag stored in row 2 alias to the same hash value. A query or reverse lookup using either of these two tags may result in both WL0 and WL2 being energized. The memory device that includes remap logic 8000 may act to compare the full received tag with the tag stored in row 0 and with the tag stored in row 2, select the correct row, and return the value stored in that row. Although multiple rows may be activated in such a case, this embodiment may still optionally provide lower power than a current art content addressable memory device where every row may have to be activated to detect the matching row.

In some embodiments, the input to hash function generator 8020 may be the entire tag. In other embodiments, the input to hash function generator 8020 may be a portion of the tag. Furthermore, row remap logic 8000 in FIG. 80 is shown to include hash function generator 8020, strictly as an example. Row remap logic 8000 may include a logic block that performs any other transformation of an input tag or a portion of an input tag instead of a hash function. Sch transformation may produce a one-to-one mapping between the input and the output or a many-to-one mapping between the input and the output.

Additional functions that may reside local to the memory subsystem include write and/or read buffers, one or more levels of memory cache, local pre-fetch logic, data encryption and/or decryption, compression and/or decompression, protocol translation, command prioritization logic, voltage and/or level translation, error detection and/or correction circuitry, data scrubbing, local power management circuitry and/or reporting, operational and/or status registers, initialization circuitry, performance monitoring and/or control, one or more co-processors, search engine(s) and other functions that may have previously resided in other memory subsystems. By placing a function local to the memory subsystem, added performance may be obtained as related to the specific function, often while making use of unused circuits within the subsystem.

Memory subsystem support device(s) may be directly attached to the same assembly (e.g. substrate, base, board, package, structure, etc.) onto which the memory device(s) are attached (e.g. mounted, connected, etc.) to a separate substrate (e.g. interposer, spacer, layer, etc.) also produced using one or more of various materials (e.g. plastic, silicon, ceramic, etc.) that include communication paths (e.g. electrical, optical, etc.) to functionally interconnect the support device(s) to the memory device(s) and/or to other elements of the memory or computer system.

Furthermore, in the various embodiments described above, a memory device (e.g. DRAM device, NAND Flash device) may be implemented as a single monolithic integrated circuit or may be implemented in a three-dimensional integrated circuit. In the context of the present description, a three-dimensional integrated circuit refers to any integrated circuit comprised of stacked wafers and/or dies (e.g. silicon wafers and/or dies, etc.), which are interconnected vertically and are capable of behaving as a single device. For example, in one embodiment, the DRAM device that includes bank 6600 may include a three-dimensional circuit that is a wafer-on-wafer device, where a first wafer may include a plurality of bit cells and a second wafer may include circuits such as address decoders, sense amplifiers, timing circuits, and/or I/O circuits. In the context of the present description, a wafer-on-wafer device refers to any device including two or more semiconductor wafers that are communicatively coupled in a wafer-on-wafer configuration. In one embodiment, the wafer-on-wafer device may include a device that is constructed utilizing two or more semiconductor wafers, which are aligned, bonded, and possibly cut in to at least one three-dimensional integrated circuit. In this case, vertical connections (e.g. TSVs, etc.) may be built into the wafers before bonding or created in the stack after bonding.

In another embodiment, the DRAM device that, for example, includes bank 6600 may include a three-dimensional integrated circuit that is a die-on-wafer device. In the context of the present description, a die-on-wafer device refers to any device including one or more dies positioned on a wafer. In one embodiment, the die-on-wafer device may be formed by dicing a first wafer into singular dies, then aligning and bonding the dies onto die sites of a second wafer. For example, the first wafer may include circuits such as address decoders, sense amplifiers, timing circuits, and/or I/O circuits, and the second wafer may include a plurality of strings. Vertical connections (e.g. TSVs, etc.) may be built into the wafers before bonding or created in the stack after bonding.

Additionally, some or all the functions of an external logic device may be implemented in the memory device die. In other embodiments, some or all the functions of an external logic device may be implemented in a separate die, which may be packaged with one or more memory dies, wherein the plurality of dies may be connected by any mechanical, electrical, or optical means (e.g. wire bonds, TSVs, lasers and photodiodes, etc.). In further embodiments, some or all the functions of an external device may be implemented with one or more memory devices in a 2.5D or 3D fabrication process.

Transfer of information (e.g. using packets, bus, signals, wires, etc.) along a bus, (e.g. channel, link, cable, etc.) may be completed using one or more of many signaling options. These signaling options may include such methods as single-ended, differential, time-multiplexed, encoded, optical or other approaches, with electrical signaling further including such methods as voltage or current signaling using either single or multi-level approaches. Signals may also be modulated using such methods as time or frequency, multiplexing, non-return to zero (NRZ), phase shift keying (PSK), amplitude modulation, combinations of these, and others.

One or more clocking methods may be used within the memory system, including global clocking, source-synchronous clocking, encoded clocking or combinations of these and/or other methods. The clock signaling may be identical to that of the signal lines, or may use one of the listed or alternate techniques that are more conducive to the planned clock frequency or frequencies, and the number of clocks planned within the various systems and subsystems. A single clock may be associated with all communication to and from the memory, as well as all clocked functions within the memory subsystem, or multiple clocks may be sourced using one or more methods such as those described earlier. When multiple clocks are used, the functions within the memory subsystem may be associated with a clock that is uniquely sourced to the memory subsystem, or may be based on a clock that is derived from the clock related to the signal(s) being transferred to and from the memory subsystem (such as that associated with an encoded clock). Alternately, a unique clock may be used for the signal(s) transferred to the memory subsystem, and a separate clock for signal(s) sourced from one (or more) of the memory subsystems. The clocks themselves may operate at the same or frequency multiple of the communication or functional frequency, and may be edge-aligned, center-aligned or placed in an alternate timing position relative to the signal(s).

Signals coupled to the memory subsystem(s) include address, command, control, and data, coding (e.g. parity, ECC, etc.), as well as other signals associated with requesting or reporting status (e.g. retry, etc.) and/or error conditions (e.g. parity error, etc.), resetting the memory, completing memory or logic initialization and other functional, configuration or related information etc. Signals coupled from the memory subsystem(s) may include any or all of the signals coupled to the memory subsystem(s) as well as additional status, error, control etc. signals, however generally will not include address and command signals. Further, any of the features disclosed herein may be implemented in the context of the systems described in the following patents/applications that are incorporated herein by reference in their entirety for all purposes: Application Ser. No. 63/761,777, filed Feb. 21, 2025 under Docket Number SUR1P001+; Application Serial No.: 63/798,153, filed May 1, 2025 under Docket Number SUR1P002+; Application Serial No.: 63/798,166, filed May 1, 2025 under Docket Number SUR1P003+; Application Serial No.: 63/929,604, filed Dec. 2, 2025 under Docket Number SUR1P004+; U.S. Pat. Nos. 8,930,647; and 9,432,298.

Signals may be coupled using methods that may be consistent with normal memory device interface specifications (generally parallel in nature, e.g. DDR2, DDR3, etc.), or the signals may be encoded into a packet structure (generally serial in nature, e.g. FB-DIMM etc.), for example, to increase communication bandwidth and/or enable the memory subsystem to operate independently of the memory technology by converting the received signals to/from the format required by the receiving memory device(s). In this regard, the following specifications are incorporated herein by reference in their entirety for all purposes: DDR5 Specification JESD79-5C.01 published July 2024, High Bandwidth Memory DRAM (HBM1, HBM2) JESD235D published January 2020, High Bandwidth Memory DRAM (HBM3) JESD238A published January 2022, and LPDDR 5/5X JESD209-5C published July 2023.

The terminology used herein is for the purpose of describing particular embodiments only and is not intended to be limiting. As used herein, the singular forms (e.g. a, an, the, etc.) are intended to include the plural forms as well, unless the context clearly indicates otherwise.

The terms comprises and/or comprising, when used in this specification, specify the presence of stated features, integers, steps, operations, elements, and/or components, but do not preclude the presence or addition of one or more other features, integers, steps, operations, elements, components, and/or groups thereof.

In the following description and claims, the terms include and comprise, along with their derivatives, may be used, and are intended to be treated as synonyms for each other.

In the following description and claims, the terms coupled and connected may be used, along with their derivatives. It should be understood that these terms are not necessarily intended as synonyms for each other. For example, connected may be used to indicate that two or more elements are in direct physical or electrical contact with each other. Further, coupled may be used to indicate that that two or more elements are in direct or indirect physical or electrical contact. For example, coupled may be used to indicate that that two or more elements are not in direct contact with each other, but the two or more elements still cooperate or interact with each other.

The corresponding structures, materials, acts, and equivalents of all means or step plus function elements in the claims below are intended to include any structure, material, or act for performing the function in combination with other claimed elements as specifically claimed. The description of the various embodiments has been presented for purposes of illustration and description, but is not intended to be exhaustive or limited to the various embodiments in the form disclosed. Many modifications and variations will be apparent to those of ordinary skill in the art without departing from the scope and spirit of the various embodiments. The embodiments were chosen and described in order to best explain the principles and the practical application of various embodiments, and to enable others of ordinary skill in the art to understand that various embodiments with various modifications as are suited to the particular use are contemplated.

As will be appreciated by one skilled in the art, aspects of various embodiments may be embodied as a system, method or computer program product. Accordingly, aspects of various embodiments may take the form of an entirely hardware embodiment, an entirely software embodiment (including firmware, resident software, micro-code, etc.) or an embodiment combining software and hardware aspects that may all generally be referred to herein as a circuit, component, module or system. Furthermore, aspects of various embodiments may take the form of a computer program product embodied in one or more computer readable medium(s) having computer readable program code embodied thereon.

The capabilities of the various embodiments can be implemented in software, firmware, hardware or some combination thereof.

As one example, one or more aspects of various embodiments can be included in an article of manufacture (e.g., one or more computer program products) having, for instance, computer usable media. The media has embodied therein, for instance, computer readable program code means for providing and facilitating the capabilities of various embodiments. The article of manufacture can be included as a part of a computer system or sold separately.

Additionally, at least one program storage device readable by a machine, tangibly embodying at least one program of instructions executable by the machine to perform the capabilities of various embodiments can be provided.

The diagrams depicted herein are just examples. There may be many variations to these diagrams or the steps (or operations) described therein without departing from the spirit of various embodiments. For instance, the steps may be performed in a differing order, or steps may be added, deleted or modified. All of these variations are considered a part of the claimed invention.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

1. An apparatus, comprising:
a memory device including an array of bit cells arranged in rows and columns; and
circuitry in communication with the memory device, the circuitry operating a first portion of the bit cells of the array and a second portion of the bit cells of the array, where the operation of the first portion of bit cells overlaps the operation of the second portion of bit cells.

2. (canceled)

3. (canceled)

4. (canceled)

5. (canceled)

6. (canceled)

7. (canceled)

8. An apparatus, comprising:
a memory device including an array of bit cells arranged in rows and columns; and circuitry in communication with the memory device, the circuitry operating to connect a first portion of the bit cells of the array to global bit lines and operating to isolate a second portion of the bit cells of the array from the global bit lines.

9. (canceled)

10. (canceled)

11. (canceled)

12. (canceled)

13. A system, comprising:
a memory sub-system including a controller communicatively coupled to one or more memory devices;
wherein the memory sub-system is configured such that a first portion of the one or more memory devices and a second portion of the one or more memory devices may be operable overlapping each other.

14. (canceled)

15. (canceled)

16. (canceled)

17. An apparatus, comprising:
a memory device including an array of bit cells arranged in rows and columns; and
circuitry in communication with the memory device, the circuitry configuring at least a portion of the bit cells of the array into a plurality of regions by assigning region identifiers to at least a portion of the bit cells of the array based on one or more aspects of the memory device, such that one or more bit cells with a first region identifier is remapped to a first region and one or more bit cells with a second region identifier is remapped to a second region.

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. A method, comprising:
at a memory device including an array of bit cells arranged in rows and columns:
configuring at least a portion of the array of bit cells into a plurality of regions, by assigning region identifiers to at least a portion of the bit cells of the array based on one or more aspects of the memory device;
remapping one or more bit cells with a first region identifier to a first region; and
remapping one or more bit cells with a second region identifier to a second region.

31. (canceled)

32. (canceled)

33. (canceled)

34. (canceled)

35. (canceled)

36. A system, comprising:
a memory sub-system including a controller communicatively coupled to one or more memory devices;
wherein the memory sub-system is configured such that at least a portion of the one or more memory devices is configured into multiple regions and information is communicated between the controller and the one or more memory devices, resulting in an equalization of sizes of at least some of the multiple regions in the one or more memory devices.

37. (canceled)

38. (canceled)

39. (canceled)

40. An apparatus, comprising:
a memory device including an array of bit cells arranged in rows and columns; and
circuitry in communication with the memory device, the circuitry repairing at least a portion of the bit cells of the array by assigning valid identifiers to the portion of the bit cells of the array based on one or more aspects of the memory device.

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. A method, comprising:
at a memory device including an array of bit cells arranged in rows and columns:
repairing at least a portion of the array of bit cells, by assigning repair identifiers to at least a portion of the bit cells of the array based on one or more aspects of the memory device;
replacing one or more bit cells with one or more other bit cells.

56. (canceled)

57. (canceled)

58. (canceled)

59. A system, comprising:
a memory sub-system including a controller communicatively coupled to one or more memory devices;
wherein the memory sub-system is configured such that information is communicated between the controller and the one or more memory devices, resulting in a repair of the one or more memory devices.

60. (canceled)

61. (canceled)

62. (canceled)

63. An apparatus, comprising:
a memory device including an array of bit cells arranged in rows and columns; and
circuitry configuring at least a portion of the bit cells of the array into a plurality of regions based on one or more aspects of the memory device.

64. (canceled)

65. (canceled)

66. (canceled)

67. (canceled)

68. (canceled)

69. (canceled)

70. (canceled)

71. (canceled)

72. (canceled)

73. (canceled)

74. (canceled)

75. (canceled)

76. (canceled)

77. (canceled)

78. A method, comprising:
at a memory device including an array of bit cells arranged in rows and columns:
configuring at least a portion of the array of bit cells into a plurality of regions based on one or more aspects of the memory device;
remapping one or more bit cells from a first region to a second region; and
restoring one or more bit cells from a second region back to a first region.

79. (canceled)

80. (canceled)

81. (canceled)

82. (canceled)

83. (canceled)

84. An apparatus, comprising:
a memory device including an array of bit cells arranged in rows and columns, and configured into a plurality of regions, such that a first region and a second region are separated by a guard band.

85. (canceled)

86. (canceled)

87. (canceled)

88. (canceled)

89. (canceled)

90. An apparatus, comprising:
a memory device including an array of bit cells arranged in rows and columns; and
circuitry in communication with the memory device, the circuitry configured to apply a second voltage to a second conductor when a first voltage is applied to a first conductor during an operation of the memory device.

91. (canceled)

92. (canceled)

93. (canceled)

94. (canceled)

95. (canceled)

96. (canceled)

97. An apparatus, comprising:
a memory device including an array of bit cells arranged in rows and columns; and
circuitry configured to remap a first plurality of bit cells from a first address to a second address, and remap a second plurality of bit cells from a second address to a first address.

98. (canceled)

99. (canceled)

100. (canceled)

101. (canceled)

102. (canceled)

103. (canceled)

104. A system, comprising:
a memory sub-system including a controller communicatively coupled to one or more memory devices;
wherein the memory sub-system is configured such that at least a portion of the one or more memory devices is configured into multiple regions and information is communicated between the controller and the one or more memory devices, resulting in a plurality of bit cells being remapped from a first region to a second.

105. (canceled)

106. (canceled)

107. (canceled)

108. (canceled)

109. (canceled)

110. (canceled)

111. (canceled)

112. (canceled)

113. A system, comprising:
a memory sub-system including a controller communicatively coupled to one or more memory devices;
wherein the memory sub-system is configured such that at least a portion of the one or more memory devices is configured into multiple regions separated by guard bands and information is communicated between the controller and the one or more memory devices, resulting in a refresh of a plurality of bit cells in a first region.

114. (canceled)

115. (canceled)

116. (canceled)

117. (canceled)

118. A system, comprising:
a memory sub-system including a controller communicatively coupled to one or more memory devices;
wherein the memory sub-system is configured such that information is communicated between the controller and the one or more memory devices, resulting in a second voltage being applied to a second conductor when a first voltage is applied to a first conductor in one or more memory devices.

119. (canceled)

120. (canceled)

121. (canceled)

122. A system, comprising:
a memory sub-system including a controller communicatively coupled to one or more memory devices;
wherein the memory sub-system is configured such that information is communicated between the controller and the one or more memory devices, resulting in a first plurality of bit cells being mapped from a first address to a second address and a second plurality of bit cells being mapped from a second address to a first address.

123. (canceled)

124. (canceled)

125. (canceled)

126. An apparatus, comprising:
a memory device including an array of bit cells arranged in rows and columns, wherein a row of bit cells includes one or more clamping transistors.

127. A system, comprising:
a memory sub-system including a controller communicatively coupled to one or more memory devices;
wherein the memory sub-system is configured such that information is communicated between the controller and the one or more memory devices, resulting in one or more conductors in the one or more memory devices being clamped to a signal.

128. (canceled)

129. (canceled)

130. An apparatus, comprising:
a memory device including an array of bit cells arranged in rows and columns; and
circuitry remapping at least a portion of the bit cells of the array based on at least a portion of data written to the at least a portion of the bit cells.

131. (canceled)

132. (canceled)

133. (canceled)

134. (canceled)
